(19) United States
(12) Patent Application Publication
(10) Pub. No.: US 2015/0144946 A1
(43) Pub. Date: May 28, 2015

(54) DISPLAY DEVICE

(71) Applicant: Semiconductor Energy Laboratory Co., Ltd., Atsugi-shi (JP)

(72) Inventors: Koji KUSUNOKI, Kawasaki (JP); Hiroyuki MIYAKE, Atsugi (JP); Hideaki SHISHIDO, Atsugi (JP)

(73) Assignee: Semiconductor Energy Laboratory Co., Ltd.

(21) Appl. No.: 14/552,029

(22) Filed: Nov. 24, 2014

(30) Foreign Application Priority Data
Nov. 28, 2013 (JP) 2013-245639
Feb. 28, 2014 (JP) 2014-038196

(51) Int. Cl. G02F 1/1335; H01L 27/12; G02F 1/1362; G02F 1/1333; G02F 1/1343; G02F 1/1368

(52) U.S. Cl. CPC G02F 1/133621; G02F 1/134309; G02F 1/1368; G02F 1/136286; G02F 1/133345; H01L 27/1225; H01L 27/1255; G02F 2001/134354
USPC 257/43

(57) ABSTRACT

A display device that includes a capacitor with low power consumption even when the number of subpixels included in a pixel is increased is provided. The area of an opening in a subpixel that controls transmission of white light is smaller than the area of an opening in each of subpixels that control transmission of red light, green light, and blue light. A transistor included in each subpixel includes an oxide semiconductor film. The capacitor includes a first electrode and a second electrode. The first electrode is a metal oxide film in contact with an inorganic insulating film over the transistor. The second electrode is a light-transmitting conductive film that is over the inorganic insulating film and is electrically connected to the transistor.

### BACKGROUND OF THE INVENTION

1. Field of the Invention

One embodiment of the present invention relates to a display device.

Note that the present invention is not limited to the above technical field. The technical field of the invention disclosed in this specification and the like relates to an object, a method, or a manufacturing method. Furthermore, the present invention relates to a process, a machine, manufacture, or a composition of matter. Specifically, examples of the technical field of one embodiment of the present invention disclosed in this specification include a semiconductor device, a display device, a light-emitting device, a power storage device, a storage device, a method for driving any of them, and a method for manufacturing any of them.

2. Description of the Related Art

A display device for color display that includes pixels each having subpixels including color filters of three primary colors, i.e. red (R), green (G), and blue (B) is in practical use. In each subpixel, the luminance of light emitted from a backlight or the like is adjusted and color display is performed by additive color mixture of R, G, and B.

In recent years, a display device has been proposed in which pixels are each having subpixels that transmit white light in addition to red (R) light, green (G) light, and blue (B) light to reduce power consumption or improve luminance (see Patent Document 1).

### REFERENCE

Patent Document 1: Japanese Published Patent Application No. H11-295717

### SUMMARY OF THE INVENTION

In the structure disclosed in Patent Document 1, when a subpixel that transmits white light is provided, the number of subpixels included in one pixel is increased; thus, the number of wirings for controlling the subpixels is increased. When the area occupied by wirings is increased, it is necessary to design the subpixels smaller. When the subpixels are designed smaller, in light of the unchanged size of a transistor or a storage capacitor, a light-transmitting region should be small. Thus, it is necessary to increase the luminance of light that is emitted by using a backlight or the like. Consequently, there is a problem of increased power consumption.

In view of the problems, it is an object of one embodiment of the present invention to provide a low-power display device or the like having a novel structure. Alternatively, it is an object of one embodiment of the present invention to provide a display device or the like having a novel structure in which the number of wirings for controlling subpixels can be reduced. Alternatively, it is an object of one embodiment of the present invention to provide a display device or the like having a novel structure in which the area occupied by a storage capacitor in a subpixel can be reduced. Alternatively, it is an object of one embodiment of the present invention to provide a display device or the like having a novel structure with high display quality. Alternatively, it is an object of one embodiment of the present invention to provide a novel display device or the like.

Note that the objects of the present invention are not limited to the above objects. The above objects do not disturb the existence of other objects. The other objects are objects that are not described above and will be described below. The other objects will be apparent from and can be derived as appropriate from the description of the specification, the drawings, and the like by those skilled in the art. One embodiment of the present invention achieves at least one of the above objects and/or the other objects.

One embodiment of the present invention is a display device that includes a pixel including first to fourth subpixels. The first to third subpixels each control transmission of any one of red light, green light, and blue light. The fourth subpixel controls transmission of white light. The area of an opening in the fourth subpixel is smaller than the area of an opening in each of the first to third subpixels.

One embodiment of the present invention is a display device that includes a pixel including first to fourth subpixels. The first to fourth subpixels each include a transistor and a capacitor. The transistor includes an oxide semiconductor film. The capacitor includes a first electrode and a second electrode. The first electrode is a metal oxide film in contact with an inorganic insulating film over the transistor. The second electrode is a light-transmitting conductive film that is over the inorganic insulating film and is electrically connected to the transistor. The first to third subpixels each control transmission of any one of red light, green light, and blue light. The fourth subpixel controls transmission of white light. The area of an opening in the fourth subpixel is smaller than the area of an opening in each of the first to third subpixels.

One embodiment of the present invention is a display device that includes a pixel including first to fourth subpixels. The first to fourth subpixels each include a transistor and a capacitor. The transistor includes an oxide semiconductor film. The capacitor includes a first electrode and a second electrode. The first electrode is a metal oxide film in contact with an inorganic insulating film over the transistor. The second electrode is a light-transmitting conductive film that is over the inorganic insulating film and is electrically connected to the transistor. The first to fourth subpixels are arranged in two rows by two columns in the pixel. The first to third subpixels each control transmission of any one of red light, green light, and blue light. The fourth subpixel controls transmission of white light. The area of an opening in the fourth subpixel is smaller than the area of an opening in each of the second to fourth subpixels.

One embodiment of the present invention is a display device that includes a pixel including first to fourth subpixels. The first to fourth subpixels each include a transistor and a capacitor. The transistor includes an oxide semiconductor film. The capacitor includes a first electrode and a second electrode. The first electrode is a metal oxide film in contact with an inorganic insulating film over the transistor. The second electrode is a light-transmitting conductive film that is over the inorganic insulating film and is electrically connected to the transistor. The first to fourth subpixels are arranged in two rows by two columns in the pixel. The first to fourth subpixels include a first wiring that supplies a first data signal to the first subpixel and the second subpixel, a second wiring that supplies a second data signal to the third subpixel and the fourth subpixel, a third wiring that supplies a signal for controlling writing of the first data signal or the second data signal to the first subpixel and the third subpixel, a fourth wiring that supplies a signal for controlling writing of the first data signal or the second data signal to the second subpixel and the fourth subpixel, and a fifth wiring for applying a constant potential to the second electrode of the capacitor. The first to third subpixels each control transmission of any one of red light, green light, and blue light. The fourth subpixel controls transmission of white light. The area of an opening in the fourth subpixel is smaller than the area of an opening in each of the first to third subpixels.

According to one embodiment of the present invention, it is possible to provide a low-power display device or the like having a novel structure. Alternatively, according to one embodiment of the present invention, it is possible to provide a display device or the like having a novel structure in which the number of wirings for controlling subpixels can be reduced. Alternatively, according to one embodiment of the present invention, it is possible to provide a display device or the like having a novel structure in which the area occupied by a storage capacitor in a subpixel can be reduced. Alternatively, according to one embodiment of the present invention, it is possible to provide a display device or the like having a novel structure with high display quality. Alternatively, according to one embodiment of the present invention, it is possible to provide a novel display device or the like.

Note that the effects of the present invention are not limited to the above effects. The above effects do not disturb the existence of other effects. The other effects are effects that are not described above and will be described below. The other effects will be apparent from and can be derived as appropriate from the description of the specification, the drawings, and the like by those skilled in the art. One embodiment of the present invention has at least one of the above effects and/or the other effects. Accordingly, one embodiment of the present invention does not have the above effects in some cases.

### BRIEF DESCRIPTION OF THE DRAWINGS

In the accompanying drawings:

FIGS. 1A and 1B are block diagrams illustrating one embodiment of the present invention;

FIGS. 2A and 2B are block diagrams illustrating one embodiment of the present invention;

FIGS. 3A to 3C are block diagrams illustrating one embodiment of the present invention;

FIGS. 4A to 4C are a block diagram and circuit diagrams illustrating one embodiment of the present invention;

FIG. 5A and FIG. 5B are a top view and a circuit diagram illustrating one embodiment of the present invention;

FIG. 6 is a top view illustrating one embodiment of the present invention;

FIG. 7 is a cross-sectional view illustrating one embodiment of the present invention;

FIGS. 8A and 8B are a top view and a cross-sectional view illustrating one embodiment of the present invention;

FIGS. 9A and 9B are a top view and a cross-sectional view illustrating one embodiment of the present invention;

FIGS. 10A and 10B are a top view and a cross-sectional view illustrating one embodiment of the present invention;

FIGS. 11A and 11B are a top view and a cross-sectional view illustrating one embodiment of the present invention;

FIGS. 12A to 12D are cross-sectional views illustrating one embodiment of the present invention;

FIGS. 13A to 13C are cross-sectional views illustrating one embodiment of the present invention;

FIGS. 14A to 14C are cross-sectional views illustrating one embodiment of the present invention;

FIGS. 15A to 15C are cross-sectional views illustrating one embodiment of the present invention;

FIGS. 16A to 16C are cross-sectional views illustrating one embodiment of the present invention;

FIGS. 17A and 17B are cross-sectional views illustrating one embodiment of the present invention;

FIG. 18 is a cross-sectional view illustrating one embodiment of the present invention;

FIG. 19 is a cross-sectional view illustrating one embodiment of the present invention;

FIGS. 20A and 20B are cross-sectional views illustrating one embodiment of the present invention;

FIGS. 21A and 21B are cross-sectional views illustrating one embodiment of the present invention;

FIGS. 22A to 22C are cross-sectional views illustrating one embodiment of the present invention;

FIGS. 23A and 23B are cross-sectional views illustrating one embodiment of the present invention;

FIG. 24 is a cross-sectional view illustrating one embodiment of the present invention;

FIGS. 25A and 25B are cross-sectional views illustrating one embodiment of the present invention;

FIGS. 26A to 26C are cross-sectional TEM images and a local Fourier transform image of an oxide semiconductor;

FIGS. 27A and 27B show nanobeam electron diffraction patterns of oxide semiconductor films, and FIGS. 27C and 27D illustrate an example of a transmission electron diffraction measurement apparatus;

FIG. 28A shows an example of structural analysis by transmission electron diffraction measurement, and FIGS. 28B and 28C show planar TEM images;

FIGS. 29A and 29B are conceptual diagrams illustrating examples of a method for driving a display device;

FIG. 30 illustrates a display module;

FIGS. 31A to 31H are each an external view of an electronic device according to one embodiment;

FIGS. 32A to 32H are each an external view of an electronic device according to one embodiment;

FIGS. 33A and 33B are block diagrams each illustrating one embodiment of the present invention; and

FIG. 34 is a graph showing temperature dependence of resistivity.

### DETAILED DESCRIPTION OF THE INVENTION

Embodiments will be described below with reference to the drawings. Note that the embodiments can be implemented in various different ways and it will be readily appreciated by those skilled in the art that modes and details of the present invention can be modified in various ways without departing from the spirit and scope of the present invention. The present invention therefore should not be construed as being limited to the following description of the embodiments. Note that in structures of the invention described below, reference numerals denoting the same portions are used in common in different drawings.

In the drawings, the size, the layer thickness, or the region is exaggerated for clarity in some cases. Thus, embodiments of the present invention are not limited to such scales. Note that the drawings are schematic views showing ideal examples, and embodiments of the present invention are not limited to shapes or values shown in the drawings. For example, the following can be included: variation in signal, voltage, or current due to noise or difference in timing.

In this specification and the like, a transistor is an element having at least three terminals: a gate (a gate terminal or a gate electrode), a drain, and a source. The transistor includes a channel region between the drain (a drain terminal, a drain region, or a drain electrode) and the source (a source terminal, a source region, or a source electrode) and current can flow through the drain, the channel region, and the source.

Here, since the source and the drain of the transistor change depending on the structure, the operating condition, and the like of the transistor, it is difficult to define which is a source or a drain. Thus, regions that function as a source or a drain are each not referred to as a source or a drain in some cases. In that case, one of the source and the drain might be referred to as a first terminal, and the other of the source and the drain might be referred to as a second terminal.

In this specification, ordinal numbers such as “first,” “second,” and “third” are used to avoid confusion among components, and thus do not limit the number of the components.

In this specification, the expression “A and B are connected” means the case where “A and B are electrically connected” in addition to the case where “A and B are directly connected.” Here, the expression “A and B are electrically connected” means the case where electric signals can be transmitted and received between A and B when an object having any electric action exists between A and B.

In this specification, terms for describing arrangement, such as “over” and “under,” are used for convenience for describing the positional relationship between components with reference to drawings. Furthermore, the positional relationship between components is changed as appropriate in accordance with a direction in which each component is described. Thus, there is no limitation on terms used in this specification, and description can be made appropriately depending on the situation.

The positional relationships of circuit blocks in diagrams are specified for description, and even in the case where different circuit blocks have different functions in the diagrams, the different circuit blocks might be provided in an actual circuit or region so that different functions are achieved in the same circuit block. The functions of circuit blocks in diagrams are specified for description, and even in the case where one circuit block is illustrated, blocks might be provided in an actual circuit or region so that processing performed by one circuit block is performed by a plurality of circuit blocks.

Voltage refers to a difference between a given potential and a reference potential (e.g., a ground potential) in many cases. Thus, voltage, a potential, and a potential difference can also be referred to as a potential, voltage, and a voltage difference, respectively. Note that voltage refers to a difference between potentials of two points, and a potential refers to electrostatic energy (electric potential energy) of a unit charge at a given point in an electrostatic field.

Note that in general, a potential and voltage are relative values. Thus, a ground potential is not always 0 V.

In this specification and the like, the term “parallel” indicates that an angle formed between two straight lines is −10 to 10°, and accordingly includes the case where the angle is −5 to 5°. In addition, the term “perpendicular” indicates that an angle formed between two straight lines is 80 to 100°, and accordingly includes the case where the angle is 85 to 95°.

In this specification and the like, trigonal and rhombohedral crystal systems are included in a hexagonal crystal system.

### Embodiment 1

In this embodiment, a display device that is one embodiment of the present invention is described with reference to drawings.

### <Structure of Subpixel Included in Pixel>

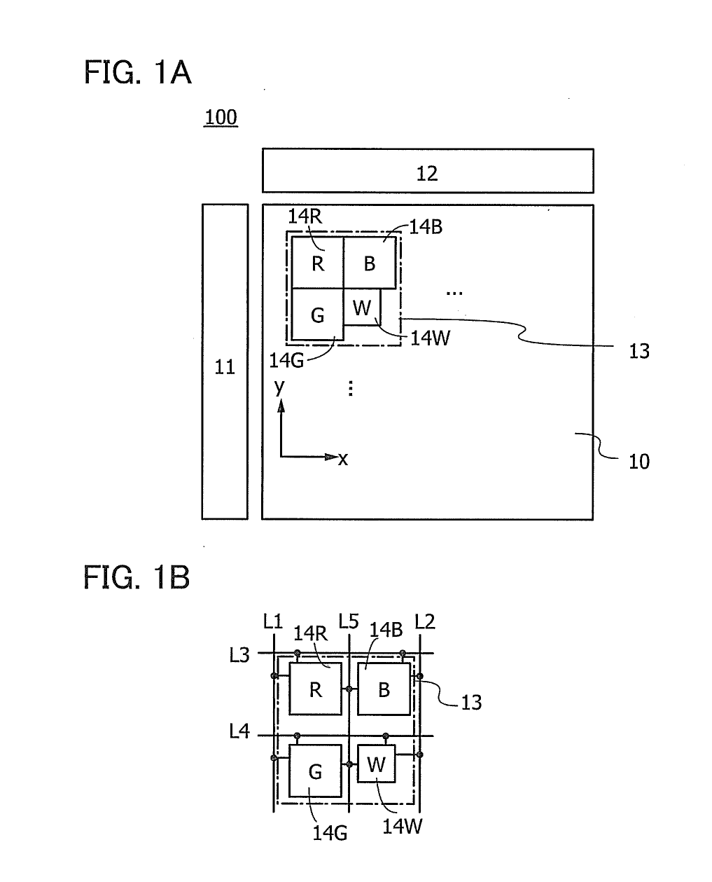

FIG. 1A is a block diagram of a pixel portion included in a display device and circuits for driving the pixel portion.

A display device 100 in FIG. 1A includes a pixel portion 10, a circuit 11, and a circuit 12. The pixel portion 10 includes a pixel 13. The pixel 13 includes a subpixel 14R, a subpixel 14G, a subpixel 14B, and a subpixel 14W.

FIG. 1B is a block diagram illustrating the details of the pixel 13 in FIG. 1A. FIG. 1B illustrates first to fifth wirings L1 to L5 in addition to the subpixel 14R, the subpixel 14G, the subpixel 14B, and the subpixel 14W included in the pixel 13.

The subpixel 14R, the subpixel 14G, the subpixel 14B, and the subpixel 14W included in the pixel 13 each include a transistor and a capacitor (both not illustrated). The first to fifth wirings L1 to L5 have a function of supplying a control signal or a constant potential to the transistor and the capacitor.

The pixel 13 has functions of controlling transmission of lights of four colors, i.e. W (white) in addition to three primary colors of R, G, and B (red, green, and blue) by the subpixels and performing color display by additive color mixture of these lights. The subpixels that control transmission of R, G, and B lights include color filters as coloring layers for converting lights from a light source into lights of respective colors. Note that the subpixel that controls transmission of W light transmits light from the light source without the color filter when the light is white. The white may be white obtained by mixture of complementary colors as well as white obtained by additive color mixture of R, G, and B.

Note that although the pixel 13 includes four kinds of subpixels of R, G, B, and W, one embodiment of the present invention is not limited thereto. One pixel includes at least two subpixels among the four subpixels. The subpixels included in one pixel may differ from those of another pixel.

For example, a first pixel may include an R subpixel, a G subpixel, and a B subpixel, and a second pixel may include an R subpixel, a G subpixel, a B subpixel, and a W subpixel.

The subpixel 14R has functions of controlling conduction of the transistor by supply of a first scan signal, retaining the first data signal by the capacitor, and controlling transmission of red light by driving a display element in accordance with the amount of charge supplied by the first data signal. The subpixel 14G has functions of controlling conduction of the transistor by supply of a second scan signal, retaining the first data signal by the capacitor, and controlling transmission of green light by driving the display element in accordance with the amount of charge supplied by the first data signal. The subpixel 14B has functions of controlling conduction of the transistor by supply of the first scan signal, retaining a second data signal by the capacitor, and controlling transmission of blue light by driving the display element in accordance with the amount of charge supplied by the second data signal. The subpixel 14W has functions of controlling conduction of the transistor by supply of the second scan signal, retaining the second data signal by the capacitor, and controlling transmission of white light by driving the display element in accordance with the amount of charge supplied by the second data signal.

Note that the subpixel 14R is also referred to as a first subpixel in some cases. The subpixel 14G is also referred to as a second subpixel in some cases. The subpixel 14B is also referred to as a third subpixel in some cases. The subpixel 14W is also referred to as a fourth subpixel in some cases.

In FIG. 1B, the first wiring L1 functions as, for example, a signal line for supplying the first data signal to the subpixel 14R and the subpixel 14G. The second wiring L2 functions as, for example, a signal line for supplying the second data signal to the subpixel 14B and the subpixel 14W. The third wiring L3 functions as, for example, a signal line for supplying a first selection signal to the subpixel 14R and the subpixel 14B. The fourth wiring L4 functions as, for example, a signal line for supplying a second selection signal to the subpixel 14G and the subpixel 14W. The fifth wiring L5 functions as, for example, a capacitor line for applying a constant potential to the subpixel 14R, the subpixel 14G, the subpixel 14B, and the subpixel 14W.

The circuit 11 in FIG. 1A functions as a scan line driver circuit. Specifically, the circuit 11 has a function of sequentially outputting the first scan signal and the second scan signal to the first wiring L1 and the second wiring L2 in FIG. 1B. The circuit 12 in FIG. 1A functions as a signal line driver circuit. Specifically, the circuit 12 has a function of sequentially outputting the first data signal and the second data signal to the third wiring L3 and the fourth wiring L4 in FIG. 1B. The circuit 11 and the circuit 12 each include a circuit such as a shift register and have a function of sequentially outputting signals.

Note that for illustrative purposes, FIG. 1A shows an X direction and a Y direction. The X direction is a direction in which the third wiring L3 and the fourth wiring L4 extend, i.e. a row direction of pixels (horizontal direction in FIG. 1A). The Y direction is a direction in which the first wiring L1 and the second wiring L2 extend, i.e. a column direction of pixels (vertical direction in FIG. 1A).

In the structures of FIGS. 1A and 1B according to one embodiment of the present invention, the occupation area of the subpixel 14W is smaller than the occupation area of each of the subpixel 14R, the subpixel 14G, and the subpixel 14B. Note that the occupation area of the subpixel can be translated into the area of an opening when the transistors and the capacitors included in the subpixels have the same size.

Note that in the following description, the subpixel 14W is abbreviated to a W subpixel in some cases. The subpixel 14R is abbreviated to an R subpixel in some cases. The subpixel 14G is abbreviated to a G subpixel in some cases. The subpixel 14B is abbreviated to a B subpixel in some cases. The subpixel 14R, the subpixel 14G, and the subpixel 14B are abbreviated to R, G, and B subpixels in some cases. The subpixel 14R, the subpixel 14G, the subpixel 14B, and the subpixel 14W are abbreviated to R, G, B, and W (red, green, blue, and white) subpixels in some cases.

When the occupation area of the W subpixel is smaller than the occupation area of each of the R, G, and B subpixels, the R, G, and B subpixels can be comparatively large; thus, the opening area of each of the R, G, and B subpixels can be large. Thus, in the case where color display is performed by a pixel including the R, G, and B subpixels, color display can be performed without any reduction in color saturation.

Unlike the R, G, and B subpixels, the W subpixel does not include a color filter for converting light into light of a predetermined color. Thus, the intensity of light that is emitted through the W subpixel is higher than that of light that is emitted through the R, G, and B subpixels. Accordingly, even when the area of the W subpixel is smaller than the other area, it is possible to keep the light intensity in balance. As a result, even when the area of the W subpixel is reduced, in the pixel, the occupation area of the W subpixel is smaller than the occupation area of each of the R, G, and B subpixels without a drastic change in white balance or the like of an image obtained by color display.

Since white light obtained by transmission of light through the R, G, and B subpixels is obtained in such a manner that light passes through the color filter, the intensity of the white light is lower than that of light emitted from the light source. The intensity of white light obtained from the W subpixel without transmission of light from the light source through the color filter as in one embodiment of the present invention is substantially the same as that of the light emitted from the light source. Thus, the intensity of white light obtained from the R, G, B, and W subpixels in one embodiment of the present invention is higher than that of white light obtained from the R, G, and B subpixels. In other words, a decrease in the intensity of white light obtained from the R, G, B, and W subpixels light intensity is suppressed. Consequently, in the structure according to one embodiment of the present invention in which the R, G, B, and W subpixels are used, white light is obtained without transmission of light through the color filter; thus, when white light having the same light intensity is obtained from the light source, the intensity of light from the light source can be lowered as compared to the case in which white light is obtained by additive color mixture using R, G, and B subpixels. As a result, the power consumption of the display device can be reduced.

Note that although the occupation area of the W subpixel depends on the amount of attenuation of light through the color filters of the R, G, and B subpixels, the occupation area of the W subpixel is equal to or larger than ⅓ of the occupation area of each of the R, G, and B subpixels and is smaller than the occupation area of each of the R, G, and B subpixels. The occupation area of the W subpixel is preferably equal to or larger than ½ of the occupation area of each of the R, G, and B subpixels and is smaller than the occupation area of each of the R, G, and B subpixels.

In the structures of FIGS. 1A and 1B according to one embodiment of the present invention, the subpixel 14R, the subpixel 14G, the subpixel 14B, and the subpixel 14W are arranged in two rows by two columns. The positions of the subpixels arranged in two rows by two columns are just examples. The positions of the subpixels can be changed as appropriate, for example, the positions of the subpixel 14R and the subpixel 14G are interchanged.

By arranging the R, G, B, and W subpixels in the pixel as illustrated in FIGS. 1A and 1B, the number of wirings such as data lines, scan lines, and capacitor lines can be reduced as compared to the case where the R, G, B, and W subpixels are arranged in stripes.

For example, in the case where the display device is a liquid crystal display device and the R, G, B, and W subpixels are arranged in stripes, it is necessary to control the pixel by using six wirings in total (four data lines, one scan line, and one capacitor line).

In contrast, in the structures of FIGS. 1A and 1B according to one embodiment of the present invention, it is possible to control the pixel by using five wirings in total (two data lines, two scan lines, and one capacitor line). Thus, the occupation area of wirings connected to the pixel including the R, G, B, and W subpixels can be reduced. The R, G, and B subpixels wiring can be increased by the reduced occupation area of the wirings; thus, the opening area of the R, G, and B subpixels can be increased. Thus, when white light having the same light intensity is obtained from the light source, the intensity of light from the light source can be lowered. As a result, power consumption can be reduced.

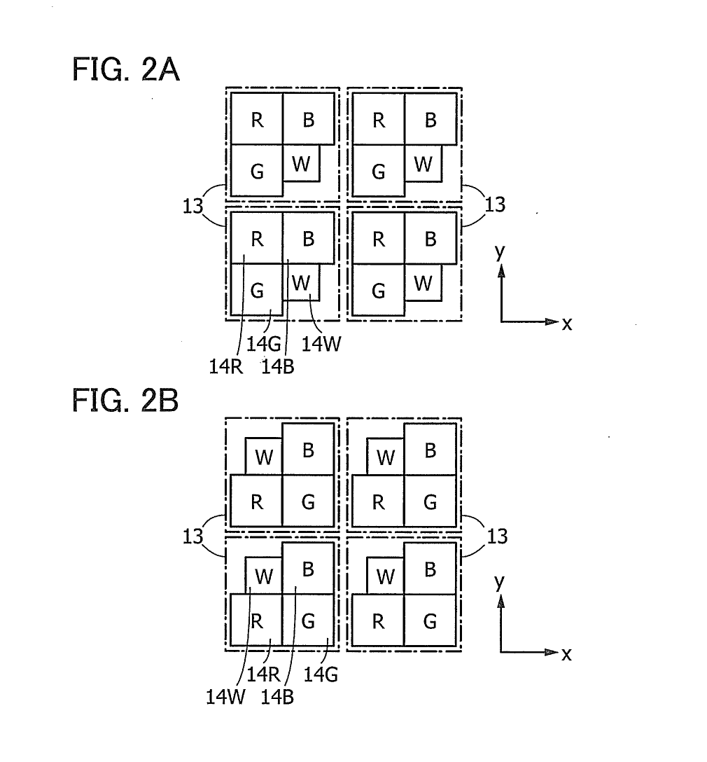

Note that in the display device according to one embodiment of the present invention, when the R, G, B, and W subpixels have the structures in FIGS. 1A and 1B, the R, G, B, and W subpixels may be arranged in matrix in the X direction and the Y direction, as illustrated in FIG. 2A. The arrangement of the subpixels is not limited to that in FIG. 2A, and can be changed as appropriate. For example, the R, G, B, and W subpixels may be arranged as illustrated in FIG. 2B.

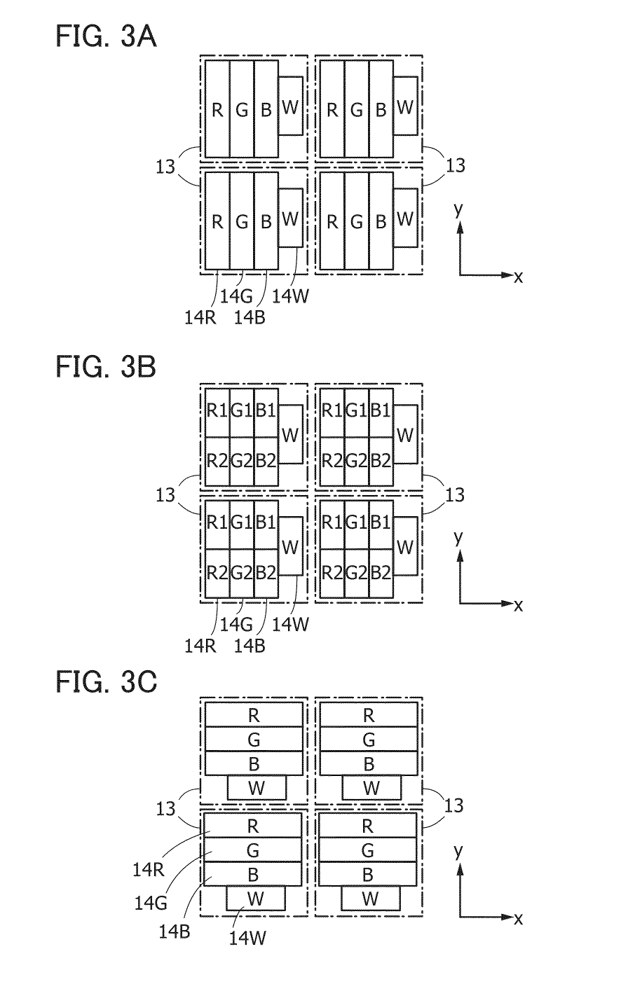

Note that in the structure according to one embodiment of the present invention, the occupation area of the subpixel 14W is smaller than the occupation area of each of the subpixel 14R, the subpixel 14G, and the subpixel 14B. In that case, the R, G, B, and W subpixels can be arranged in stripes as illustrated in FIG. 3A. Alternatively, as illustrated in FIG. 3B, the subpixel 14R, the subpixel 14G, and the subpixel 14B can be further divided. Alternatively, although the R, G, B, and W subpixels in the pixel 13 are arranged in stripes in the Y direction in FIGS. 3A and 3B, the R, G, B, and W subpixels in the pixel 13 may be arranged in stripes in the X direction, as illustrated in FIG. 3C.

### <Data Signal Supplied to Pixel>

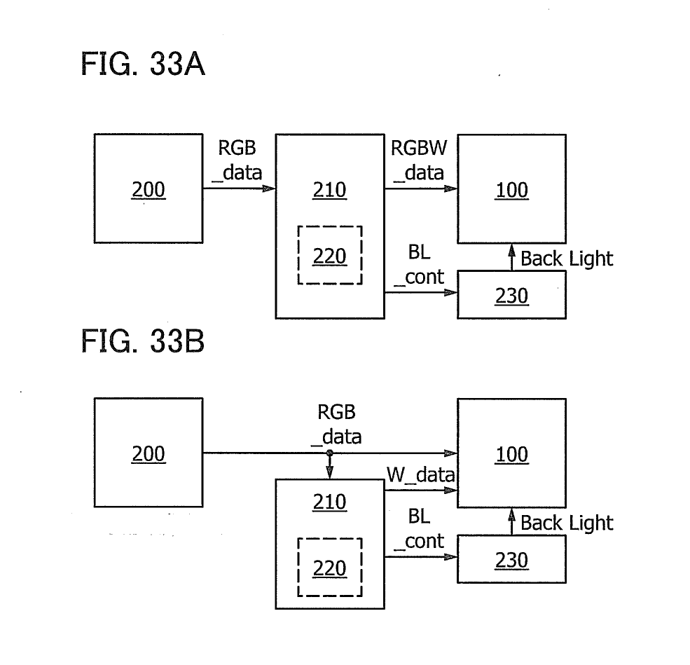

The first data signal and the second data signal supplied to the R, G, B, and W subpixels in the pixel are data signals of R, G, B, and W obtained by addition of W to the three primary colors of R, G, and B. The first data signal and the second data signal may be generated from data signals of the three primary colors of R, G, and B. For example, the first data signal and the second data signal may be generated using structures of block diagrams in FIGS. 33A and 33B.

FIG. 33A illustrated as an example shows a display controller 200, a signal conversion circuit 210, and a backlight unit 230 in addition to the display device 100. The signal conversion circuit 210 includes a data signal arithmetic circuit 220. Note that FIG. 33A illustrates an example in which the display device 100 is a liquid crystal display device and a backlight unit 230 is used as a light source.

The display controller 200 has functions of generating and outputting data signals (RGB_data in FIG. 33A) of R, G, and B. The signal conversion circuit 210 has functions of converting the data signals of R, G, and B into data signals (RGBW_data in FIG. 33A) of R, G, B, and W and outputting the data signals of R, G, B, and W to the display device 100. The signal conversion circuit 210 has a function of generating a backlight control signal BL_cont for controlling the light intensity of a backlight (back light in FIG. 33A) in the backlight unit 230 from the data signals of R, G, B, and W. The backlight unit 230 has a function of controlling the light intensity of the backlight that is the light source of the display device 100 in accordance with the backlight control signal BL_cont. Note that the backlight unit 230 may include a plurality of light sources that can be controlled independently in a plurality of subpixels so that light intensities can be controlled independently by the light sources. This structure can set the light intensities in accordance with the data signals of R, G, B, and W and can further reduce power consumption.

The data signal arithmetic circuit 220 of the signal conversion circuit 210 includes a look-up table, and may have functions of converting the data signals of R, G, and B into the data signals of R, G, B, and W by using the look-up table and outputting the data signals of R, G, B, and W. With this structure, the data signals of R, G, and B can be converted into the data signals of R, G, B, and W without performing complicated arithmetic processing. Alternatively, the data signal arithmetic circuit 220 may perform arithmetic processing in accordance with the data signals of R, G, and B and generate the data signals of R, G, B, and W.

The backlight unit 230 is controlled by the backlight control signal BL_cont. For example, the backlight unit 230 is controlled to weaken light from a corresponding light source when the gray level of the data signal of W is higher than that of each of the data signals of R, G, and B, i.e. when the intensity of light passing through the W subpixel is higher than the intensity of light passing through each of the R, G, and B subpixels. In addition, the backlight unit 230 is controlled to strengthen light from a corresponding light source when the gray level of the data signal of W is lower than that of each of the data signals of R, G, and B. With this structure, the amount of light transmission can be adjusted as appropriate by suppressing the decrease in the intensity of light passing through the W subpixel, so that power consumption can be reduced. Note that the gray levels of the data signals of R, G, B, and W may be compared by calculation on the basis of the average value of all the pixels or calculation on the basis of the average value of given pixels.

Note that as illustrated in FIG. 33B, the data signal of W and the data signals of R, G, and B may be separately generated. In this structure, the data signal arithmetic circuit 220 does not need to correct the data signals of R, G, and B, so that the amount of arithmetic operation of the data signal arithmetic circuit 220 can be reduced. In that case, since the data signal arithmetic circuit 220 does not correct the data signals of R, G, and B, light from the light source is adjusted by the backlight unit 230 in accordance with the data signal of W, so that power consumption can be reduced.

### <Display Device Structure>

In addition to the structures in which the opening area of the W subpixel is smaller than the opening area of each of the R, G, and B subpixels and the subpixels are arranged in two rows by two columns to reduce the number of wirings for controlling the pixel, one embodiment of the present invention employs a structure in which a semiconductor film of a transistor included in each subpixel is an oxide semiconductor film and an electrode included in a capacitor is formed using a light-transmitting conductive film. The structures of a transistor and a capacitor included in a subpixel are described with reference to drawings.

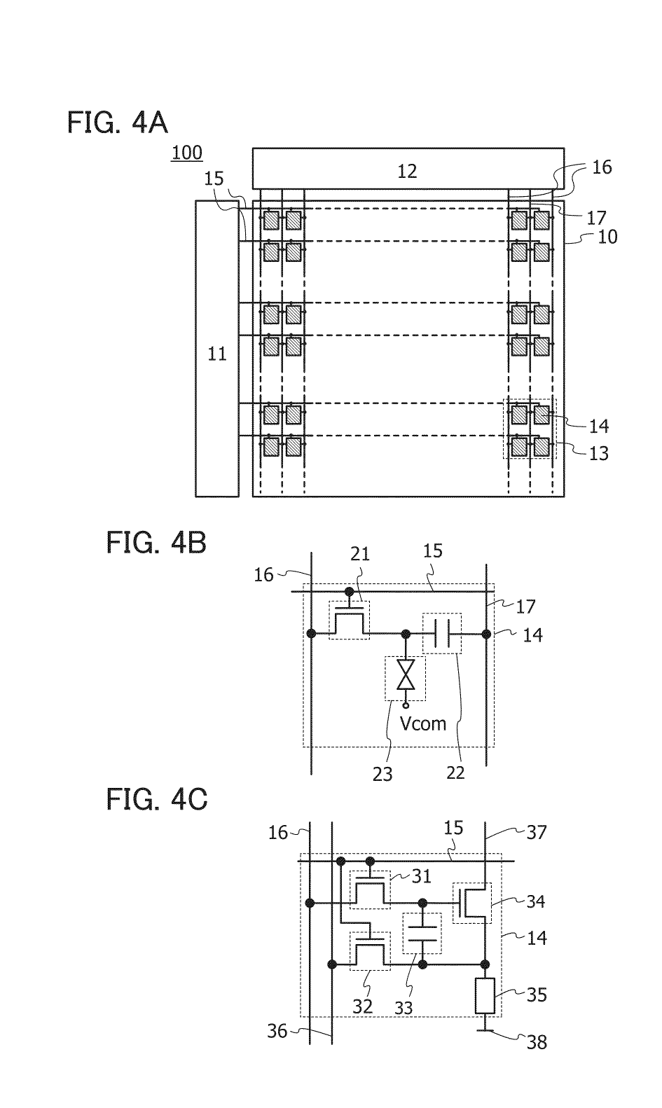

First, FIG. 4A illustrates a more specific block diagram of the display device 100 than that of FIG. 1A. The display device 100 in FIG. 4A includes a pixel portion 10; a circuit 11; a circuit 12; m (m is a natural number) scan lines 15 that are arranged parallel or substantially parallel to each other and whose potentials are controlled by the circuit 11; and n (n is a natural number) signal lines 16 that are arranged parallel or substantially parallel to each other and whose potentials are controlled by the circuit 12. In addition, the pixel portion 10 includes the plurality of pixels 13 arranged in matrix. Furthermore, the pixel 13 includes subpixels 14 arranged in two rows by two columns. Furthermore, capacitor lines 17 arranged parallel or substantially parallel to each other are provided along the signal lines 16. Note that the capacitor lines 25 may be arranged parallel or substantially parallel to each other along the scan lines 17.

Note that the display device might also be referred to as a display module including a display controller, a signal conversion circuit, a power supply circuit, a backlight unit, and the like provided over another substrate.

FIGS. 4B and 4C illustrate examples of circuit structures that can be used for the subpixels 14 in the display device in FIG. 4A.

The subpixel 14 illustrated in FIG. 4B is an example of a subpixel included in a liquid crystal display device, which includes a liquid crystal element 23, a transistor 21, and a capacitor 22.

The potential of one of a pair of electrodes of the liquid crystal element 23 is set in accordance with the specifications of the subpixel 14 appropriately. The alignment state of the liquid crystal element 23 depends on written data. A common potential (Vcom) may be applied to one of the pair of electrodes of the liquid crystal element 23 included in each of the plurality of subpixels 14. Furthermore, the potential applied to one of a pair of electrodes of the liquid crystal element 23 of the subpixel 14 in one row may be different from the potential applied to one of a pair of electrodes of the liquid crystal element 23 of the subpixel 14 in another row.

The liquid crystal element 23 is an element that has a function of controlling transmission and non-transmission of light by the optical modulation action of a liquid crystal. Note that the optical modulation action of a liquid crystal is controlled by an electric filed applied to the liquid crystal (including a horizontal electric field, a vertical electric field, and an oblique electric field). The following can be used for the liquid crystal element 23: a nematic liquid crystal, a cholesteric liquid crystal, a smectic liquid crystal, a thermotropic liquid crystal, a lyotropic liquid crystal, a ferroelectric liquid crystal, an anti-ferroelectric liquid crystal, and the like.

Examples of a method for driving the display device including the liquid crystal element 23 include a TN mode, a VA mode, an axially symmetric aligned micro-cell (ASM) mode, an optically compensated birefringence (OCB) mode, an MVA mode, a patterned vertical alignment (PVA) mode, an IPS mode, an FFS mode, and a transverse bend alignment (TBA) mode. Note that one embodiment of the present invention is not limited thereto, and various liquid crystal elements and driving methods can be used.

The liquid crystal element may be formed using a liquid crystal composition including a liquid crystal exhibiting a blue phase and a chiral material. The liquid crystal exhibiting a blue phase has a short response time of 1 ms or less. In addition, the liquid crystal exhibiting a blue phase is optically isotropic; therefore, alignment treatment is not necessary and viewing angle dependence is small.

In the subpixel 14 in FIG. 4B, one of a source electrode and a drain electrode of the transistor 21 is connected to the signal line 16, and the other of the source electrode and the drain electrode of the transistor 21 is connected to the other of the pair of electrodes of the liquid crystal element 23. A gate electrode of the transistor 21 is connected to the scan line 15. The transistor 21 has a function of controlling whether to write a data signal by being turned on or off.

In the subpixel 14 in FIG. 4B, one of a pair of electrodes of the capacitor 22 is connected to the capacitor line 25 to which a potential is applied, and the other of the pair of electrodes of the capacitor 22 is connected to the other of the pair of electrodes of the liquid crystal element 23. The potential of the capacitor line 17 is set in accordance with the specifications of the pixel 301 appropriately. The capacitor 22 functions as a storage capacitor for retaining written data.

For example, in the display device including the subpixel 14 in FIG. 4B, the subpixels 14 are sequentially selected row by row by the circuit 11, so that the transistors 21 are turned on and a data signal is written.

When the transistors 21 are turned off, the subpixels 14 to which the data has been written are brought into a holding state. This operation is sequentially performed row by row; thus, an image can be displayed.

As another example, the subpixel 14 illustrated in FIG. 4C is a subpixel included in a light-emitting display device. The subpixel 14 includes a transistor 31, a transistor 32, a transistor 34, a capacitor 33, and a light-emitting element 35.

One of a source electrode and a drain electrode of the transistor 31 is connected to the signal line 16 to which a data signal is supplied. A gate electrode of the transistor 31 is connected to the scan line 15.

The transistor 31 has a function of controlling whether to write a data signal by being turned on or off.

One of a source electrode and a drain electrode of the transistor 34 is connected to a wiring 37 serving as an anode line, and the other of the source electrode and the drain electrode of the transistor 34 is connected to one electrode of the light-emitting element 35. A gate electrode of the transistor 34 is connected to the other of the source and drain electrodes of the transistor 31 and one electrode of the capacitor 33.

The transistor 34 has a function of controlling the amount of current flowing through the light-emitting element 35 in accordance with data retained in the gate.

One of a source electrode and a drain electrode of the transistor 32 is connected to a wiring 36 to which a reference potential of data is applied, and the other of the source electrode and the drain electrode of the transistor 32 is connected to the one electrode of the light-emitting element 35 and the other electrode of the capacitor 33. A gate electrode of the transistor 32 is connected to the scan line 15.

The transistor 32 has a function of adjusting the current flowing through the light-emitting element 35. For example, when the internal resistance of the light-emitting element 35 increases because of deterioration or the like, the current flowing through the light-emitting element 35 can be corrected by monitoring current flowing through the wiring 36 to which one of the source and drain electrodes of the transistor 32 is connected. A potential that is applied to the wiring 36 can be, for example, 0 V.

One of a pair of electrodes of the capacitor 33 is connected to the other of the source electrode and the drain electrode of the transistor 31 and the gate electrode of the transistor 34. The other of the pair of electrodes of the capacitor 33 is connected to the other of the source electrode and the drain electrode of the transistor 34 and one electrode of the light-emitting element 35.

In the subpixel 14 in FIG. 4C, the capacitor 33 functions as a storage capacitor for retaining written data.

One of the pair of electrodes of the light-emitting element 35 is connected to the other of the source electrode and the drain electrode of the transistor 34, the other electrode of the capacitor 33, and the other of the source electrode and the drain electrode of the transistor 32. In addition, the other of the pair of electrodes of the light-emitting element 35 is connected to a wiring 38 that functions as a cathode.

As the light-emitting element 35, an organic electroluminescent element (also referred to as an organic EL element) or the like can be used, for example. Note that the light-emitting element 35 is not limited thereto and may be an inorganic EL element containing an inorganic material.

A high power supply potential VDD is applied to one of the wirings 37 and 38, and a low power supply potential VSS is applied to the other of the wirings 37 and 38. In the structure of FIG. 4C, the high power supply potential VDD is applied to the wiring 37 and the low power supply potential VSS is applied to the wiring 38.

In the display device including the subpixel 14 in FIG. 4C, the subpixels 14 are sequentially selected row by row by the circuit 11, so that the transistors 31 are turned on and a data signal is written.

When the transistors 31 are turned off, the subpixels 14 to which the data has been written are brought into a holding state. Moreover, the transistor 31 is connected to the capacitor 33; thus, the written data can be retained for a long time. Furthermore, the transistor 32 controls the amount of current that flows between the source electrode and the drain electrode of the transistor 32. The light-emitting element 35 emits light with luminance corresponding to the amount of flowing current. This operation is sequentially performed row by row; thus, an image can be displayed.

Note that although FIGS. 4B and 4C each illustrate an example in which the liquid crystal element 23 or the light-emitting element 35 is used as a display element, one embodiment of the present invention is not limited thereto. Any of a variety of display elements can be used. Examples of display elements include elements including a display medium whose contrast, luminance, reflectance, transmittance, or the like is changed by electromagnetic action, such as an EL (electroluminescent) element (e.g., an EL element including organic and inorganic materials, an organic EL element, or an inorganic EL element), an LED (e.g., a white LED, a red LED, a green LED, or a blue LED), a transistor (a transistor that emits light depending on current), an electron emitter, a liquid crystal element, electronic ink, an electrophoretic element, a grating light valve (GLV), a plasma display panel (PDP), a display element using a micro electro mechanical system (MEMS), a digital micromirror device (DMD), a digital micro shutter (DMS), an interferometric modulator display (IMOD) element, a MEMS shutter display element, an optical-interference-type MEMS display element, an electrowetting element, a piezoelectric ceramic display, and a carbon nanotube. Examples of display devices including EL elements include an EL display. Examples of display devices including electron emitters are a field emission display (FED) and an SED-type flat panel display (SED: surface-conduction electron-emitter display). Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples of a display device using electronic ink or electrophoretic elements include electronic paper. In the case of a transflective liquid crystal display or a reflective liquid crystal display, some of or all of pixel electrodes function as reflective electrodes. For example, some or all of pixel electrodes contain aluminum, silver, or the like. In such a case, a storage circuit such as an SRAM can be provided below the reflective electrodes, leading to lower power consumption.

<Structures over Element Substrate and Counter Substrate>

Next, the structures of a transistor and a capacitor included in a subpixel are described. In particular, one embodiment of the present invention features a structure in which the semiconductor film of the transistor included in each subpixel is an oxide semiconductor film and the electrode included in the capacitor is formed using a light-transmitting conductive film. In addition, in one embodiment of the present invention, the light-transmitting conductive film included in the capacitor can be formed using a material that can be formed without any increase in the number of steps. The structure of a subpixel including a transistor, a capacitor, and the like on the element substrate side and a color filter and the like on the counter substrate side is described in detail below.

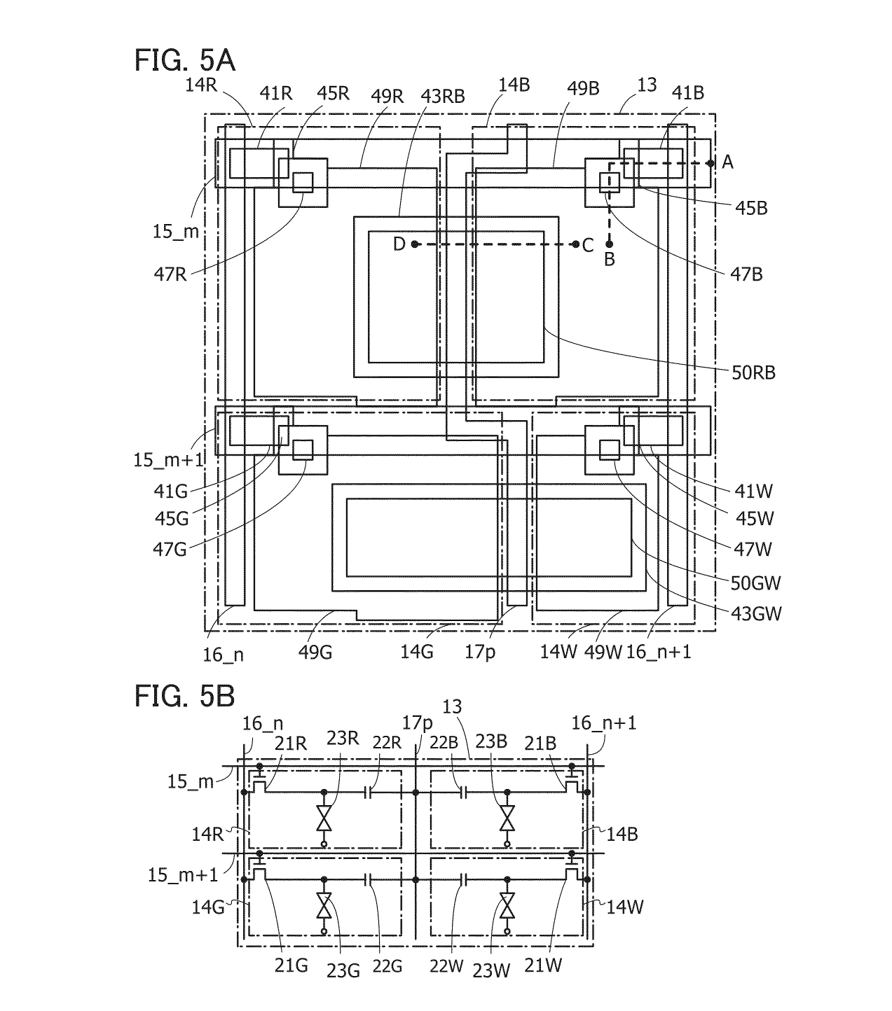

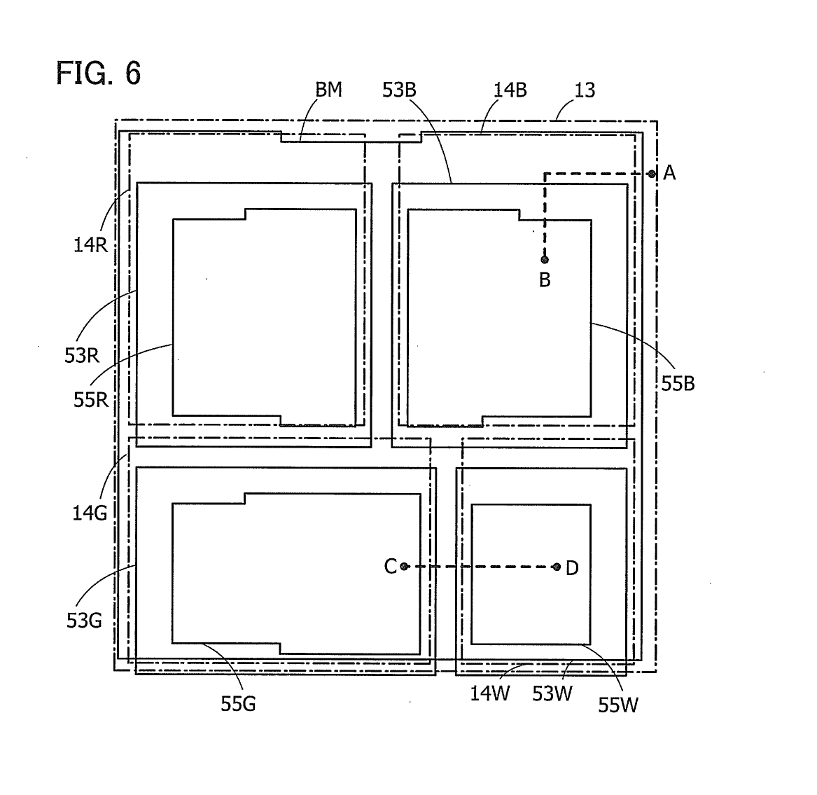

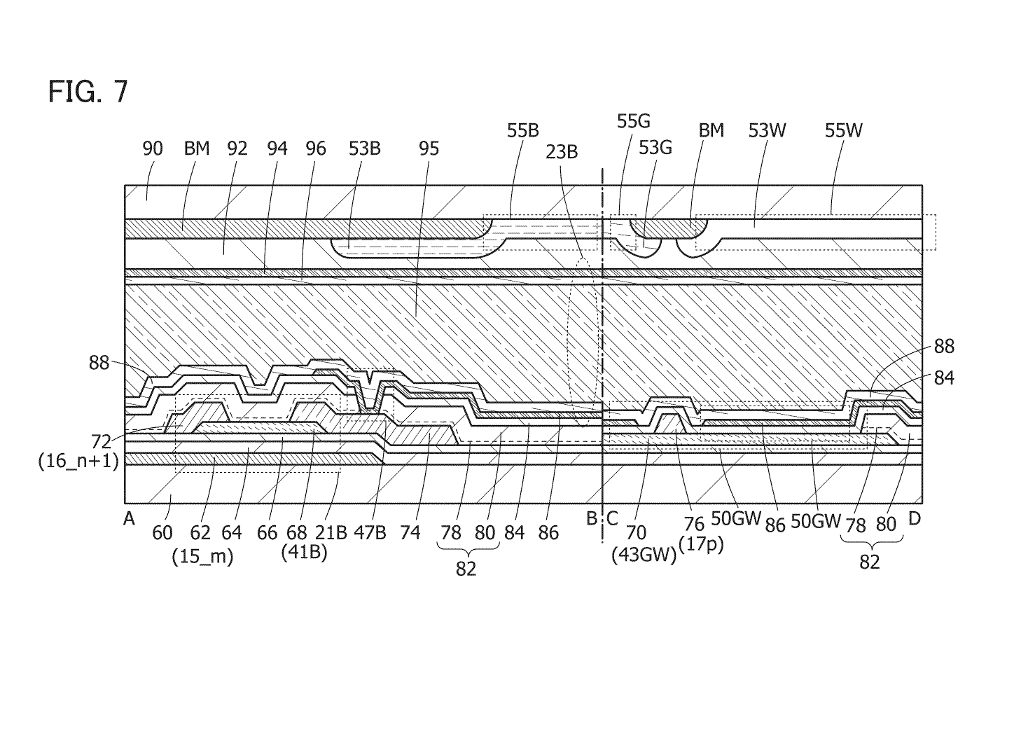

Note that in the following description, the display device is a liquid crystal display device. FIG. 5A is a top view illustrating the arrangement of components on the element substrate side in the pixel 13. FIG. 5B illustrates a circuit structure corresponding to the top view. FIG. 6 is a top view illustrating the arrangement of components on the counter substrate side that corresponds to the arrangement of components on the element substrate side in FIG. 5A. FIG. 7 illustrates cross-sectional views of the element substrate side in the top view of FIG. 5A and the counter substrate side in the top view of FIG. 6 taken along dashed line A-B and dashed line C-D.

In FIG. 5A, conductive films 15_{—}m and 15_{—}m+1 functioning as scan lines extend in a direction substantially perpendicular to a conductive film functioning as a signal line. Conductive films 16_{—}n and 16n+1 functioning as signal lines and a conductive film 17p functioning as a capacitor line extend in a direction substantially perpendicular to a conductive film functioning as a scan line. Note that the conductive films 15_{—}m and 15_{—}m+1 functioning as scan lines are connected to the circuit 11 functioning as a scan line driver circuit (see FIG. 4A). The conductive films 16_{—}n and 16n+1 functioning as signal lines are connected to the circuit 12 functioning as a signal line driver circuit (see FIG. 4A). The conductive film 17p functioning as a capacitor line is connected to a circuit (not illustrated) for applying a constant potential.

In the top view of FIG. 5A, an arrangement example of the subpixel 14R, the subpixel 14G, the subpixel 14B, and the subpixel 14W included in the pixel 13 is shown. The subpixel 14R includes an oxide semiconductor film 41R, a conductive film 45R, an opening 47R, a conductive film 49R, a metal oxide film 43RB, and an opening 50RB. The subpixel 14G includes an oxide semiconductor film 41G, a conductive film 45G, an opening 47G, a conductive film 49G, a metal oxide film 43GW, and an opening 50GW. The subpixel 14B includes an oxide semiconductor film 41B, a conductive film 45B, an opening 47B, a conductive film 49B, a metal oxide film 43RB, and an opening 50RB. The subpixel 14W includes an oxide semiconductor film 41W, a conductive film 45W, an opening 47W, a conductive film 49W, a metal oxide film 43GW, and an opening 50GW.

In FIG. 5B, a circuit structure example of the subpixel 14R, the subpixel 14G, the subpixel 14B, and the subpixel 14W included in the pixel 13 that corresponds to the top view of FIG. 5A is shown. The subpixel 14R includes a transistor 21R, a capacitor 22R, and a liquid crystal element 23R. The subpixel 14G includes a transistor 21G, a capacitor 22G, and a liquid crystal element 23G. The subpixel 14B includes a transistor 21B, a capacitor 22B, and a liquid crystal element 23B. The subpixel 14W includes a transistor 21W, a capacitor 22W, and a liquid crystal element 23W.

The transistor 21R (21G, 21B, or 21W) in FIG. 5B is provided at an intersection of the conductive film functioning as a scan line and the conductive film functioning as a signal line. The transistor 21R (21G, 21B, or 21W) includes the conductive film 15_{—}m (or 15_{—}m+1) functioning as a gate electrode, a gate insulating film (not illustrated in FIG. 5A), the oxide semiconductor film 41R (41G, 41B, or 41W) that is formed over the gate insulating film and provided with a channel region, a pair of conductive films 16_{—}n (or 16_{—}n+1) functioning as a source electrode and a drain electrode, and a conductive film 45R (45G, 45B, or 45W).

Note that the conductive film 15_{—}m (or 15_{—}m+1) also functions as a scan line, and a region of the conductive film 15_{—}m (or 15_{—}m+1) that overlaps the oxide semiconductor film 41R (41G, 41B, or 41W) functions as the gate electrode of the transistor 21R (21G, 21B, or 21W). The conductive film 16_{—}n (or 16n+1) functions as a signal line, and a region of the conductive film 16_{—}n (or 16_{—}n+1) that overlaps the oxide semiconductor film 41R (41G, 41B, or 41W) functions as the source electrode or the drain electrode of the transistor 21R (21G, 21B, or 21W). Furthermore, in the top view of FIG. 5A, an end portion of the conductive film functioning as a scan line is located on the outer side of an end portion of the oxide semiconductor film 41R (41G, 41B, or 41W). Thus, the conductive film functioning as a scan line functions as a light-blocking film for blocking light from a light source such as a backlight. For this reason, the oxide semiconductor film 41R (41G, 41B, or 41W) included in the transistor is not irradiated with light, so that changes in the electrical characteristics of the transistor can be suppressed.

Over the metal oxide film 43RB (or 43GW), the conductive film 49R (49G, 49B, or 49W) is provided with an insulating film positioned therebetween. In the insulating film provided over the metal oxide film 43RB (or 43GW), the opening 50RB (or 50GW) is provided. Through the opening 50RB (or 50GW), the metal oxide film 43RB (or 43GW) is in contact with a nitride insulating film (not illustrated in FIGS. 5A and 5B) included in the insulating film.

The capacitor 22R (22G, 22B, or 22W) is formed in a region where the metal oxide film 43RB (or 43GW) overlaps the conductive film 49R (49G, 49B, or 49W). The metal oxide film 43RB (or 43GW) and the conductive film 49R (49G, 49B, or 49W) have light-transmitting properties. In other words, the capacitor 22R (22G, 22B, or 22W) has a light-transmitting property.

The conductive film 49R (49G, 49B, or 49W) functions as a pixel electrode. The conductive film 49R (49G, 49B, or 49W) is connected to the conductive film 45R (45G, 45B, or 45W) through the opening 47R (47G, 47B, or 47W). In other words, the transistor 21R (21G, 21B, or 21W), the capacitor 22R (22G, 22B, or 22W), and the conductive film 49R (49G, 49B, or 49W) are connected to each other.

Owing to the light-transmitting property of the capacitor 22R (22G, 22B, or 22W), the capacitor 22R (22G, 22B, or 22W) can be formed large (in a large area) in the subpixel 14R (14G, 14B, or 14W). Accordingly, a display device having capacitance increased while increasing the aperture ratio, typically 50% or more, preferably 60% or more can be provided. For example, in a high-resolution display device such as a liquid crystal display device, the area of a pixel is small and thus the area of a capacitor is also small. For this reason, the amount of charge stored in the capacitor is small in the high-resolution display device. However, since the capacitor 22R (22G, 22B, or 22W) in this embodiment transmits light, when the capacitor is provided in a pixel, enough capacitance can be obtained in the pixel and the aperture ratio can be increased. Typically, the capacitor 22R (22G, 22B, or 22W) can be favorably used for a high-resolution display device with a pixel density of 100 ppi or more, 200 ppi or more, or 300 ppi or more.

In a liquid crystal display device, as the capacitance of a capacitor is increased, a period during which the alignment of liquid crystal molecules of a liquid crystal element can be kept constant in the state where an electric field is applied can be made longer. When the period can be made longer in the case of displaying a still image, the rewriting number of image data can be reduced, leading to a reduction in power consumption. Furthermore, according to the structure of this embodiment, the aperture ratio can be increased even in a high-resolution display device, which makes it possible to use light from a light source such as a backlight efficiently, so that the power consumption of the display device can be reduced.

In FIG. 5B, the transistor 21R (21G, 21B, or 21W) has the gate on at least one side of a semiconductor film; alternatively, the transistor 21R (21G, 21B, or 21W) may have a pair of gates with a semiconductor film positioned therebetween. When one of the pair of gates is regarded as a back gate, potentials at the same level may be applied to a normal gate and the back gate, or a constant potential such as a ground potential may be applied only to the back gate. By controlling the level of the potential applied to the back gate, the threshold voltage of the transistor can be controlled. By providing the back gate, a channel formation region is enlarged and drain current can be increased. Furthermore, the back gate facilitates formation of a depletion layer in the semiconductor film, which results in lower subthreshold swing.

In FIG. 5B, the transistor 21R (21G, 21B, or 21W) has a single-gate structure including one gate and one channel formation region; however, one embodiment of the present invention is not limited to this structure. The transistor 21R (21G, 21B, or 21W) may have a multi-gate structure including a plurality of gates connected to each other and a plurality of channel formation regions.

In the top view of FIG. 6 that corresponds to the top view of the counter substrate side of FIG. 5A, an arrangement example of the subpixel 14R, the subpixel 14G, the subpixel 14B, and the subpixel 14W included in the pixel 13 is shown. The subpixel 14R includes a color filter 53R and an opening 55R. The subpixel 14G includes a color filter 53G and an opening 55G. The subpixel 14B includes a color filter 53B and an opening 55B. The subpixel 14W includes a light-transmitting layer 53W and an opening 55W.

The color filter 53R (53G or 53B) is a layer for converting light to be transmitted from a light source into light of a predetermined color. The opening 55R (55G or 55B) makes the color filter 53R (53G or 53B) transmit light.

The light-transmitting layer 53W transmits light from a light source. The opening 55W makes the light-transmitting layer 53W transmit light.

Next, FIG. 7 is a cross-sectional view taken along dashed line A-B and dashed line C-D in FIG. 5A and FIG. 6.

Here, each component between the substrate 60 that is an element substrate and the substrate 90 that is a counter substrate in FIG. 7 is described below.

First, each component over the substrate 60 that is an element substrate is described.

Over the substrate 60, a conductive film 62 is formed. The conductive film 62 corresponds to the conductive film 15_{—}m and functions as the gate electrode of the transistor 21B.

There is no particular limitation on the material and the like of the substrate 60 as long as the material has heat resistance high enough to withstand at least heat treatment performed later. For example, a glass substrate, a ceramic substrate, a quartz substrate, or a sapphire substrate may be used as the substrate 60. Alternatively, a single crystal semiconductor substrate or a polycrystalline semiconductor substrate made of silicon, silicon carbide, or the like, a compound semiconductor substrate made of silicon germanium or the like, an SOI substrate, or the like can be used as the substrate 60. Alternatively, any of these substrates provided with a semiconductor element may be used as the substrate 60. In the case where a glass substrate is used as the substrate 60, a large-area glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm); thus, a large display device can be manufactured.

Alternatively, a flexible substrate may be used as the substrate 60, and the transistor may be provided directly on the flexible substrate. Alternatively, a separation layer may be provided between the substrate 60 and the transistor. The separation layer can be used when part or all of an element portion formed over the separation layer is completed, separated from the substrate 60, and then transferred to another substrate. In such a case, the transistor can be transferred to a substrate having low heat resistance or a flexible substrate.

For the conductive film 62, a metal element selected from aluminum, chromium, copper, tantalum, titanium, molybdenum, or tungsten; an alloy containing any of these metal elements as a component; an alloy containing these metal elements in combination; or the like can be used. Alternatively, one or more metal elements selected from manganese or zirconium may be used. The conductive film 62 may have a single-layer structure or a layered structure including two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, or a three-layer structure in which a titanium film, an aluminum film, and a titanium film are stacked in that order can be used. Alternatively, an alloy film or a nitride film that contains aluminum and one or more elements selected from titanium, tantalum, tungsten, molybdenum, chromium, neodymium, or scandium may be used.

The conductive film 62 can be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to use a layered structure formed using the light-transmitting conductive material and the metal element.

Insulating films 64 and 66 are formed over the substrate 60 and the conductive film 62. The insulating films 64 and 66 function as a gate insulating film of the transistor 21B.

The insulating film 64 is preferably formed using a nitride insulating film containing silicon nitride, silicon nitride oxide, aluminum nitride, or aluminum nitride oxide, for example.

The insulating film 66 may be formed to have a single-layer structure or a layered structure using, for example, any of silicon oxide, silicon oxynitride, silicon nitride oxide, silicon nitride, aluminum oxide, hafnium oxide, gallium oxide, and a Ga—Zn-based metal oxide. Alternatively, the insulating film 66 may be formed using a high-k material such as hafnium silicate (HfSiaₓ), hafnium silicate to which nitrogen is added (HfSiₓO_{y}N_{z}), hafnium aluminate to which nitrogen is added (HfAlₓO_{y}N_{z}), hafnium oxide, or yttrium oxide, so that gate leakage of the transistor can be reduced.

The total thickness of the insulating films 64 and 66 is 5 to 400 nm, preferably 10 to 300 nm, more preferably 50 to 250 nm.

The oxide semiconductor film 68 and the metal oxide film 70 are formed over the insulating film 66. The oxide semiconductor film 68 corresponds to the oxide semiconductor film 41B, is formed in a position overlapping the conductive film 62, and functions as a channel region of the transistor 21B. The metal oxide film 70 is connected to a conductive film 76 and functions as electrodes of the capacitors 22G and 22W. Note that the conductive film 76 corresponds to the conductive film 17p that functions as a capacitor line.

The oxide semiconductor film 68 and the metal oxide film 70 are each typically an In—Ga oxide film, an In—Zn oxide film, or an In-M-Zn oxide film (M represents Al, Ti, Ga, Y, Zr, La, Ce, Nd, Sn, or Hf). Note that the oxide semiconductor film 68 and the metal oxide film 70 have light-transmitting properties.

Note that in the case where the oxide semiconductor film 68 and the metal oxide film 70 are each an In-M-Zn oxide film, when summation of In and M is assumed to be 100 atomic %, the proportions of In and M, not taking Zn and O into consideration, are greater than or equal to 25 atomic % and less than 75 atomic %, respectively, preferably greater than or equal to 34 atomic % and less than 66 atomic %, respectively.

The energy gap of each of the oxide semiconductor film 68 and the metal oxide film 70 is 2 eV or more, preferably 2.5 eV or more, more preferably 3 eV or more. In this manner, the off-state current of a transistor can be reduced by using an oxide semiconductor having a wide energy gap.

The thickness of each of the oxide semiconductor film 68 and the metal oxide film 70 is 3 to 200 nm, preferably 3 to 100 nm, more preferably 3 to 50 nm.

For each of the oxide semiconductor film 68 and the metal oxide film 70, an In—Ga—Zn oxide with an atomic ratio of In:Ga:Zn=1:1:1, 1:1:1.2, or 3:1:2 can be used. Note that the atomic ratio of each of the oxide semiconductor film 68 and the metal oxide film 70 varies within a range of ±20% of the above atomic ratio as an error.

The oxide semiconductor film 68 and the metal oxide film 70 may each have a non-single crystal structure, for example. The non-single crystal structure includes a c-axis aligned crystalline oxide semiconductor (CAAC-OS) described later, a polycrystalline structure, a microcrystalline structure described later, or an amorphous structure, for example. Among the non-single crystal structures, the amorphous structure has the highest density of defect states, whereas CAAC-OS has the lowest density of defect states. Note that the oxide semiconductor film 68 and the metal oxide film 70 have the same crystallinity.

Note that each of the oxide semiconductor film 68 and the metal oxide film 70 may be a mixed film including two or more of the following: a region having an amorphous structure, a region having a microcrystalline structure, a region having a polycrystalline structure, a CAAC-OS region, and a region having a single-crystal structure. Furthermore, the mixed film has a layered structure of two or more of a region having an amorphous structure, a region having a microcrystalline structure, a region having a polycrystalline structure, a CAAC-OS region, and a region having a single-crystal structure in some cases.

When silicon or carbon, which is one of elements belonging to Group 14, is contained in the oxide semiconductor film 68, oxygen vacancies are increased in the oxide semiconductor film 68, and the oxide semiconductor film 68 becomes n-type. Thus, the concentration of silicon or carbon (the concentration is measured by SIMS) of the oxide semiconductor film 68 is lower than or equal to 2×10¹⁸ atoms/cm³, preferably lower than or equal to 2×10¹⁷ atoms/cm³.

Furthermore, the concentration of alkali metal or alkaline earth metal of the oxide semiconductor film 68 that is measured by SIMS is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, which may increase the off-state current of the transistor. Thus, it is preferable to reduce the concentration of alkali metal or alkaline earth metal of the oxide semiconductor film 68.

When nitrogen is contained in the oxide semiconductor film 68, electrons serving as carriers are generated and carrier density increases, so that the oxide semiconductor film 68 easily becomes n-type. Thus, a transistor including an oxide semiconductor that contains nitrogen is likely to be normally on. For this reason, nitrogen in the oxide semiconductor film is preferably reduced as much as possible; the concentration of nitrogen that is measured by SIMS is preferably, for example, lower than or equal to 5×10¹⁸ atoms/cm³.

An oxide semiconductor film with low carrier density is used as the oxide semiconductor film 68. For example, an oxide semiconductor film whose carrier density is lower than or equal to 1×10¹⁷/cm³, preferably 1×10¹⁵/cm³ or less, further preferably 1×10¹³/cm³ or less, particularly preferably lower than 8×10¹¹/cm³, still further preferably lower than 1×10¹¹/cm³, yet further preferably lower than 1×10¹⁰/cm³, and is 1×10⁻⁹/cm³ or higher is used as the oxide semiconductor film 68.

Note that, without limitation on those described above, a material with an appropriate composition may be used depending on required semiconductor characteristics and electrical characteristics (e.g., field-effect mobility and threshold voltage) of a transistor. Furthermore, to obtain required semiconductor characteristics of a transistor, it is preferable that carrier density, impurity concentration, defect density, the atomic ratio of a metal element to oxygen, interatomic distance, density, and the like of the oxide semiconductor film 68 be set appropriate.

The oxide semiconductor film 68 is in contact with films each formed using a material that can improve characteristics of an interface with the oxide semiconductor film, such as the insulating films 66 and 78. Thus, the oxide semiconductor film 68 functions as a semiconductor, so that a transistor including the oxide semiconductor film 68 has excellent electrical characteristics.

Note that it is preferable to use, as the oxide semiconductor film 68, an oxide semiconductor film in which impurity concentration is low and density of defect states is low because the transistor can have excellent electrical characteristics. Here, a state in which impurity concentration is low and density of defect states is low (the number of oxygen vacancies is small) is referred to as “highly purified intrinsic” or “substantially highly purified intrinsic.” A highly purified intrinsic or substantially highly purified intrinsic oxide semiconductor has few carrier generation sources, and thus has low carrier density in some cases. Thus, in some cases, a transistor in which a channel region is formed in the oxide semiconductor film rarely has negative threshold voltage (is rarely normally on). A highly purified intrinsic or substantially highly purified intrinsic oxide semiconductor film has low density of defect states, and thus has low density of trap states in some cases. Furthermore, the highly purified intrinsic or substantially highly purified intrinsic oxide semiconductor film has extremely low off-state current. Even when an element has a channel width of 1×10⁶ μm and a channel length of 10 μm, off-state current can be lower than or equal to the measurement limit of a semiconductor parameter analyzer, i.e. lower than or equal to 1×10⁻¹³ A, at a voltage (drain voltage) between a source electrode and a drain electrode of 1 to 10 V. Thus, the transistor whose channel region is formed in the oxide semiconductor film has few variations in electrical characteristics and high reliability in some cases. Charge trapped by the trap states in the oxide semiconductor film takes a long time to be released and may behave like fixed charge. Thus, the transistor whose channel region is formed in the oxide semiconductor film having high density of trap states has unstable electrical characteristics in some cases. Examples of the impurities include hydrogen, nitrogen, alkali metal, and alkaline earth metal.

The metal oxide film 70 is formed by processing an oxide semiconductor film formed at the same time as the oxide semiconductor film 68. Thus, the metal oxide film 70 contains a metal element similar to that in the oxide semiconductor film 68. Furthermore, the metal oxide film 70 has a crystal structure similar to or different from that of the oxide semiconductor film 68. By adding impurities or oxygen vacancies to the oxide semiconductor film formed at the same time as the oxide semiconductor film 68, the metal oxide film 70 has conductivity and thus functions as an electrode of a capacitor. An example of the impurities contained in the oxide semiconductor film is hydrogen. Instead of hydrogen, as the impurity, boron, phosphorus, tin, antimony, a rare gas element, alkali metal, alkaline earth metal, or the like may be contained. Alternatively, the metal oxide film 70 is formed at the same time as the oxide semiconductor film 68 and has increased conductivity by including oxygen vacancies generated by plasma damage or the like. Alternatively, the metal oxide film 70 is formed at the same time as the oxide semiconductor film 68 and has increased conductivity by containing an impurity and including oxygen vacancies generated by plasma damage or the like.

In an oxide semiconductor including oxygen vacancies, hydrogen enters oxygen vacant sites and forms a donor level in the vicinity of the conduction band. As a result, the conductivity of the oxide semiconductor is increased, so that the oxide semiconductor becomes a conductor. The oxide semiconductor that becomes a conductor is referred to as an oxide conductor as well as a metal oxide film. Oxide semiconductors generally transmit visible light because of their large energy gap. An oxide conductor is an oxide semiconductor having a donor level in the vicinity of the conduction band. Thus, the influence of absorption due to the donor level is small, and an oxide conductor has a visible light-transmitting property comparable to that of an oxide semiconductor.

The oxide semiconductor film 68 and the metal oxide film 70 are formed over the insulating film 66 and have different impurity concentrations. Specifically, the metal oxide film 70 has higher impurity concentration than the oxide semiconductor film 68. For example, the concentration of hydrogen contained in the oxide semiconductor film 68 is lower than 5×10¹⁹ atoms/cm³, preferably lower than 5×10¹⁸ atoms/cm³, more preferably lower than or equal to 1×10¹⁸ atoms/cm³, much more preferably lower than or equal to 5×10¹⁷ atoms/cm³, still more preferably lower than or equal to 1×10¹⁶ atoms/cm³. The concentration of hydrogen contained in the metal oxide film 70 is higher than or equal to 8×10¹⁹ atoms/cm³, preferably higher than or equal to 1×10²⁰ atoms/cm³, more preferably higher than or equal to 5×10²⁰ atoms/cm³. The concentration of hydrogen contained in the metal oxide film 70 is twice or more, preferably 10 times or more that in the oxide semiconductor film 68.

By exposing the oxide semiconductor film formed at the same time as the oxide semiconductor film 68 to plasma, the oxide semiconductor film can be damaged, so that oxygen vacancies can be formed. For example, when a film is formed over the oxide semiconductor film by plasma-enhanced CVD or sputtering, the oxide semiconductor film is exposed to plasma and oxygen vacancies are generated. Alternatively, when the oxide semiconductor film is exposed to plasma in etching treatment for formation of an insulating film 84, oxygen vacancies are generated. Alternatively, when the oxide semiconductor film is exposed to plasma of, for example, hydrogen, a rare gas, ammonia, a mixed gas of oxygen and hydrogen, oxygen vacancies are generated. As a result, the conductivity of the oxide semiconductor film is increased, so that the oxide semiconductor film has conductivity and functions as the metal oxide film 70.

In other words, the metal oxide film 70 is formed using an oxide semiconductor film having high conductivity. It can also be said that the metal oxide film 70 is formed using a metal oxide film having high conductivity.

In the case where a silicon nitride film is used as the insulating film 84, the silicon nitride film contains hydrogen. Thus, when hydrogen in the insulating film 84 is diffused into the oxide semiconductor film formed at the same time as the oxide semiconductor film 68, hydrogen is bonded to oxygen and electrons serving as carriers are generated in the oxide semiconductor film. When the silicon nitride film is formed by plasma-enhanced CVD or sputtering, the oxide semiconductor film is exposed to plasma and oxygen vacancies are generated in the oxide semiconductor film. When hydrogen contained in the silicon nitride film enters the oxygen vacancies, electrons serving as carriers are generated. As a result, the conductivity of the oxide semiconductor film is increased, so that the oxide semiconductor film becomes the metal oxide film 70.

The metal oxide film 70 has lower resistivity than the oxide semiconductor film 68. The resistivity of the metal oxide film 70 is preferably greater than or equal to 1×10⁻⁸ times and less than 1×10⁻¹ times the resistivity of the oxide semiconductor film 68. The resistivity of the metal oxide film 70 is typically greater than or equal to 1×10⁻³ Ωcm and less than 1×10⁴ Ωcm, preferably greater than or equal to 1×10⁻³ Ωcm and less than 1×10⁻¹ Ωcm.

Note that one embodiment of the present invention is not limited thereto, and it is possible that the metal oxide film 70 be not in contact with the insulating film 84 depending on circumstances.

Furthermore, one embodiment of the present invention is not limited thereto, and the metal oxide film 70 may be formed by a process different from that of the oxide semiconductor film 68 depending on circumstances. In that case, the metal oxide film 70 may include a material different from that of the oxide semiconductor film 68. For example, the metal oxide film 70 may include indium tin oxide (hereinafter referred to as ITO) or indium zinc oxide.

In the display device in this embodiment, a capacitor has light-transmitting properties. Thus, the region occupied by the capacitor in a subpixel can be a light-transmitting region, so that the aperture ratio of the subpixel can be increased while the occupation area of the capacitor is increased.

The conductive films 72, 74, and 76 are formed to have a single-layer structure or a layered structure including, as a conductive material, any of metals such as aluminum, titanium, chromium, nickel, copper, yttrium, zirconium, molybdenum, silver, tantalum, and tungsten or an alloy containing any of these metals as its main component. For example, a single-layer structure of an aluminum film containing silicon, a two-layer structure in which a titanium film is stacked over an aluminum film, a two-layer structure in which a titanium film is stacked over a tungsten film, a two-layer structure in which a copper film is stacked over a copper-magnesium-aluminum alloy film, a three-layer structure in which a titanium film or a titanium nitride film, an aluminum film or a copper film, and a titanium film or a titanium nitride film are stacked in that order, a three-layer structure in which a molybdenum film or a molybdenum nitride film, an aluminum film or a copper film, and a molybdenum film or a molybdenum nitride film are stacked in that order, or the like can be used. Note that a transparent conductive material containing indium oxide, tin oxide, or zinc oxide may be used.

The insulating films 82 and 84 are formed over the insulating film 66, the oxide semiconductor film 68, the metal oxide film 70, and the conductive films 72, 74, and 76. For the insulating film 82, in a manner similar to that of the insulating film 66, a material that can improve characteristics of the interface with the oxide semiconductor film is preferably used. The insulating film 82 can be formed using an oxide insulating film. Here, the insulating film 82 is formed by stacking insulating films 78 and 80.

The insulating film 78 is an oxide insulating film through which oxygen is passed. Note that the insulating film 78 also functions as a film that relieves damage to the oxide semiconductor film 68 and the metal oxide film 70 at the time of forming the insulating film 80 later.

As the insulating film 78, a silicon oxide film, a silicon oxynitride film, or the like with a thickness of 5 to 150 nm, preferably 5 to 50 nm can be used. In this specification, a silicon oxynitride film means a film that includes more oxygen than nitrogen, and a silicon nitride oxide film means a film that includes more nitrogen than oxygen.

The insulating film 78 is an oxide insulating film. The oxide insulating film preferably contains nitrogen and has a small number of defects.

Typical examples of the oxide insulating film containing nitrogen and having a small number of defects include a silicon oxynitride film and an aluminum oxynitride film.

In an ESR spectrum at 100 K or lower of the oxide insulating film with a small number of defects, a first signal that appears at a g-factor of greater than or equal to 2.037 and less than or equal to 2.039, a second signal that appears at a g-factor of greater than or equal to 2.001 and less than or equal to 2.003, and a third signal that appears at a g-factor of greater than or equal to 1.964 and less than or equal to 1.966 are observed. The distance between the first and second signals and the distance between the second and third signals that are obtained by ESR measurement using an X-band are each approximately 5 mT. The spin density at a g-factor in the range from 2.037 or more and 2.039 or less to 1.964 or more and 1.966 or less is lower than 1×10¹⁸ spins/cm³, typically higher than or equal to 1×10¹⁷ spins/cm³ and lower than 1×10¹⁸ spins/cm³.

In the ESR spectrum at 100 K or lower, the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 correspond to signals attributed to nitrogen oxide (NOₓ; x is greater than or equal to 0 and less than or equal to 2, preferably greater than or equal to 1 and less than or equal to 2). Typical examples of nitrogen oxide include nitrogen monoxide and nitrogen dioxide. In other words, the lower the spin density at a g-factor in the range from 2.037 or more and 2.039 or less to 1.964 or more and 1.966 or less is, the smaller amount of nitrogen oxide the oxide insulating film contains.

When the insulating film 78 contains a small amount of nitrogen oxide as described above, the carrier trap at the interface between the insulating film 78 and the oxide semiconductor film can be inhibited. Thus, a change in the threshold voltage of the transistor can be reduced, which leads to a reduced change in the electrical characteristics of the transistor.

The insulating film 78 preferably has a nitrogen concentration measured by secondary ion mass spectrometry (SIMS) of lower than or equal to 6×10²⁰ atoms/cm³. In that case, nitrogen oxide is unlikely to be generated in the insulating film 78, so that the carrier trap at the interface between the insulating film 78 and the oxide semiconductor film 68 can be inhibited. Furthermore, a change in the threshold voltage of the transistor can be reduced, which leads to a reduced change in the electrical characteristics of the transistor.

Note that when the insulating film 78 contains nitrogen oxide and ammonia, nitrogen oxide and ammonia react with each other in heat treatment in a manufacturing step and a nitrogen gas formed by the reaction of nitrogen oxide is released. As a result, the nitrogen concentration and the content of nitrogen oxide in the insulating film 78 can be reduced. Furthermore, the carrier trap at the interface between the insulating film 78 and the oxide semiconductor film 68 can be inhibited. Furthermore, a change in the threshold voltage of the transistor can be reduced, which leads to a reduced change in the electrical characteristics of the transistor.

Note that in the insulating film 78, all oxygen entering the insulating film 78 from the outside does not move to the outside of the insulating film 78 and some oxygen remains in the insulating film 78. Furthermore, movement of oxygen occurs in the insulating film 78 in some cases in such a manner that oxygen enters the insulating film 78 and oxygen contained in the insulating film 78 is moved to the outside of the insulating film 78.

When the oxide insulating film through which oxygen is passed is formed as the insulating film 78, oxygen released from the insulating film 80 provided over the insulating film 78 can be moved to the oxide semiconductor film 68 through the insulating film 78.

The insulating film 80 is in contact with the insulating film 78. The insulating film 80 is preferably formed using an oxide insulating film that contains oxygen at higher proportion than the stoichiometric composition. Part of oxygen is released by heating from the oxide insulating film containing oxygen at higher proportion than the stoichiometric composition. The oxide insulating film containing oxygen at higher proportion than the stoichiometric composition is an oxide insulating film in which the amount of released oxygen converted into oxygen atoms is greater than or equal to 1.0×10¹⁸ atoms/cm³, preferably greater than or equal to 3.0×10²⁰ atoms/cm³ in TDS analysis. Note that the surface temperature of the film in the TDS analysis is preferably higher than or equal to 100° C. and lower than or equal to 700° C., or higher than or equal to 100° C. and lower than or equal to 500° C.

A silicon oxide film, a silicon oxynitride film, or the like with a thickness 30 to 500 nm, preferably 50 to 400 nm can be used as the insulating film 80.

Furthermore, it is preferable that the number of defects in the insulating film 80 be small, typically the spin density of a signal that appears at g=2.001 due to a dangling bond of silicon, be lower than 1.5×10¹⁸ spins/cm³, preferably lower than or equal to 1×10¹⁸ spins/cm³ by ESR measurement. Note that the insulating film 80 is provided more distant from the oxide semiconductor film 68 than the insulating film 78 is; thus, the insulating film 80 may have higher defect density than the insulating film 78.

It is possible to prevent outward diffusion of oxygen from the oxide semiconductor film 68 and the metal oxide film 70 by providing a nitride insulating film having a blocking effect against oxygen, hydrogen, water, alkali metal, alkaline earth metal, and the like as the insulating film 84. The nitride insulating film is formed using silicon nitride, silicon nitride oxide, aluminum nitride, aluminum nitride oxide, or the like.

Note that over the nitride insulating film having a blocking effect against oxygen, hydrogen, water, alkali metal, alkaline earth metal, and the like, an oxide insulating film having a blocking effect against oxygen, hydrogen, water, and the like, may be provided. As the oxide insulating film having a blocking effect against oxygen, hydrogen, water, and the like, an aluminum oxide film, an aluminum oxynitride film, a gallium oxide film, a gallium oxynitride film, an yttrium oxide film, an yttrium oxynitride film, a hafnium oxide film, a hafnium oxynitride film, or the like can be used. To control the capacitance of the capacitor, a nitride insulating film or an oxide insulating film may be provided over the nitride insulating film having a blocking effect against oxygen, hydrogen, water, alkali metal, alkaline earth metal, and the like, as appropriate.

A conductive film 86 is formed over the insulating film 84. The conductive film 86 functions as a pixel electrode and an electrode of the capacitor. The conductive film 86 is connected to the conductive film 74 through the opening 47B (see FIG. 5A).

The conductive film 86 can be formed using a conductive material having a light-transmitting property. For the conductive film 86, indium oxide including tungsten oxide, indium zinc oxide including tungsten oxide, indium oxide including titanium oxide, indium tin oxide including titanium oxide, ITO, indium zinc oxide, indium tin oxide to which silicon oxide is added, or the like can be used.

An alignment film 88 is formed over the conductive films 84 and 86. The alignment film 88 preferably has a light-transmitting property and can be formed. The alignment film 320 preferably has a light-transmitting property and can be formed using, typically, an organic resin such as an acrylic resin, polyimide, or an epoxy resin.

The above is the description of each component over the substrate 60 that is an element substrate.

Then, each component over the substrate 90 that is a counter substrate is described.

Light-blocking films BM are provided on the substrate 90, and color filters 53B and 53G and a light-transmitting layer 53W are formed in the openings 55B, 55G, and 55W provided in the light-blocking film.

The color filter 53R (53G or 53B) transmits light in a specific wavelength range. For example, a color filter for transmitting light in a red wavelength range, a color filter for transmitting light in a green wavelength range, a color filter for transmitting light in a blue wavelength range, or the like can be used.

The light-blocking film BM has a function of blocking light in a specific wavelength range, and can be a metal film or an organic insulating film including a black pigment or the like.

The light-transmitting layer 53W preferably has a light-transmitting property and can be formed using, typically, an organic resin such as an acrylic resin, polyimide, or an epoxy resin. Alternatively, the light-transmitting layer 53W may be formed using a conductive material having a light-transmitting property, or may be formed using a stack of a conductive material having a light-transmitting property and an organic resin. Note that the organic resin may contain a metal element. As a layer including the light-transmitting layer 53W, a layer that absorbs light at particular wavelength may be provided. This structure enables, for example, display with high color purity even when appropriate white light is not obtained depending on the wavelength of light from a light source because white balance can be adjusted.

An insulating film 92 is formed on the color filters 53R, 53B, and 53G and the light-transmitting layer 53W. The insulating film 92 functions as a planarization layer or has a function of inhibiting diffusion of impurities that might be contained in the color filters 53R, 53B, and 53G and the light-transmitting layer 53W into the liquid crystal element 23B side. Note that it is preferable that the color filters 53R, 53B, and 53G and the light-transmitting layer 53W not overlap each other on the light-blocking films BM. This structure can improve the flatness of the surface of a conductive film 94.

The conductive film 94 is formed on the insulating film 92. The conductive film 94 functions as the other of the pair of electrodes of the liquid crystal element in the pixel portion. Note that the conductive film 94 can be using the same material as the conductive film 86.

An alignment film 96 is formed on the conductive film 94. The alignment film 96 can be using the same material as the conductive film 88.

A liquid crystal layer 95 is formed between the conductive film 86 and the conductive film 94. The liquid crystal layer 95 is sealed between the substrate 60 and the substrate 90 with a sealant (not illustrated). Note that the sealant is preferably in contact with an inorganic material to inhibit entry of moisture and the like from the outside.

A spacer may be provided between the conductive films 86 and 94 to maintain the thickness of the liquid crystal layer 95 (also referred to as a cell gap).

The above is the description of each component over the substrate 90 that is a counter substrate.

The semiconductor film of the transistor included in each subpixel is an oxide semiconductor film and the electrode included in the capacitor is formed using a light-transmitting conductive film. In this structure, the capacitor can transmit light; thus, the apparent occupation area of the capacitor in the subpixel can be small. In the case where the pixel includes R, G, B, and W subpixels, the area of each subpixel is small. However, needed capacitance can be secured without a decrease in the aperture ratio even when the occupation area of the capacitor is large because the capacitor transmits light. Thus, a subpixel with higher capacitance and the higher aperture ratio can be obtained. As a result, the power consumption of the display device can be reduced.

Since the light-transmitting conductive film included in the capacitor is formed using a metal oxide film provided in the same layer as the semiconductor film of the transistor, the light-transmitting conductive film included in the capacitor can be formed using a material that can be formed without any increase in the number of steps.

### <Modification Example of Color Filter Included in Subpixel>

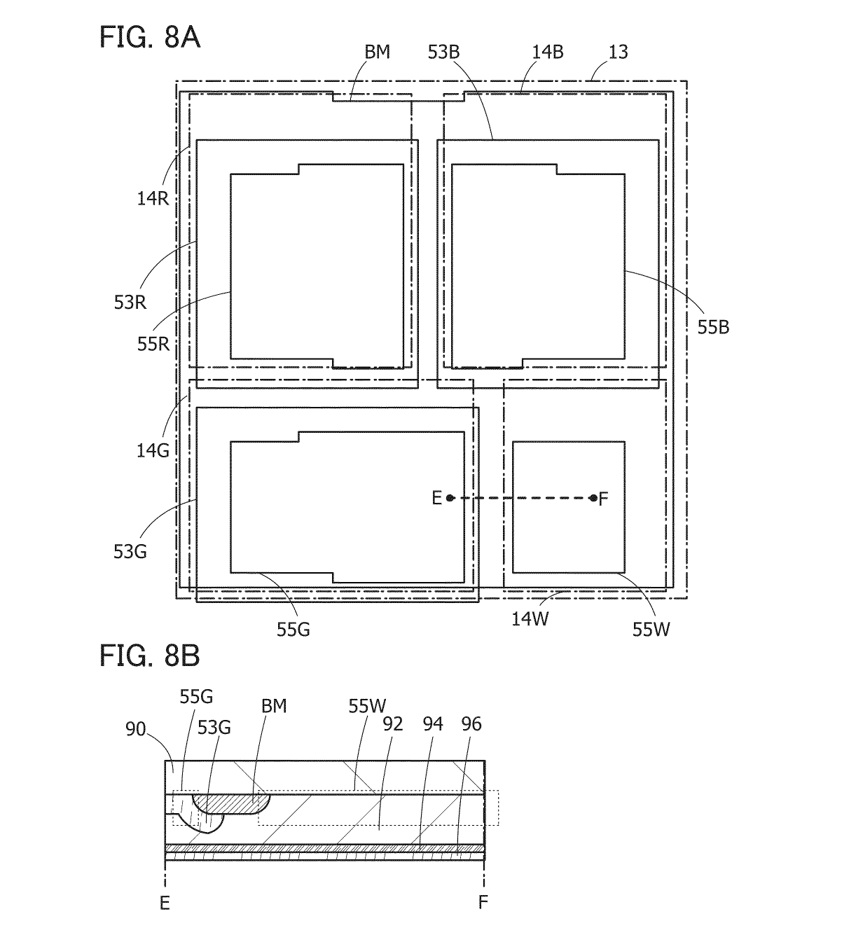

Although in FIG. 6 and FIG. 7, the light-transmitting layer 53W is provided, one embodiment of the present invention is not limited thereto. As illustrated in FIG. 8A, it may be possible not to provide the light-transmitting layer 53W. In that case, a cross-sectional structure can be represented as a cross-sectional structure in FIG. 8B by giving a cross-section taken along dashed line E-F in FIG. 8A as an example. This structure can reduce the material of the light-transmitting layer 53W and the number of steps of forming the light-transmitting layer 53W.

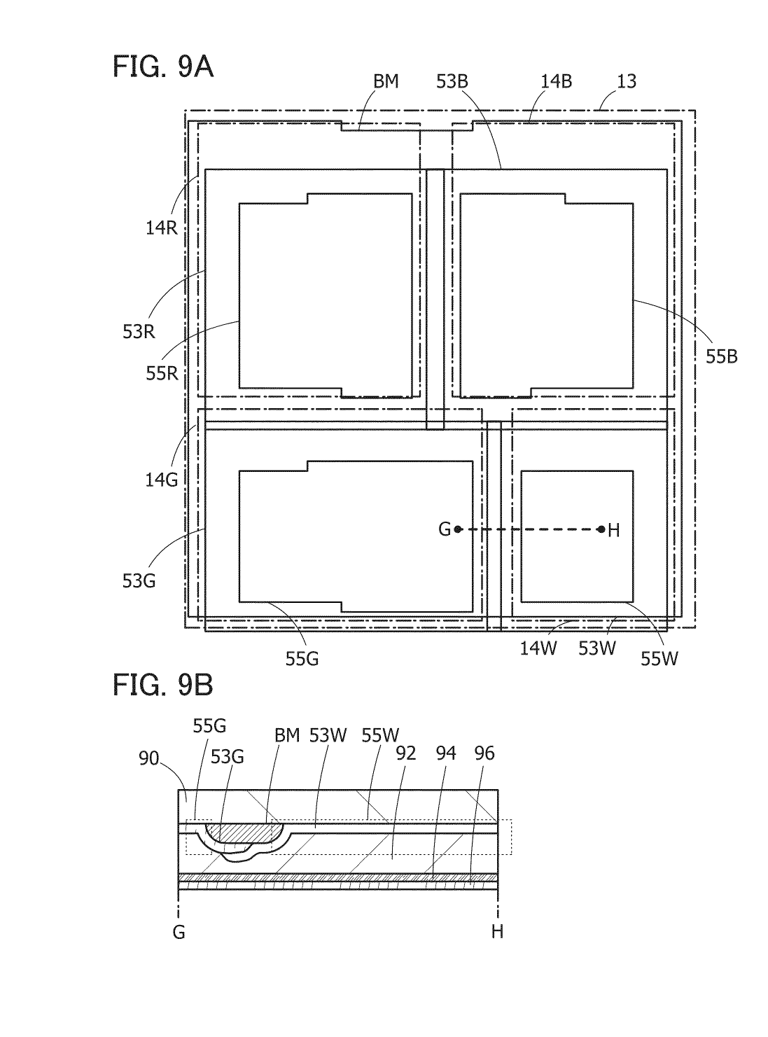

Although in FIG. 6 and FIG. 7, the color filters 53R, 53B, and 53G and the light-transmitting layer 53W do not overlap each other on the light-blocking films BM, one embodiment of the present invention is not limited thereto. As illustrated in FIG. 9A, the color filters 53R, 53B, and 53G and the light-transmitting layer 53W may overlap each other. In that case, a cross-sectional structure can be represented as a cross-sectional structure in FIG. 9B by giving a cross-section taken along dashed line G-H in FIG. 9A as an example. This structure can inhibit light leakage caused by misalignment of a mask at the time of forming the color filters 53R, 53B, and 53G and the light-transmitting layer 53W.

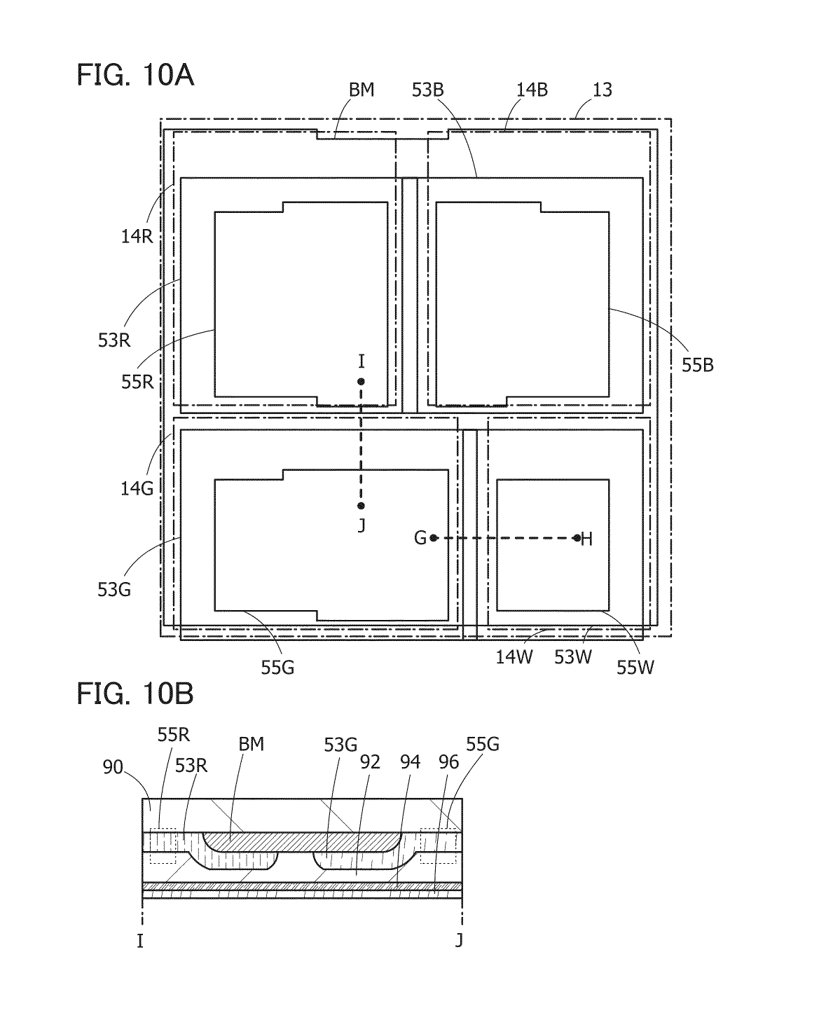

Although in FIGS. 9A and 9B, the color filters 53R, 53B, and 53G and the light-transmitting layer 53W overlap each other on the light-blocking films BM, one embodiment of the present invention is not limited thereto. As illustrated in FIG. 10A, a structure may be employed in which some of the color filters 53R, 53B, and 53G and the light-transmitting layer 53W overlap each other on the light-blocking films BM and the rest of the color filters 53R, 53B, and 53G and the light-transmitting layer 53W do not overlap each other on the light-blocking films BM. In that case, a cross-sectional structure can be represented as a cross-sectional structure in FIG. 9B or FIG. 10B by giving cross-sections taken along dashed line G-H and dashed line I-J in FIG. 10A as examples. This structure can inhibit light leakage caused by misalignment of a mask at the time of forming the color filters 53R, 53B, and 53G and the light-transmitting layer 53W.

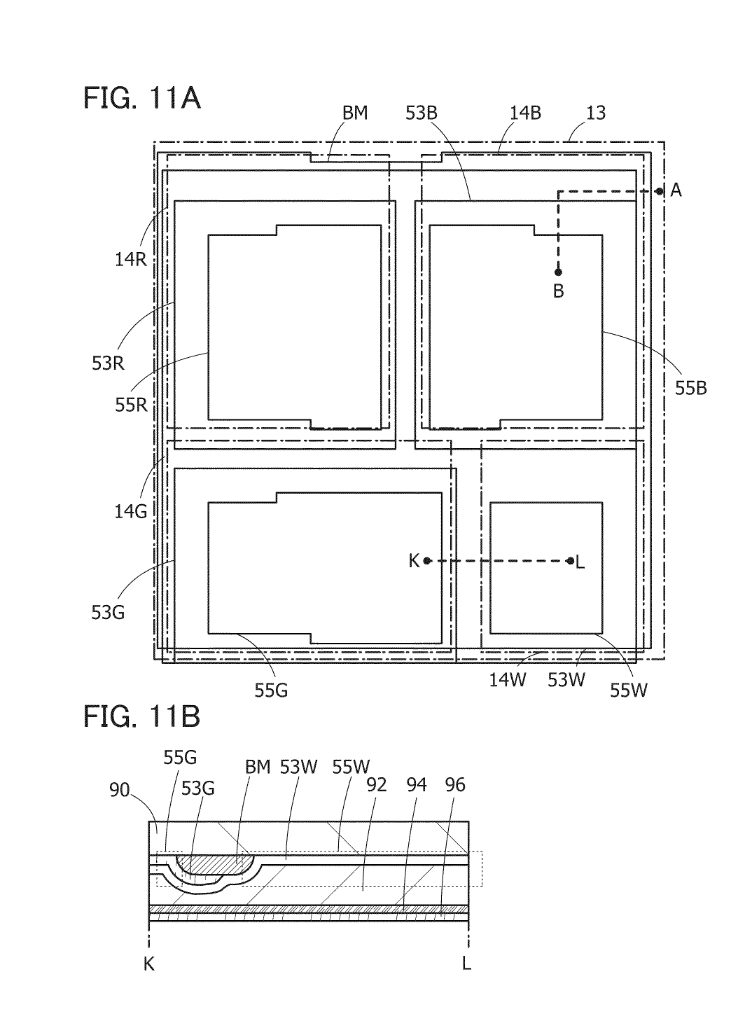

Although in FIG. 6 and FIG. 7, the color filters 53R, 53B, and 53G and the light-transmitting layer 53W are separately provided in respective subpixels, one embodiment of the present invention is not limited thereto. As illustrated in FIG. 11A, the light-transmitting layer 53W may overlap the entire surface of the pixel 13. In that case, a cross-sectional structure can be represented as a cross-sectional structure in FIG. 11B by giving a cross-section taken along dashed line K-L in FIG. 11A as an example. This structure can reduce the number of masks.

### <Method for Forming Transistor and Capacitor on Element Substrate Side>

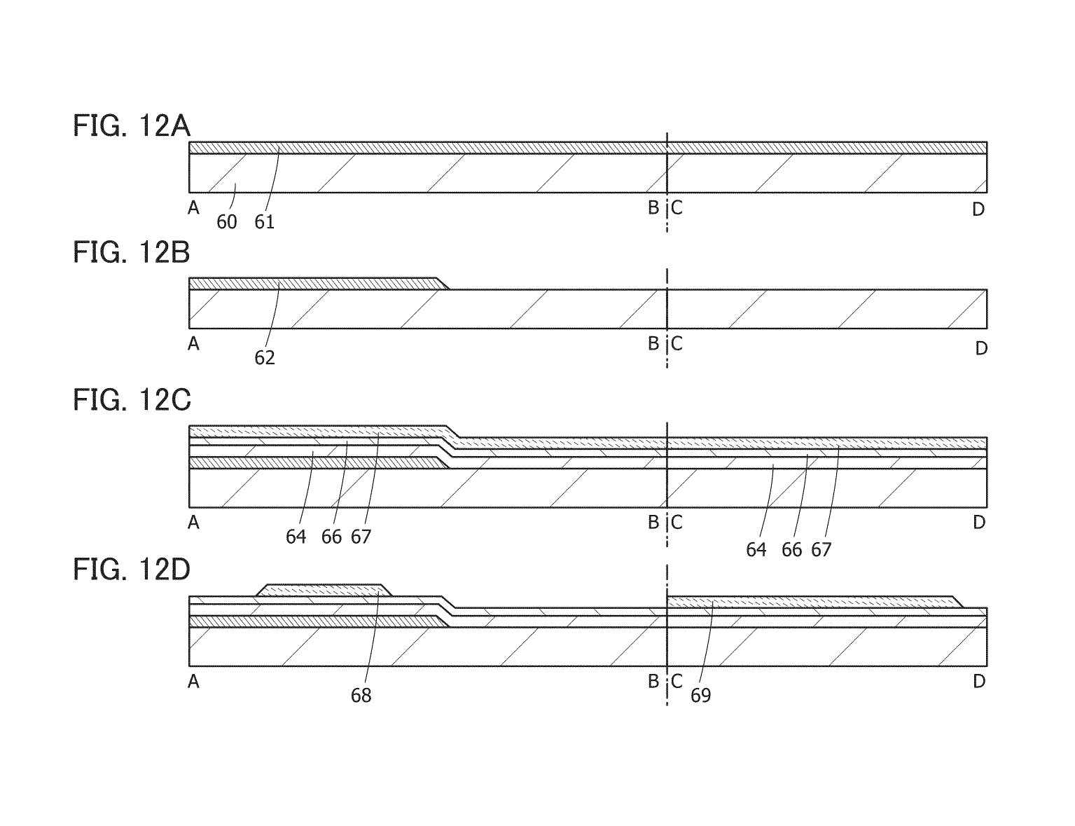

Next, a method for forming each component on the element substrate side is described. Here, a method for forming each component over the substrate 60 in FIG. 7 is described with reference to FIGS. 12A to 12D, FIGS. 13A to 13C, FIGS. 14A to 14C, and FIGS. 15A to 15C. Note that the component provided over the substrate 60 that is an element substrate refers to a component provided in a region between the substrate 60 and the alignment film 88. The method for forming each component on the element substrate side is described below with reference to cross-sectional structures taken along dashed lines A-B and C-D of FIG. 5A in FIG. 7.

Films of the transistor (e.g., an insulating film, a semiconductor film, an oxide semiconductor film, a metal oxide film, and a conductive film) can be formed by sputtering, chemical vapor deposition (CVD), vacuum vapor deposition, or pulsed laser deposition (PLD). Alternatively, the films of the transistor can be formed by a coating method or a printing method. Although sputtering and plasma-enhanced chemical vapor deposition (PECVD) are typical examples of the deposition method, thermal CVD may be used. As thermal CVD, metal organic chemical vapor deposition (MOCVD) or atomic layer deposition (ALD) may be used, for example.

Deposition by thermal CVD is performed in such a manner that pressure in a chamber is set to atmospheric pressure or reduced pressure, and a source gas and an oxidizer are supplied to the chamber at the same time and react with each other in the vicinity of the substrate or over the substrate. In this manner, thermal CVD does not generate plasma and thus has an advantage that no defect due to plasma damage is caused.

Deposition by ALD is performed in such a manner that pressure in a chamber is set to atmospheric pressure or reduced pressure, source gases for reaction are sequentially introduced into the chamber, and then the sequence of gas introduction is repeated. For example, two or more kinds of source gases are sequentially supplied to the chamber by switching switching valves (also referred to as high-speed valves). In such a case, a first source gas is introduced, an inert gas (e.g., argon or nitrogen) or the like is introduced at the same time as or after introduction of the first gas so that the source gases are not mixed, and then a second source gas is introduced. Note that in the case where the first source gas and the inert gas are introduced at the same time, the inert gas serves as a carrier gas, and the inert gas may be introduced at the same time as introduction of the second source gas. Alternatively, the first source gas may be exhausted by vacuum evacuation instead of introduction of the inert gas, and then the second source gas may be introduced. The first source gas is adsorbed on the surface of the substrate to form a first single-atomic layer; then the second source gas is introduced to react with the first single-atomic layer; as a result, a second single-atomic layer is stacked over the first single-atomic layer, so that a thin film is formed.

The sequence of gas introduction is repeated more than once until desired thickness is obtained, so that a thin film with excellent step coverage can be formed. The thickness of the thin film can be adjusted by the number of repetition times of the sequence of gas introduction; therefore, ALD makes it possible to adjust thickness accurately and thus is suitable for manufacturing a scaled transistor.

First, the substrate 60 is prepared. Here, a glass substrate is used as the substrate 60.

Then, a conductive film is formed over the substrate 60 (see FIG. 12A) and processed into a desired region, so that the conductive film 62 is formed. The conductive film 62 can be formed in such a manner that a mask is formed in the desired region by first patterning and regions that are not covered with the mask are etched (see FIG. 12B).

The conductive film 62 can be typically formed by sputtering, vacuum vapor deposition, PLD, thermal CVD, or the like.

Alternatively, a tungsten film can be formed as the conductive film 62 with a deposition apparatus employing ALD. In that case, a WF₆ gas and a B₂H₆ gas are sequentially introduced more than once to form an initial tungsten film, and then a WF₆ gas and an H₂ gas are introduced at the same time, so that a tungsten film is formed. Note that an SiH₄ gas may be used instead of a B₂H₆ gas.

Next, the insulating film 64 is formed over the substrate 60 and the conductive film 62, and then the insulating film 66 is formed over the insulating film 64 (see FIG. 12C).

The insulating films 64 and 66 are formed by sputtering, vacuum vapor deposition, PLD, thermal CVD, or the like. Note that it is preferable that the insulating films 64 and 66 be formed in succession in a vacuum because entry of impurities is inhibited.

When a silicon oxide film or a silicon oxynitride film is formed as each of the insulating films 64 and 66, a deposition gas containing silicon and an oxidizing gas are preferably used as a source gas. Typical examples of the deposition gas containing silicon include silane, disilane, trisilane, and silane fluoride. Examples of the oxidizing gas include oxygen, ozone, dinitrogen monoxide, and nitrogen dioxide.

In the case where a gallium oxide film is formed as each of the insulating films 64 and 66, MOCVD can be used.

In the case where a hafnium oxide film is formed as each of the insulating films 64 and 66 by thermal CVD such as MOCVD or ALD, two kinds of gases, i.e. ozone (O₃) as an oxidizer and a source gas that is obtained by vaporizing liquid containing a solvent and a hafnium precursor compound (a hafnium alkoxide solution, typically tetrakis(dimethylamide) hafnium (TDMAH)) are used. Note that the chemical formula of tetrakis(dimethylamide) hafnium is Hf[N(CH₃)₂]₄. Examples of another material liquid include tetrakis(ethylmethylamide) hafnium.

In the case where an aluminum oxide film is formed as each of the insulating films 64 and 66 by thermal CVD such as MOCVD or ALD, two kinds of gases, e.g., H₂O as an oxidizer and a source gas that is obtained by vaporizing liquid containing a solvent and an aluminum precursor compound (e.g., trimethylaluminum (TMA)) are used. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate).

In the case where a silicon oxide film is formed as each of the insulating films 64 and 66 by thermal CVD such as MOCVD or ALD, hexachlorodisilane is adsorbed on a deposition surface, chlorine contained in adsorbate is removed, and radicals of an oxidizing gas (e.g., 02 or dinitrogen monoxide) are supplied to react with the adsorbate.

Next, an oxide semiconductor film 67 is formed over the insulating film 66 (see FIG. 12C).

The oxide semiconductor film 67 can be formed by sputtering, pulsed laser deposition, laser ablation, thermal CVD, or the like.

As a sputtering gas, a rare gas (typically argon), oxygen, or a mixed gas of a rare gas and oxygen is used as appropriate. In the case where the mixed gas of a rare gas and oxygen is used, the proportion of oxygen to a rare gas is preferably increased.

A target may be selected as appropriate in accordance with the composition of an oxide semiconductor film to be formed.

For example, in the case where the oxide semiconductor film is formed by sputtering at a substrate temperature of 150 to 750° C., preferably 150 to 450° C., more preferably 200 to 350° C., the oxide semiconductor film can be a CAAC-OS film.

For the deposition of the CAAC-OS film, the following conditions are preferably employed.

By inhibiting entry of impurities during the deposition, the crystal state can be prevented from being broken by the impurities. For example, the concentration of impurities (e.g., hydrogen, water, carbon dioxide, or nitrogen) that exist in a deposition chamber may be reduced. Furthermore, the concentration of impurities in a deposition gas may be reduced. Specifically, a deposition gas whose dew point is −80° C. or lower, preferably −100° C. or lower is used.

In the case where an oxide semiconductor film, e.g., an InGaZnO_{X} (X>0) film is formed using a deposition apparatus employing ALD, an In(CH₃)₃ gas and an O₃ gas are sequentially introduced more than once to form an InO₂ layer, a Ga(CH₃)₃ gas and an O₃ gas are introduced at the same time to form a GaO layer, and then a Zn(CH₃)₂ gas and an O₃ gas are introduced at the same time to form a ZnO layer. Note that the order of these layers is not limited to this example. A mixed compound layer such as an InGaO₂ layer, an InZnO₂ layer, a GaInO layer, a ZnInO layer, or a GaZnO layer may be formed by mixing of these gases. Although an H₂O gas that is obtained by bubbling with an inert gas such as Ar may be used instead of an O₃ gas, it is preferable to use an O₃ gas that does not contain H. Instead of an In(CH₃)₃ gas, an In(C₂H₅)₃ gas may be used. Instead of a Ga(CH₃)₃ gas, a Ga(C₂H₅)₃ gas may be used. Furthermore, a Zn(CH₃)₂ gas may be used.

Next, the oxide semiconductor film 67 is processed into desired regions, so that the island-shaped oxide semiconductor film 68 and an island-shaped oxide semiconductor film 69 are formed. The oxide semiconductor films 68 and 69 can be formed in such a manner that a mask is formed in the desired regions by second patterning and regions that are not covered with the mask are etched. Dry etching, wet etching, or a combination of dry etching and wet etching can be employed as etching (see FIG. 12D).

After that, hydrogen, water, and the like may be released from the oxide semiconductor films 68 and 69 by heat treatment and hydrogen concentration and water concentration in the oxide semiconductor films 68 and 69 may be reduced. As a result, highly purified oxide semiconductor films 68 and 69 can be formed. The heat treatment is performed typically at a temperature of 250 to 650° C., preferably 300 to 500° C. The heat treatment is performed typically at a temperature of 300 to 400° C., preferably 320 to 370° C., so that warp or shrinkage of a large-area substrate can be reduced and yield can be improved.

An electric furnace, an RTA apparatus, or the like can be used for the heat treatment. With the use of an RTA apparatus, the heat treatment can be performed at a temperature of higher than or equal to the strain point of the substrate if the heating time is short. Thus, the heat treatment time can be shortened and warp of the substrate during the heat treatment can be reduced, which is particularly preferable in a large-area substrate.

The heat treatment may be performed under an atmosphere of nitrogen, oxygen, ultra-dry air (air in which water content is 20 ppm or less, preferably 1 ppm or less, more preferably 10 ppb or less), or a rare gas (e.g., argon or helium). The atmosphere of nitrogen, oxygen, ultra-dry air, or a rare gas preferably does not contain hydrogen, water, and the like. Furthermore, after heat treatment is performed in a nitrogen atmosphere or a rare gas atmosphere, heat treatment may be additionally performed in an oxygen atmosphere or an ultra-dry air atmosphere. As a result, hydrogen, water, and the like can be released from the oxide semiconductor film and oxygen can be supplied to the oxide semiconductor film at the same time. Consequently, the number of oxygen vacancies in the oxide semiconductor film can be reduced.

In the case where the deposition temperature of an insulating film 77 formed later is 280 to 400° C., hydrogen, water, and the like can be released from the oxide semiconductor films 68 and 69; thus, the heat treatment is not necessary.

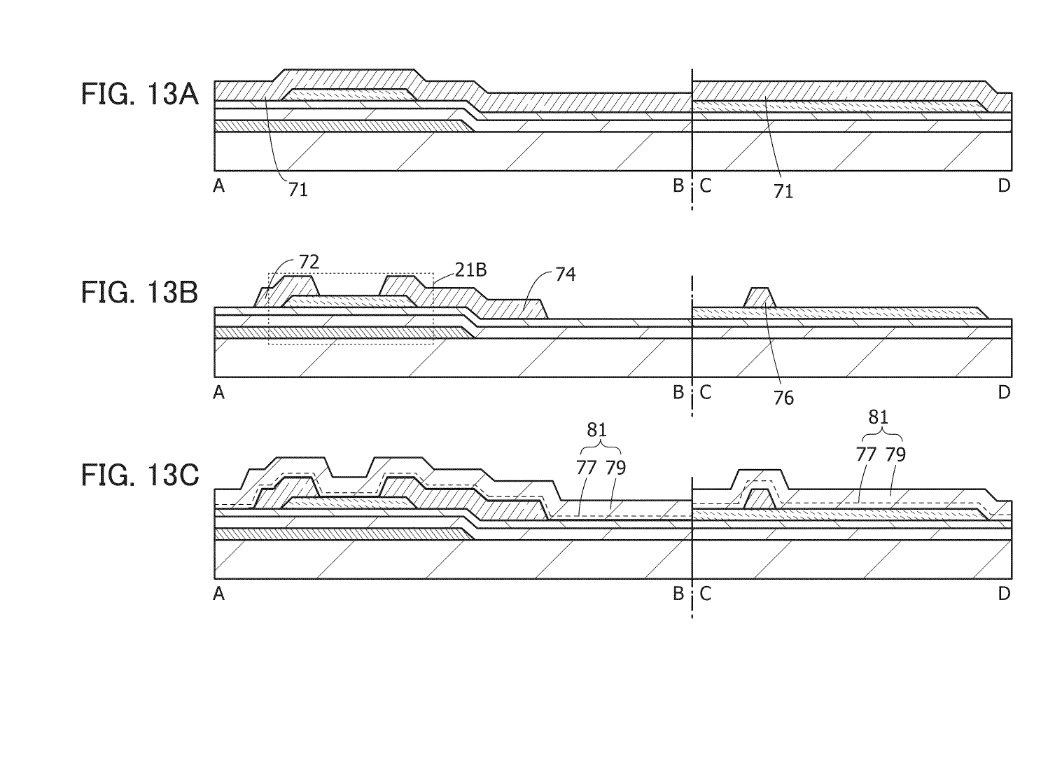

Next, a conductive film 71 is formed over the insulating film 66 and the oxide semiconductor films 68 and 69 (see FIG. 13A).

The conductive film 71 can be formed by sputtering, vacuum vapor deposition, PLD, thermal CVD, or the like.

Then, the conductive film 71 is processed into desired regions, so that the conductive films 72, 74, and 76 are formed. Note that the conductive films 72, 74, and 76 can be formed in such a manner that a mask is formed in a desired region by third patterning and regions that are not covered with the mask are etched (see FIG. 13B).

Next, an insulating film 81 in which the insulating film 77 and an insulating film 79 are stacked is formed to cover the insulating film 66, the oxide semiconductor films 68 and 69, and the conductive films 72, 74, and 76 (see FIG. 13C). The insulating film 81 can be formed by sputtering, CVD, vapor deposition, or the like.

Note that after the insulating film 77 is formed, the insulating film 79 is preferably formed in succession without exposure to the air. After the insulating film 77 is formed, the insulating film 79 is formed in succession by adjusting at least one of the flow rate of a source gas, pressure, high-frequency power, and substrate temperature without exposure to the air, so that the concentration of impurities attributed to an atmospheric component at an interface between the insulating films 77 and 79 can be lowered and oxygen in the insulating film 79 can be moved to the oxide semiconductor films 68 and 69. Accordingly, the number of oxygen vacancies in the oxide semiconductor films 68 and 69 can be reduced.

An oxide insulating film containing nitrogen and having a small number of defects can be formed as the insulating film 77 by CVD under the conditions that the ratio of an oxidizing gas to a deposition gas is higher than 20 times and lower than 100 times, preferably higher than or equal to 40 times and lower than or equal to 80 times and pressure in a treatment chamber is lower than 100 Pa, preferably lower than or equal to 50 Pa.

A deposition gas containing silicon and an oxidizing gas are preferably used as the source gas of the insulating film 77. Typical examples of the deposition gas containing silicon include silane, disilane, trisilane, and silane fluoride. Examples of the oxidizing gas include oxygen, ozone, dinitrogen monoxide, and nitrogen dioxide.

Under the above conditions, an oxide insulating film that passes oxygen can be formed as the insulating film 77. With the insulating film 77, damage to the oxide semiconductor films 68 and 69 can be reduced in a step of forming the insulating film 79 formed later.

As the insulating film 79, a silicon oxide film or a silicon oxynitride film is formed under the following conditions: a substrate placed in a vacuum-evacuated treatment chamber of a plasma-enhanced CVD apparatus is held at a temperature of 180 to 280° C., preferably 200 to 240° C., a source gas is introduced into the treatment chamber, pressure in the treatment chamber is 100 to 250 Pa, preferably 100 to 200 Pa, and a high-frequency power of 0.17 to 0.5 W/cm², preferably 0.25 to 0.35 W/cm² is supplied to an electrode provided in the treatment chamber.

A deposition gas containing silicon and an oxidizing gas are preferably used as the source gas of the insulating film 79. Typical examples of the deposition gas containing silicon include silane, disilane, trisilane, and silane fluoride. Examples of the oxidizing gas include oxygen, ozone, dinitrogen monoxide, and nitrogen dioxide.

As the deposition conditions of the insulating film 79, high-frequency power is supplied, so that the decomposition efficiency of the source gas in plasma is increased, oxygen radicals are increased, and oxidation of the source gas is promoted; therefore, the oxygen content of the insulating film 79 becomes higher than in the stoichiometric composition. However, when the substrate temperature is the deposition temperature of the insulating film 79, the bond between silicon and oxygen is weak; thus, part of oxygen is released by heating. Thus, it is possible to form an oxide insulating film which contains oxygen at higher proportion than the stoichiometric composition and from which part of oxygen is released by heating. Furthermore, the insulating film 77 is provided over the oxide semiconductor films 68 and 69. Accordingly, in the step of forming the insulating film 79, the insulating film 77 serves as a protective film of the oxide semiconductor films 68 and 69. Consequently, the insulating film 79 can be formed using the high-frequency power having high power density while damage to the oxide semiconductor films 68 and 69 is reduced.

Note that in the deposition conditions of the insulating film 79, the flow rate of the deposition gas containing silicon relative to the oxidizing gas can be increased, so that the number of defects in the insulating film 79 can be reduced. Typically, it is possible to form an oxide insulating film in which the number of defects is small, i.e. the spin density of a signal that appears at g=2.001 due to a dangling bond of silicon, be lower than 6×10¹⁷ spins/cm³, preferably lower than or equal to 3×10¹⁷ spins/cm³, more preferably lower than or equal to 1.5×10¹⁷ spins/cm³ by ESR measurement. As a result, the reliability of the transistor can be increased.

Next, heat treatment is performed. The temperature of the heat treatment is typically higher than or equal to 150° C. and lower than the strain point of the substrate, preferably higher than or equal to 200° C. and lower than or equal to 450° C., more preferably higher than or equal to 300° C. and lower than or equal to 450° C. The heat treatment is performed typically at a temperature of higher than or equal to 300° C. and lower than or equal to 400° C., preferably higher than or equal to 320° C. and lower than or equal to 370° C., so that warp or shrinkage of a large-area substrate can be reduced and yield can be improved.

An electric furnace, an RTA apparatus, or the like can be used for the heat treatment. With the use of an RTA apparatus, the heat treatment can be performed at a temperature of higher than or equal to the strain point of the substrate if the heating time is short. Thus, the heat treatment time can be shortened.

The heat treatment may be performed under an atmosphere of nitrogen, oxygen, ultra-dry air (air in which water content is 20 ppm or less, preferably 1 ppm or less, more preferably 10 ppb or less), or a rare gas (e.g., argon or helium). The atmosphere of nitrogen, oxygen, ultra-dry air, or a rare gas preferably does not contain hydrogen, water, and the like.

By the heat treatment, part of oxygen contained in the insulating film 79 can be moved to the oxide semiconductor films 68 and 69 to reduce the oxygen vacancies in the oxide semiconductor films 68 and 69. Consequently, the number of oxygen vacancies in the oxide semiconductor films 68 and 69 can be further reduced.

In the case where water, hydrogen, or the like is contained in the insulating films 77 and 79, when an insulating film 83 having a function of blocking water, hydrogen, and the like is formed later and heat treatment is performed, water, hydrogen, or the like contained in the insulating films 77 and 79 is moved to the oxide semiconductor films 68 and 69, so that defects are generated in the oxide semiconductor films 68 and 69. However, by the heating, water, hydrogen, or the like contained in the insulating films 77 and 79 can be released; thus, variations in electrical characteristics of the transistor can be reduced, and changes in the threshold voltage can be inhibited.

Note that when the insulating film 79 is formed over the insulating film 77 while being heated, oxygen can be moved to the oxide semiconductor films 68 and 69 to compensate the oxygen vacancies in the oxide semiconductor films 68 and 69; thus, the heat treatment is not necessarily performed.

When the conductive films 72, 74, and 76 are formed, the oxide semiconductor films 68 and 69 are damaged by etching of the conductive film, so that oxygen vacancies are generated on a back channel side of the oxide semiconductor film 68 (a side of the oxide semiconductor film 68 that is opposite to a side facing the conductive film 62 functioning as a gate electrode). However, with the use of the oxide insulating film containing oxygen at higher proportion than the stoichiometric composition as the insulating film 79, the oxygen vacancies generated on the back channel side can be repaired by heat treatment. This reduces defects contained in the oxide semiconductor film 68 to improve the reliability of the transistor.

Note that the heat treatment may be performed after formation of the opening 50GW to be formed later.

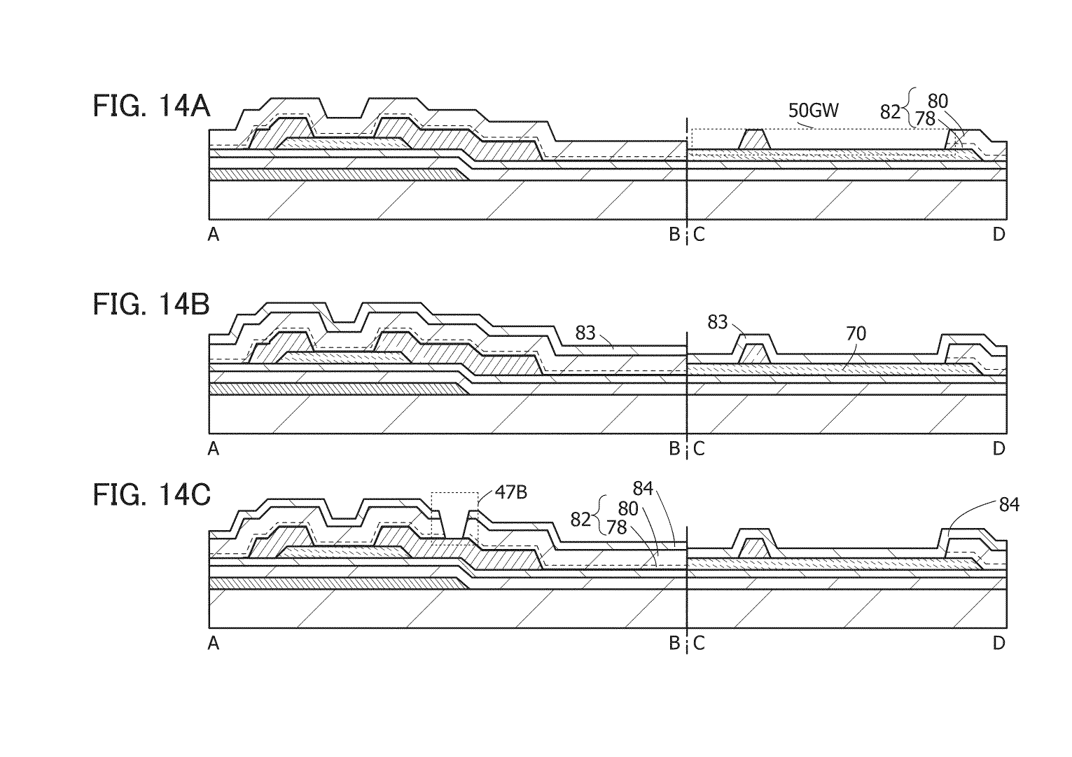

Next, the insulating films 77 and 79 are processed into desired regions, so that the insulating film 82 in which the insulating films 78 and 80 are stacked, and the opening 50GW are formed. The insulating film 82 and the opening 50GW can be formed in such a manner that a mask is formed in the desired regions by fourth patterning and regions that are not covered with the mask are etched (see FIG. 14A).

The opening 50GW is formed to expose the surface of the oxide semiconductor film 69. The opening 50GW can be formed by dry etching, for example. The insulating film 81 is preferably etched by dry etching. In that case, the oxide semiconductor film 69 is exposed to plasma in the etching treatment; thus, oxygen vacancies in the oxide semiconductor film 69 can be increased. Note that the method for forming the opening 50GW is not limited to dry etching, and wet etching or a combination of dry etching and wet etching may be employed.

Next, the insulating film 83 is formed over the insulating film 82 and the oxide semiconductor film 69 (see FIG. 14B).

The insulating film 83 is preferably formed using a material that prevents diffusion of impurities from the outside, such as oxygen, hydrogen, water, alkali metal, and alkaline earth metal, into the oxide semiconductor film, more preferably formed using the material including hydrogen, and typically an inorganic insulating material containing nitrogen, such as a nitride insulating film, can be used. The insulating film 83 can be formed by CVD or sputtering, for example.

When the insulating film 83 is formed by plasma-enhanced CVD or sputtering, the oxide semiconductor film is exposed to plasma and oxygen vacancies are generated in the oxide semiconductor film. The insulating film 83 is formed using a material that prevents diffusion of impurities from the outside, such as water, alkali metal, and alkaline earth metal, into the oxide semiconductor film, and the material further includes hydrogen. Thus, when hydrogen in the insulating film 83 is diffused into the oxide semiconductor film 69, hydrogen is bonded to oxygen and electrons serving as carriers are generated in the oxide semiconductor film 69. Alternatively, when hydrogen enters the oxygen vacancies in the oxide semiconductor film, electrons serving as carriers are generated. As a result, the conductivity of the oxide semiconductor film 69 is increased, so that the oxide semiconductor film 69 becomes the metal oxide film 70.

The silicon nitride film is preferably formed at high temperature to have an improved blocking property; for example, the silicon nitride film is preferably formed at a substrate temperature of 100 to 400° C., more preferably 300 to 400° C. When the silicon nitride film is formed at high temperature, a phenomenon in which oxygen is released from the oxide semiconductor used for the oxide semiconductor film 68 and carrier concentration is increased is caused in some cases; therefore, the upper limit of the temperature is temperature at which the phenomenon is not caused.

Next, the insulating films 82 and 83 are processed into desired regions, so that the insulating films 82 and 84 and the opening 47B are formed. The insulating film 84 and the opening 47B can be formed in such a manner that a mask is formed in the desired regions by fourth patterning and regions that are not covered with the mask are etched (see FIG. 14C).

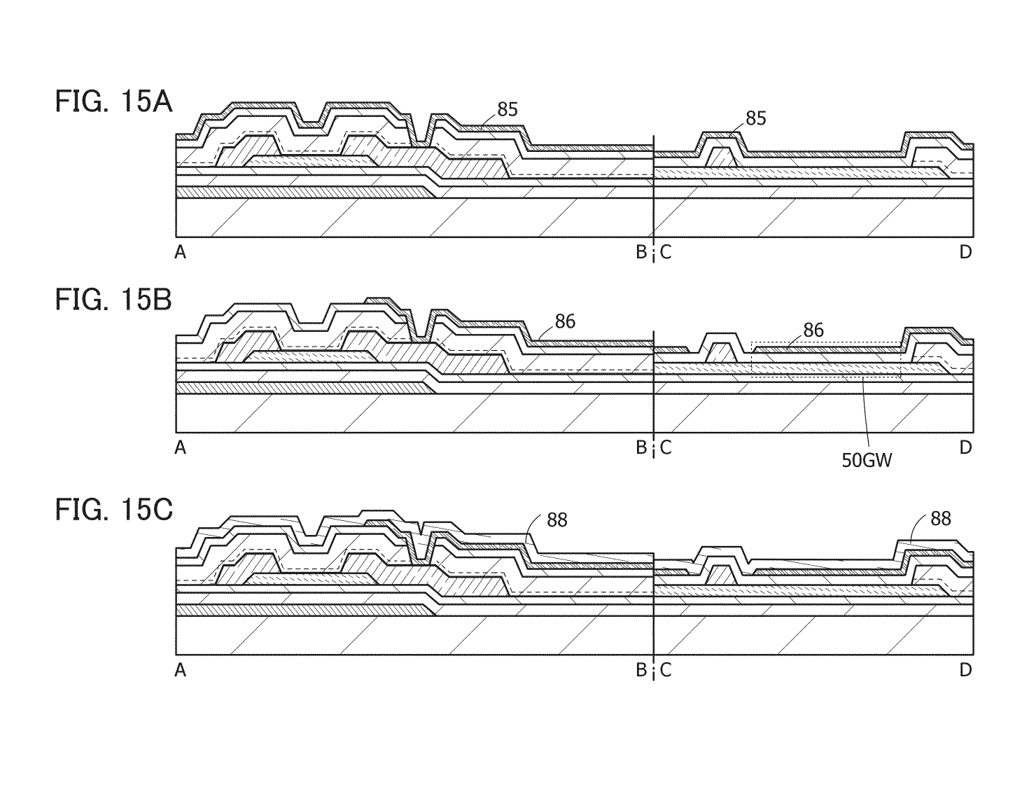

Next, a conductive film 85 is formed (see FIG. 15A).

The conductive film 85 can be formed using a conductive material having a light-transmitting property. For the conductive film 85, indium oxide including tungsten oxide, indium zinc oxide including tungsten oxide, indium oxide including titanium oxide, indium tin oxide including titanium oxide, ITO, indium zinc oxide, indium tin oxide to which silicon oxide is added, or the like can be used. The conductive film 85 can be formed by sputtering, for example.

Then, the conductive film 85 is processed into a desired region, so that the conductive film 86 is formed. Note that the conductive film 86 can be formed in such a manner that a mask is formed in a desired region by sixth patterning and regions that are not covered with the mask are etched (see FIG. 15B).

Next, the alignment film 88 is formed (see FIG. 15C).

The alignment film 88 can be formed by a rubbing method, an optical alignment method, or the like.

Through the above steps, the transistor and the capacitor can be formed.

On the element substrate of the liquid crystal display device in one embodiment of the present invention illustrated as an example, the pixel electrode is formed at the same time as the oxide semiconductor film of the transistor; therefore, the transistor and the capacitor can be formed using six photomasks. The pixel electrode functions as one electrode of the capacitor. Thus, a step of forming another conductive film is not needed to form the capacitor, and the number of manufacturing steps can be reduced. The capacitor has a light-transmitting property. As a result, the aperture ratio of a pixel can be increased while the occupation area of the capacitor is increased.

### <Method for Forming Light-Blocking Film and Color Filter on Counter Substrate Side>

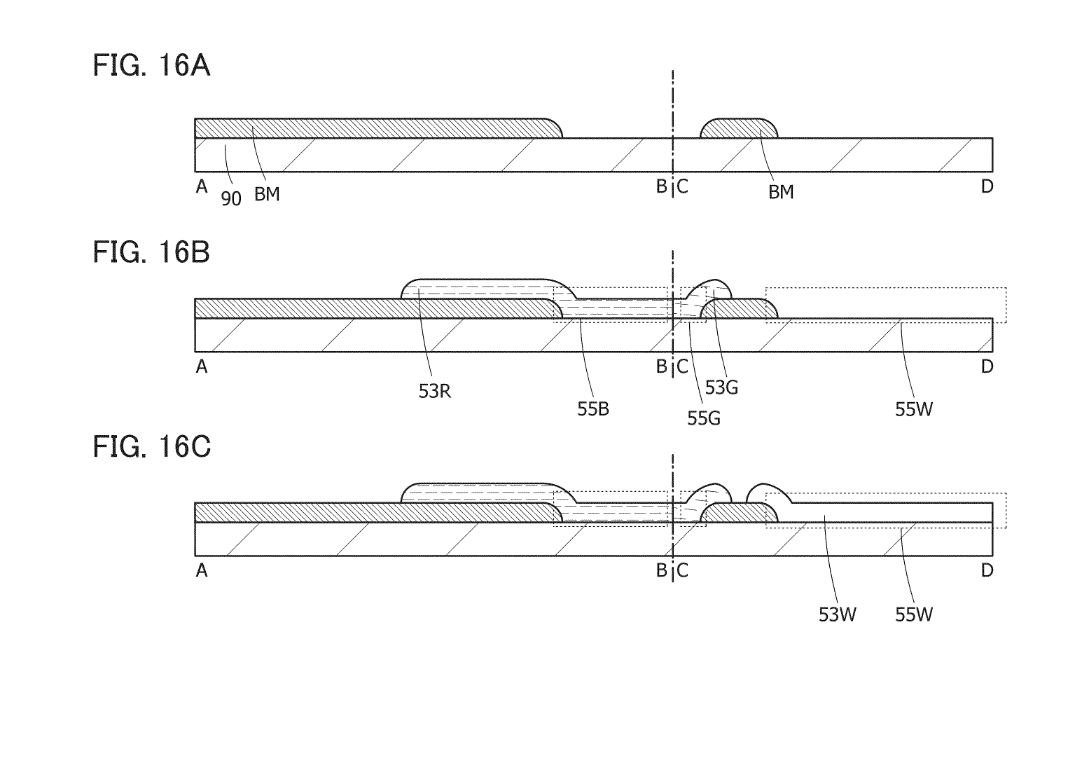

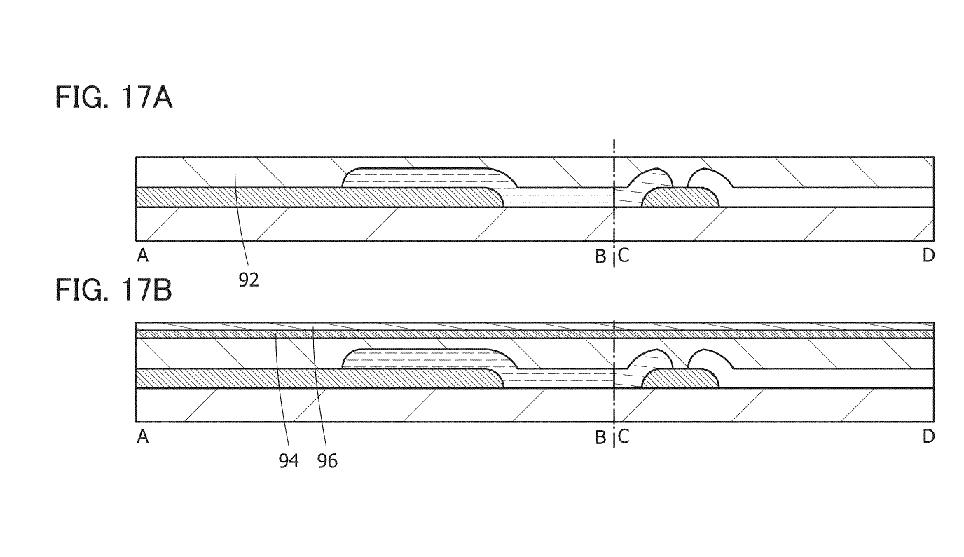

Next, a method for forming each component on the counter substrate side is described. Here, a method for forming the light-blocking film and the color filter over the substrate 90 in FIG. 7 is described with reference to FIGS. 16A to 16C and FIGS. 17A and 17B. Note that the component provided over the substrate 90 that is a counter substrate refers to a component provided in a region between the substrate 90 and the alignment film 96. The method for forming each component on the counter substrate side is described below with reference to cross-sectional structures taken along dashed lines A-B and C-D of FIG. 6 in FIG. 7.

First, the substrate 90 is prepared. For the substrate 90, the materials used for the substrate 90 can be referred to. Next, the light-blocking films BM are formed over the substrate 90 (see FIG. 16A).

The light-blocking films BM are formed in desired positions with a metal film or an organic insulating film including a black pigment or the like by a printing method, an inkjet method, etching using a photolithography technique, or the like.

Next, the openings 55B and 55W are provided over the light-blocking films BM to form the color filters 53G and 53B in the openings 55G and 55B (see FIG. 16B). Note that although not illustrated, the color filter 53R is formed in the opening 55R.

Then, the light-transmitting layer 53W is formed in the opening 55W (see FIG. 16C). An acrylic resin can be used for the light-transmitting layer 53W, for example.

Next, the insulating film 92 is formed over the light-blocking films BM and the color filters 53G and 53B (see FIG. 17A).

As the insulating film 92, an organic insulating film of an acrylic resin, an epoxy resin, polyimide, or the like can be used, for example. With the insulating film 92, impurities or the like contained in the color filters 53G and 53B can be inhibited from diffusing into the liquid crystal layer 95 side, for example. Note that the insulating film 92 is not necessarily formed.

Then, the conductive film 94 is formed over the insulating film 92, and the alignment film 96 is formed over the conductive film 94 (see FIG. 17B). For the conductive film 94, the materials used for the conductive film 86 can be referred to.

The alignment film 96 can be formed by a rubbing method, an optical alignment method, or the like.

Through the above steps, the structure formed over the substrate 90 can be formed.

After that, the liquid crystal layer 95 is formed between the substrates 60 and 90. The liquid crystal layer 95 can be formed by a dispenser method (dropping method), or an injection method by which a liquid crystal is injected using a capillary phenomenon after the substrates 60 and 90 are attached to each other.

Through the above steps, the liquid crystal display device in FIG. 7 can be manufactured.

One embodiment of the present invention described above features at least one of the following structures: (1) the opening area of the W subpixel is smaller than the opening area of each of the R, G, and B subpixels; (2) the subpixels are arranged in two rows by two columns to reduce the number of wirings for controlling the pixel; and (3) a semiconductor film of a transistor included in each subpixel is an oxide semiconductor film and an electrode included in a capacitor is formed using a light-transmitting conductive film. Thus, one embodiment of the present invention can achieve a display device with the following features: (1) color display can be performed without any reduction in color saturation, (2) the number of wirings for driving four subpixels can be reduced, and (3) the aperture ratio can be increased without any reduction in capacitance required and an increase in the number of steps can be inhibited. As a result, the power consumption of the display device can be reduced.

### <Oxide Conductor (Metal Oxide Film)>

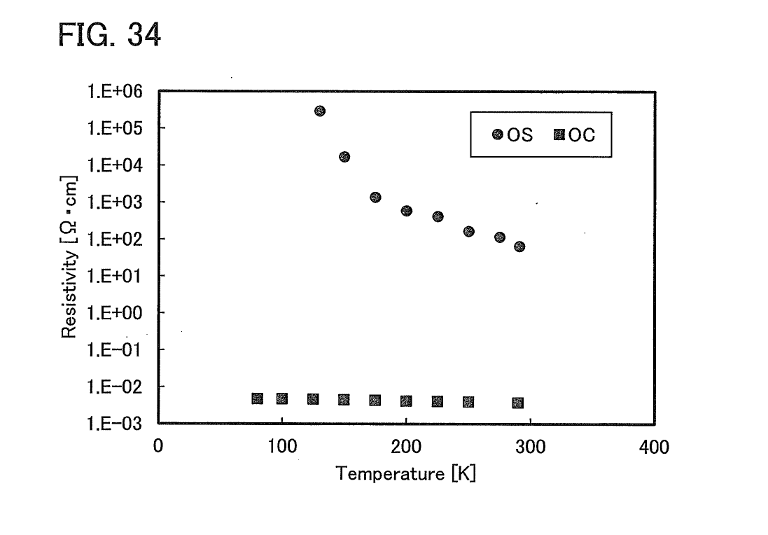

Here, the temperature dependence of resistivity of a film formed using an oxide semiconductor (hereinafter referred to as an oxide semiconductor film (OS)) and that of a film formed using an oxide conductor (hereinafter referred to as an oxide conductor film (OC)) are described with reference to FIG. 34. In FIG. 34, the horizontal axis represents measurement temperature, and the vertical axis represents resistivity. Measurement results of the oxide semiconductor film (OS) are plotted as circles, and measurement results of the oxide conductor film (OC) are plotted as squares.

Note that a sample including the oxide semiconductor film (OS) is prepared by forming a 35-nm-thick In—Ga—Zn oxide film over a glass substrate by sputtering using a sputtering target with an atomic ratio of In:Ga:Zn=1:1:1.2, forming a 20-nm-thick In—Ga—Zn oxide film over the 35-nm-thick In—Ga—Zn oxide film by sputtering using a sputtering target with an atomic ratio of In:Ga:Zn=1:4:5, performing heat treatment at 450° C. in a nitrogen atmosphere and then performing heat treatment at 450° C. in the atmosphere of a mixed gas of nitrogen and oxygen, and forming a silicon oxynitride film by plasma-enhanced CVD.

A sample including the oxide conductor film (OC) is prepared by forming a 100-nm-thick In—Ga—Zn oxide film over a glass substrate by sputtering using a sputtering target with an atomic ratio of In:Ga:Zn=1:1:1, performing heat treatment at 450° C. in a nitrogen atmosphere and then performing heat treatment at 450° C. in the atmosphere of a mixed gas of nitrogen and oxygen, and forming a silicon nitride film by plasma-enhanced CVD.

As can be seen from FIG. 34, the temperature dependence of resistivity of the oxide conductor film (OC) is lower than the temperature dependence of resistivity of the oxide semiconductor film (OS). Typically, variation of the resistivity of the oxide conductor film (OC) at temperatures from 80 to 290 K is more than −20% and less than +20%. Alternatively, the range of variation of resistivity at temperatures from 150 to 250 K is more than −10% and less than +10%. In other words, the oxide conductor is a degenerate semiconductor and it is suggested that the conduction band edge agrees with or substantially agrees with the Fermi level. Thus, the oxide conductor film can be used for a wiring, an electrode, a pixel electrode, or the like.

Note that the structures, methods, and the like described in this embodiment can be combined with any of the structures, methods, and the like described in the other embodiments as appropriate.

### Embodiment 2

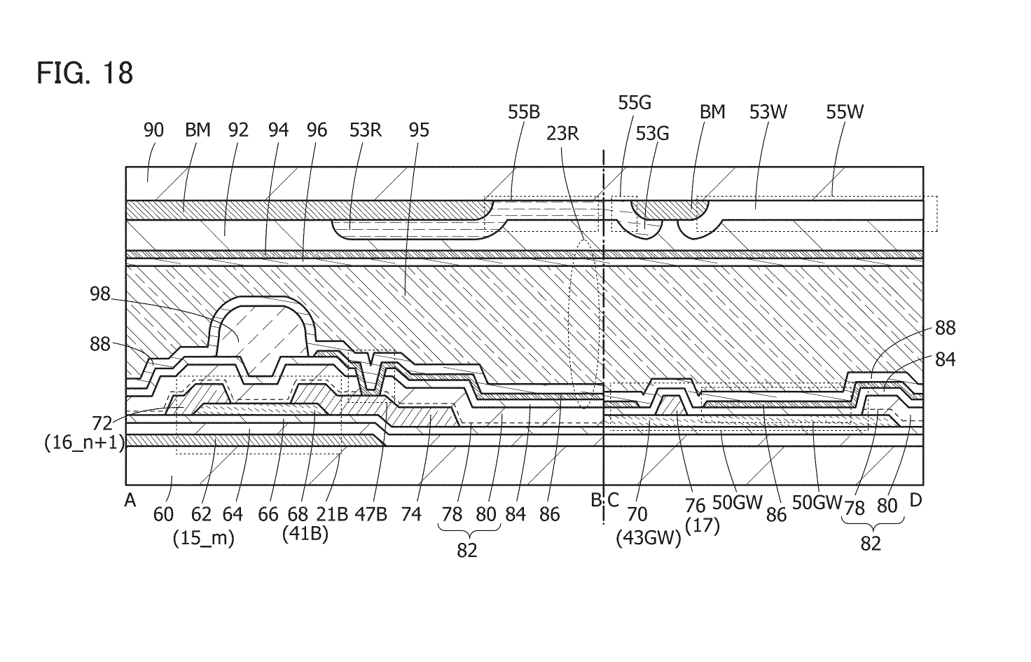

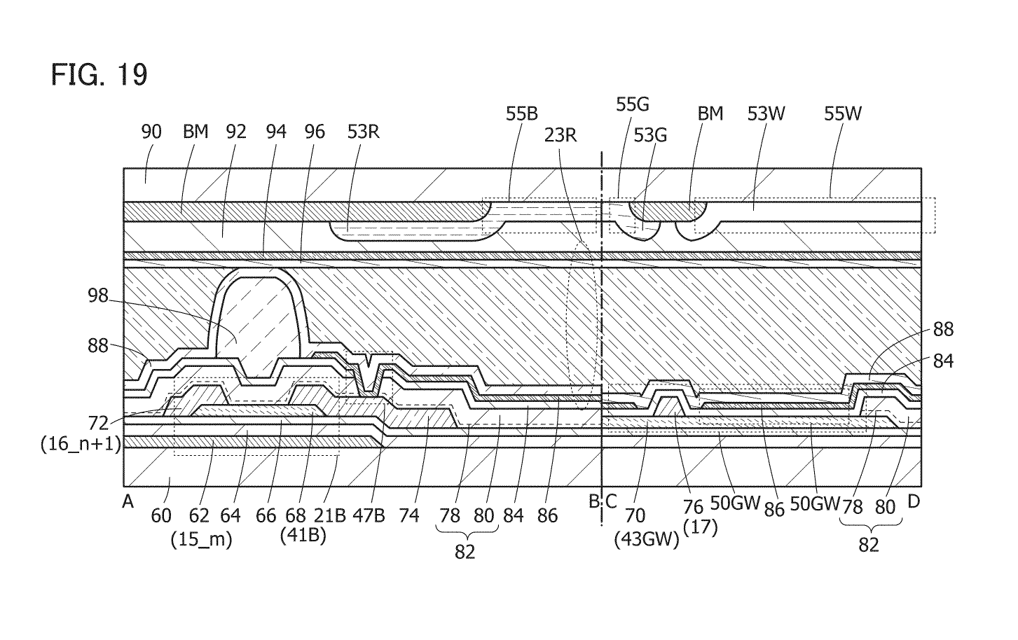

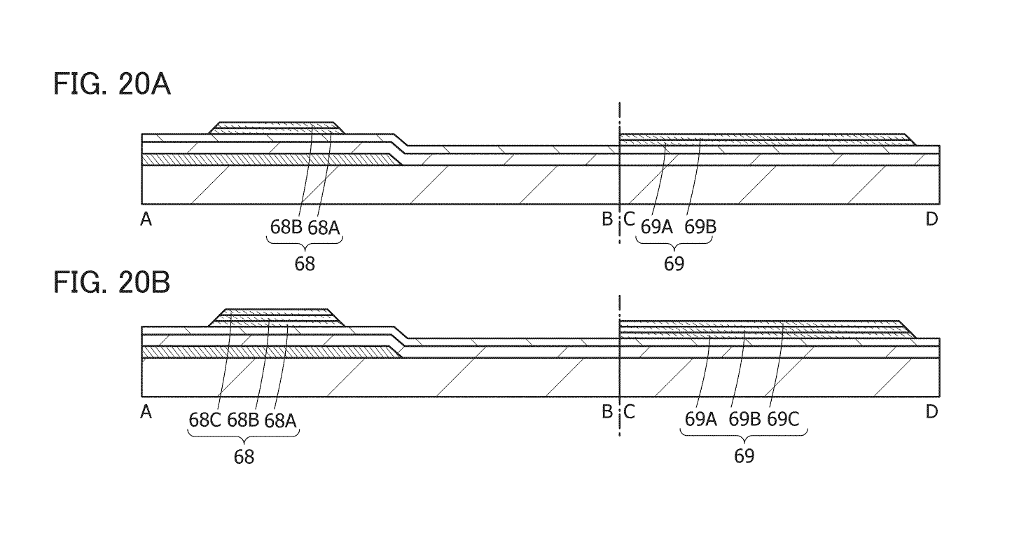

In this embodiment, modification examples of the components of the element substrate and/or the counter substrate in Embodiment 1 are described with reference to FIG. 18, FIG. 19, FIGS. 20A and 20B, FIGS. 21A and 21B, FIGS. 22A to 22C, FIGS. 23A and 23B, FIG. 24, and FIGS. 25A and 25B.

### Modification Example 1

As a modification example of the transistor 21B (21R, 21B, or 21W) included in the pixel portion of FIG. 7 in Embodiment 1, an insulating film 98 may be provided to overlap the oxide semiconductor film 68 as illustrated in FIG. 18.

The thickness of the insulating film 98 is preferably 500 nm to 10 μm.

The insulating film 98 is formed using an organic resin such as an acrylic resin, a polyimide resin, or an epoxy resin. The insulating film 98 formed using an organic resin is referred to as an organic insulating film in some cases.

The transistor 21B (21R, 21B, or 21W) in FIG. 18 includes the insulating film 98 over the insulating film 84. Since the thickness of the insulating film 98 is as large as 500 nm or more, the electric field generated by application of negative voltage to the conductive film 62 functioning as a gate electrode does not affect the surface of the insulating film 98, and the surface of the insulating film 98 is hardly charged with positive charge. In addition, even when positive charge particles contained in air are adsorbed to the surface of the insulating film 98, the electric field of the positive charge particles adsorbed to the surface of the insulating film 98 hardly affects the interface between the oxide semiconductor film 68 and the insulating film 84 because the thickness of the insulating film 98 is as large as 500 nm or more. Thus, substantially positive bias is not applied to the interface between the oxide semiconductor film 68 and the insulating film 84, so that variations in the threshold voltage of the transistor are small.

Accordingly, when the isolated insulating film 98 is provided over the transistor, variations in the electrical characteristics of the transistor can be reduced. In addition, a normally-off transistor having high reliability can be formed. Furthermore, the insulating film 98 can be formed by a printing method, a coating method, or the like; thus, manufacturing time can be shortened.

Note that although not illustrated, also in the transistor 21R, 21B, or 21W, the insulating film 98 can be formed as in FIG. 18.

As illustrated in FIG. 19, the alignment film 88 over the insulating film 98 and the alignment film 96 included in the element layer on the substrate 90 may be in contact with each other. In that case, the insulating film 98 functions as a spacer; therefore, the cell gap of the liquid crystal display device can be maintained with the insulating film 98.

### Modification Example 2

As modification examples of the oxide semiconductor films 68 and 69 of FIG. 12D in Embodiment 1, the oxide semiconductor film can have a layered structure as illustrated in FIGS. 20A and 20B.

In a transistor of FIG. 20A, oxide semiconductor films 68A and 68B are formed as the oxide semiconductor film 68, and oxide semiconductor films 69A and 69B are formed as the oxide semiconductor film 69.

The oxide semiconductor films 68B and 69B contain one or more elements that form the oxide semiconductor films 68A and 69A. Since the oxide semiconductor films 68B and 69B contain one or more elements that form the oxide semiconductor films 68A and 69A, interface scattering is unlikely to occur at an interface between the oxide semiconductor films 68A and 69A and the oxide semiconductor films 68B and 69B. Thus, the transistor can have high field-effect mobility because the movement of carriers is not hindered at the interface.

For example, for the oxide semiconductor films 68A and 69A, an In—Ga—Zn oxide with an atomic ratio of In:Ga:Zn=1:1:1, 1:1:1.2, or 3:1:2 can be used. For the oxide semiconductor films 68B and 69B, an In—Ga—Zn oxide with an atomic ratio of In:Ga:Zn=1:3:n (n is an integer of 2 or more and 8 or less), 1:6:m (m is an integer of 2 or more and 10 or less), or 1:9:6 can be used.

The oxide semiconductor films 68B and 69B also function as films that relieve damage to the oxide semiconductor films 68A and 69A at the time of forming the insulating film 80 later.

Note that in FIG. 20A, two-layer structures of the oxide semiconductor films 68A and 69A and the oxide semiconductor films 68B and 69B are used; however, as illustrated in FIG. 20B, three-layer structures of the oxide semiconductor films 68A and 69A, the oxide semiconductor films 68B and 69B, and oxide semiconductor films 68C and 69C may be used.

### Modification Example 3

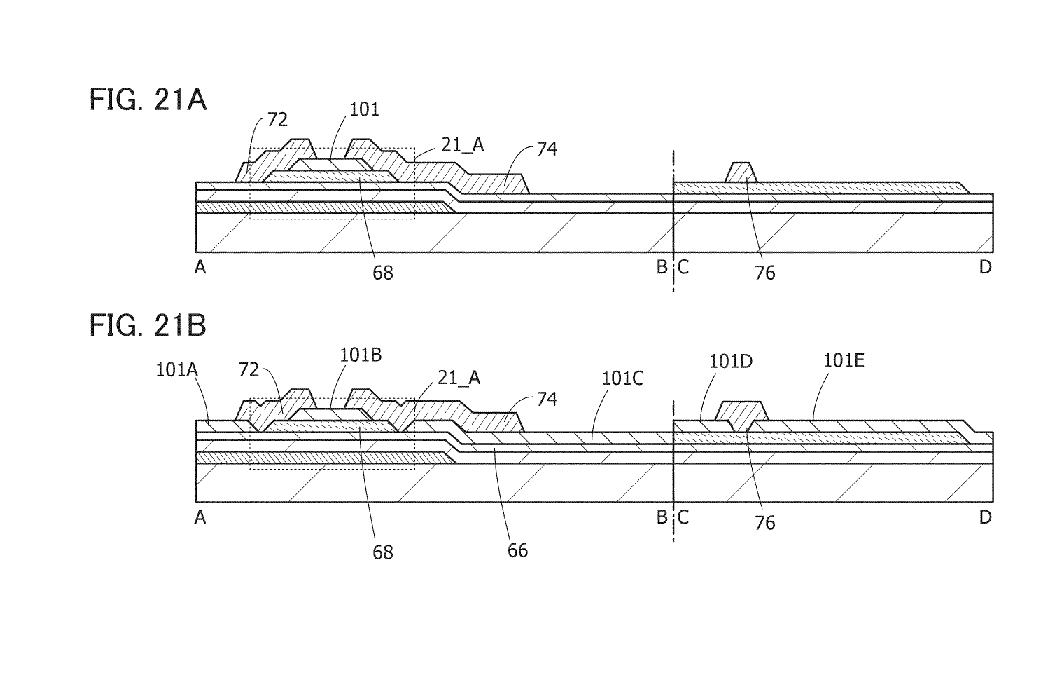

As a modification example of the transistor 21B of FIG. 13B in Embodiment 1, as illustrated in FIGS. 21A and 21B, a channel-protective structure in which an insulating film functioning as a protective film is provided over an oxide semiconductor film can be used.

In a transistor 21_A of FIG. 21A, an insulating film 101 functioning as a protective film is formed over the oxide semiconductor film 68. The insulating film 101 can be formed like the insulating film 82, for example.

Alternatively, as in a transistor 21_B of FIG. 21B, insulating films 101A to 101E obtained by formation of openings in an insulating film functioning as a protective film over the oxide semiconductor film 68 may be included.

### Modification Example 4

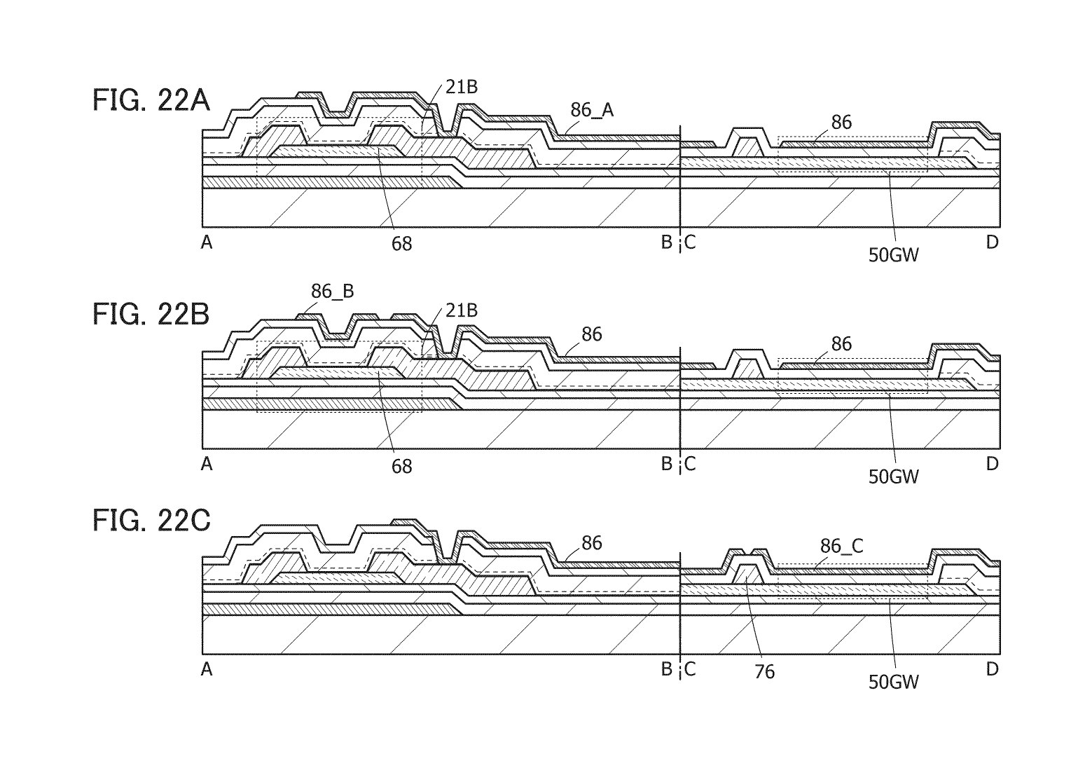

A modification example of the conductive film 86 of FIG. 15B in Embodiment 1 is described with reference to FIGS. 22A to 22C.

A conductive film 86_A in FIG. 22A is formed over the oxide semiconductor film 68 of the transistor 21B. Thus, the transistor 21B can be a dual-gate transistor with high reliability, high on-state current, and high field-effect mobility. Accordingly, a display device with high display quality can be manufactured.

Alternatively, as illustrated in FIG. 22B, a conductive film 86_B provided over the oxide semiconductor film 68 of the transistor 21B may be electrically isolated from the conductive film 86 used as a pixel electrode. With this structure, the conductive film 86 and the conductive film 86_B can be controlled by different potentials.

Alternatively, as illustrated in FIG. 22C, a conductive film 86_C separated along the conductive film 76 may be separated along a region overlapping the conductive film 76.

### Modification Example 5

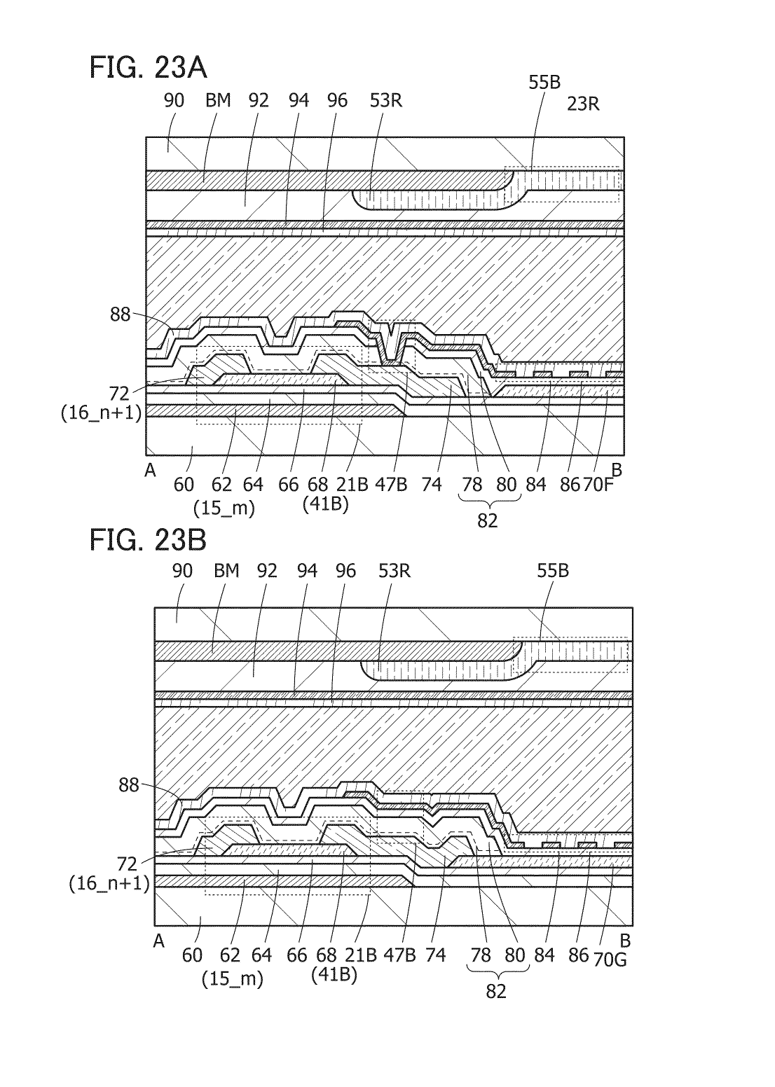

Modification examples of the cross-sectional view taken along line A-B of FIG. 7 in Embodiment 1 are described with reference to FIGS. 23A and 23B.

As illustrated in FIG. 23A, an electrode may be formed so that the conductive film 86 has a comb shape (cross-sectional shape in FIG. 23A), and a pair of electrodes may be formed in a plane shape. In that case, a common electrode that pairs up with the conductive film 86 functioning as a pixel electrode is formed as a metal oxide film 70F.

Alternatively, as illustrated in FIG. 23B, an electrode may be formed so that the conductive film 86 has a comb shape (cross-sectional shape in FIG. 23B), and a common electrode may be formed. In that case, the conductive film 74 of the transistor 21B is connected to the metal oxide film 70F, and a metal oxide film 70G is used as a pixel electrode.

### Modification Example 6

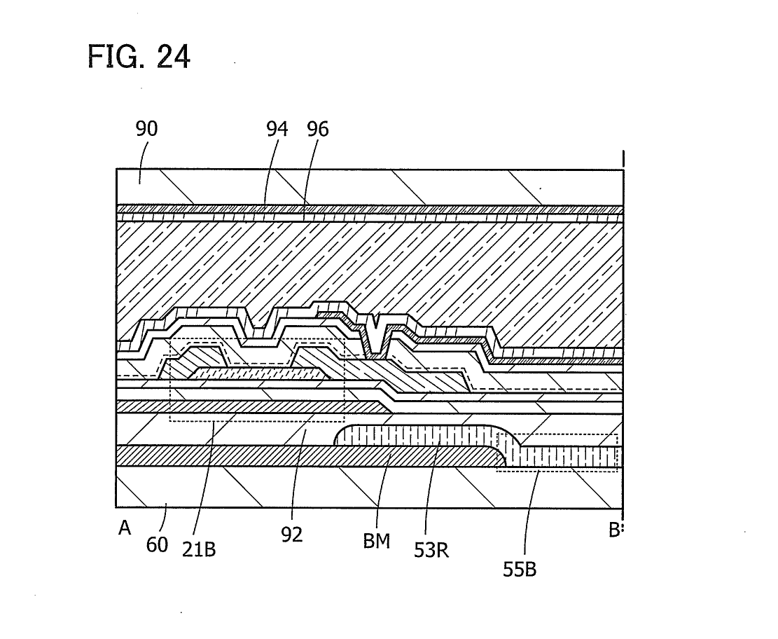

A modification example of the cross-sectional view taken along line A-B of FIG. 7 in Embodiment 1 is described with reference to FIG. 24. In particular, a modification example is described in which the light-blocking films BM and the color filters 53R and 53B that are provided on the substrate 90 side are provided on the substrate 60 side.

This structure can facilitate the structure of the substrate 90 side and formation of an electrode or the like of a touch panel on the substrate 90.

### Modification Example 7

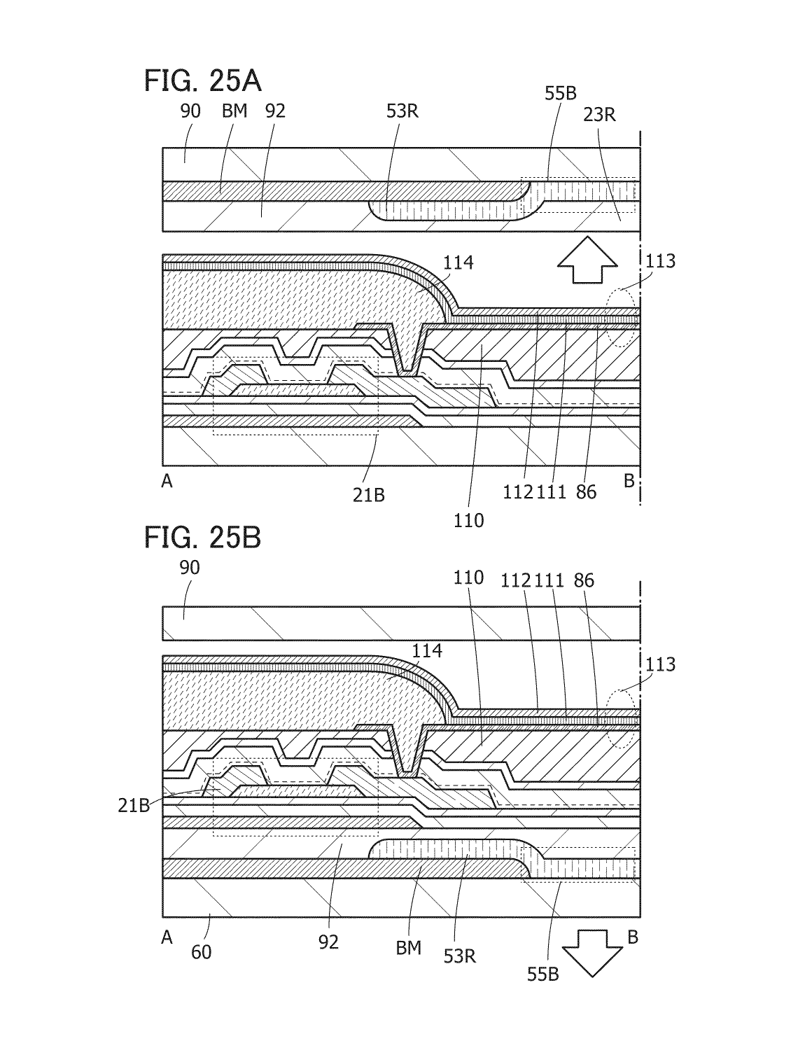

Modification examples of the cross-sectional view taken along line A-B of FIG. 7 in Embodiment 1 are described with reference to FIGS. 25A and 25B.

FIG. 25A is a structure example of a cross-sectional view of a subpixel including an EL element 113 as a display element. The EL element 113 is formed after an insulating film 110 for improving the flatness of a surface on which the EL element 113 is provided is formed. Over the insulating film 110, an insulating film 114 functioning as a partition layer is formed. In addition, over the conductive film 86 functioning as one electrode, the EL layer 111 and a conductive layer 112 functioning as the other electrode are formed.

In the case of the structure in FIG. 25A, a combination with the structure in FIG. 24 can achieve a structure in FIG. 25B. Note that in FIGS. 25A and 25B, arrows indicate light emission.

Note that the structures, methods, and the like described in this embodiment can be combined with any of the structures, methods, and the like described in the other embodiments as appropriate.

### Embodiment 3

In this embodiment, one embodiment that can be applied to an oxide semiconductor film in the transistor included in the display device described in the above embodiment is described.

The oxide semiconductor film may include one or more of the following: an oxide semiconductor having a single-crystal structure (hereinafter referred to as a single-crystal oxide semiconductor); an oxide semiconductor having a polycrystalline structure (hereinafter referred to as a polycrystalline oxide semiconductor); an oxide semiconductor having a microcrystalline structure (hereinafter referred to as a microcrystalline oxide semiconductor); and an oxide semiconductor having an amorphous structure (hereinafter referred to as an amorphous oxide semiconductor). Alternatively, the oxide semiconductor film may be a CAAC-OS film. Alternatively, the oxide semiconductor film may include an amorphous oxide semiconductor and an oxide semiconductor having a crystal grain. The CAAC-OS and the microcrystalline oxide semiconductor are described below as typical examples.

First, a CAAC-OS film is described.

The CAAC-OS film is one of oxide semiconductor films having a plurality of c-axis aligned crystal parts.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology that reflects a surface over which the CAAC-OS film is formed (also referred to as a formation surface) or a top surface of the CAAC-OS film, and is provided parallel to the formation surface or the top surface of the CAAC-OS film.

On the other hand, according to the TEM image of the CAAC-OS film observed in a direction substantially perpendicular to the sample surface (planar TEM image), metal atoms are arranged in a triangular or hexagonal configuration in the crystal parts. However, there is no regularity of arrangement of metal atoms between different crystal parts.

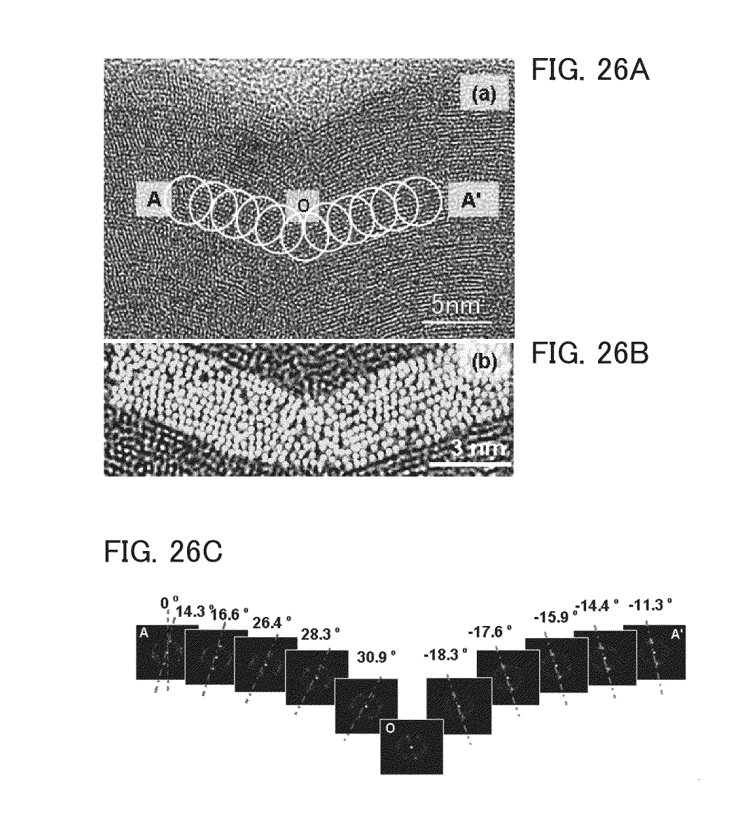

FIG. 26A is a cross-sectional TEM image of a CAAC-OS film. FIG. 26B is a cross-sectional TEM image obtained by enlarging the image of FIG. 26A. In FIG. 26B, atomic order is highlighted for easy understanding.

FIG. 26C shows Fourier transform images of regions each surrounded by a circle (diameter is approximately 4 nm) between A and O and between O and A′ in FIG. 26A. C-axis alignment can be observed in each region in FIG. 26C. The c-axis direction between A and O is different from that between O and A′, which indicates that a grain in the region between A and O is different from that between O and A′. In addition, between A and O, the angle of the c-axis continuously and gradually changes, for example, 14.3°, 16.6°, and 26.4°. Similarly, between O and A′, the angle of the c-axis continuously changes, for example, −18.3°, −17.6°, and −15.9°.

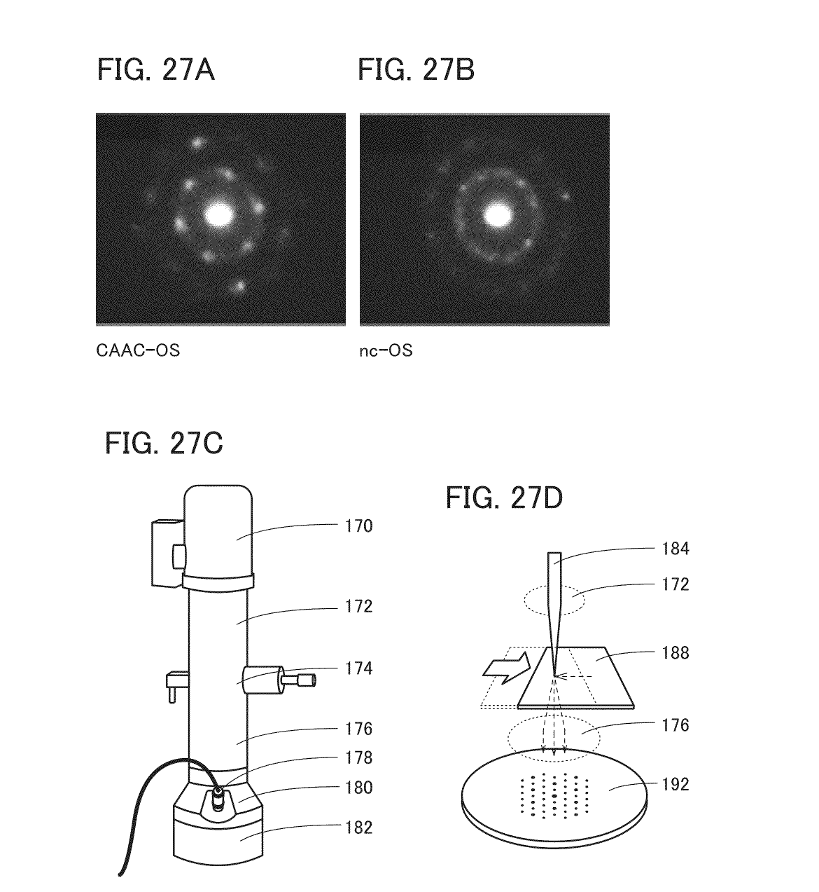

Note that in an electron diffraction pattern of the CAAC-OS film, spots (bright spots) indicating alignment are observed. For example, when electron diffraction with an electron beam having a diameter of 1 to 30 nm (such electron diffraction is also referred to as nanobeam electron diffraction) is performed on the top surface of the CAAC-OS film, spots are observed (see FIG. 27A).

From the results of the cross-sectional TEM image and the planar TEM image, alignment is found in the crystal parts in the CAAC-OS film.

Most of the crystal parts included in the CAAC-OS film each fit into a cube whose one side is less than 100 nm. Thus, there is a case where a crystal part included in the CAAC-OS film fits into a cube whose one side is less than 10 nm, less than 5 nm, or less than 3 nm Note that when a plurality of crystal parts included in the CAAC-OS film are connected to each other, one large crystal region is formed in some cases. For example, a crystal region with an area of larger than or equal to 2500 nm², larger than or equal to 5 μm², or larger than or equal to 1000 μm² is observed in some cases in the planar TEM image.

The CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer which is arranged in a layered manner and observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where the shape of the CAAC-OS film is changed by etching or the like, the c-axis might not be necessarily parallel to a normal vector of a formation surface or a normal vector of a top surface of the CAAC-OS film.

In addition, distribution of c-axis aligned crystal parts in the CAAC-OS film is not necessarily uniform. For example, in the case where crystal growth leading to the crystal parts of the CAAC-OS film occurs from the vicinity of the top surface of the film, the proportion of the c-axis aligned crystal parts in the vicinity of the top surface is higher than that in the vicinity of the formation surface in some cases. Furthermore, when an impurity is added to the CAAC-OS film, a region to which the impurity is added is altered, and the proportion of the c-axis aligned crystal parts in the CAAC-OS film varies depending on regions, in some cases.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ not appear at around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic order of the oxide semiconductor film by depriving the oxide semiconductor film of oxygen and causes a decrease in crystallinity. Furthermore, a heavy metal such as iron or nickel, argon, carbon dioxide, or the like has a large atomic radius (molecular radius), and thus disturbs the atomic order of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as “highly purified intrinsic” or “substantially highly purified intrinsic.” A highly purified intrinsic or substantially highly purified intrinsic oxide semiconductor film has few carrier generation sources, and thus can have low carrier density. Thus, a transistor including the oxide semiconductor film rarely has negative threshold voltage (is rarely normally on). The highly purified intrinsic or substantially highly purified intrinsic oxide semiconductor film has few carrier traps. Accordingly, the transistor including the oxide semiconductor film has few variations in electrical characteristics and high reliability. Charge trapped by the carrier traps in the oxide semiconductor film takes a long time to be released and may behave like fixed charge. Thus, the transistor that includes the oxide semiconductor film having high impurity concentration and high density of defect states has unstable electrical characteristics in some cases.

In a transistor including the CAAC-OS film, changes in electrical characteristics of the transistor due to irradiation with visible light or ultraviolet light are small.

Next, a microcrystalline oxide semiconductor film is described.

In a TEM image, crystal parts cannot be found clearly in the microcrystalline oxide semiconductor film in some cases. In most cases, a crystal part in the microcrystalline oxide semiconductor film is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm is specifically referred to as nanocrystal (nc). An oxide semiconductor film including nanocrystal is referred to as a nanocrystalline oxide semiconductor (nc-OS) film. In a TEM image, a grain boundary cannot be found clearly in the nc-OS film in some cases.

In the nc-OS film, a microscopic region (e.g., a region with a size greater than or equal to 1 nm and less than or equal to 10 nm, in particular, a region with a size greater than or equal to 1 nm and less than or equal to 3 nm) has periodic atomic order. There is no regularity of crystal orientation between different crystal parts in the nc-OS film. Thus, the orientation of the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than that of a crystal part, a peak that shows a crystal plane does not appear. Furthermore, a halo pattern is shown in a selected-area electron diffraction pattern of the nc-OS film obtained by using an electron beam having a probe diameter larger than the diameter of a crystal part (e.g., larger than or equal to 50 nm). Meanwhile, spots are shown in a nanobeam electron diffraction pattern of the nc-OS film obtained by using an electron beam having a probe diameter close to or smaller than the diameter of a crystal part. Furthermore, in a nanobeam electron diffraction pattern of the nc-OS film, regions with high luminance in a circular (ring) pattern are observed in some cases. Also in a nanobeam electron diffraction pattern of the nc-OS film, a plurality of spots are shown in a ring-like region in some cases (see FIG. 27B).

The nc-OS film is an oxide semiconductor film that has high regularity than an amorphous oxide semiconductor film. Thus, the nc-OS film has a lower density of defect states than the amorphous oxide semiconductor film. Note that there is no regularity of crystal orientation between different crystal parts in the nc-OS film; thus, the nc-OS film has a higher density of defect states than the CAAC-OS film.

Note that an oxide semiconductor film may be a stacked film including two or more films of an amorphous oxide semiconductor film, a microcrystalline oxide semiconductor film, and a CAAC-OS film, for example.

In the case where the oxide semiconductor film has a plurality of structures, the structures can be analyzed using nanobeam electron diffraction in some cases.

FIG. 27C illustrates a transmission electron diffraction measurement apparatus. The transmission electron diffraction measurement apparatus includes an electron gun chamber 170, an optical system 172 below the electron gun chamber 170, a sample chamber 174 below the optical system 172, an optical system 176 below the sample chamber 174, an observation chamber 180 below the optical system 176, a camera 178 provided for the observation chamber 180, and a film chamber 182 below the observation chamber 180. The camera 178 is provided to face toward the inside of the observation chamber 180. Note that the film chamber 182 is not necessarily provided.

FIG. 27D illustrates the internal structure of the transmission electron diffraction measurement apparatus in FIG. 27C. In the transmission electron diffraction measurement apparatus, a substance 188 that is positioned in the sample chamber 174 is irradiated with electrons emitted from an electron gun installed in the electron gun chamber 170 through the optical system 172. Electrons passing through the substance 188 enter a fluorescent plate 192 provided in the observation chamber 180 through the optical system 176. On the fluorescent plate 192, a pattern corresponding to the intensity of the incident electron appears, which enables measurement of a transmission electron diffraction pattern.

The camera 178 is installed to face the fluorescent plate 192 and can take a picture of a pattern appearing in the fluorescent plate 192. An angle formed by a straight line that passes through the center of a lens of the camera 178 and the center of the fluorescent plate 192 and an upper surface of the fluorescent plate 192 is, for example, 15 to 80°, 30 to 75°, or 45 to 70°. As the angle is reduced, distortion of the transmission electron diffraction pattern taken by the camera 178 becomes larger. Note that if the angle is obtained in advance, distortion of an obtained transmission electron diffraction pattern can be corrected. The camera 178 may be set in the film chamber 182 in some cases. For example, the camera 178 may be set in the film chamber 182 to be opposite to the incident direction of electrons 184. In that case, a transmission electron diffraction pattern with less distortion can be taken from a rear surface of the fluorescent plate 192.

A holder for fixing the substance 88 that is a sample is provided in the sample chamber 174. The holder transmits electrons passing through the substance 188. The holder may have, for example, a function of moving the substance 188 along the x-axis, the y-axis, the z-axis, or the like. The movement function of the holder may have an accuracy of moving the substance in the range of, for example, 1 to 10 nm, 5 to 50 nm, 10 to 100 nm, 50 to 500 nm, and 100 nm to 1 μm. The range is preferably optimized depending on the structure of the substance 188.

Then, a method for measuring a transmission electron diffraction pattern of a substance by the transmission electron diffraction measurement apparatus is described.

For example, changes in the structure of a substance can be observed by changing (scanning) the irradiation position of the electrons 184 that are a nanobeam in the substance, as illustrated in FIG. 27D. At this time, when the substance 188 is a CAAC-OS film, a diffraction pattern as shown in FIG. 27A is observed. When the substance 188 is an nc-OS film, a diffraction pattern shown in FIG. 27B is observed.

Even when the substance 188 is a CAAC-OS film, a diffraction pattern similar to that of an nc-OS film or the like is partly observed in some cases. Therefore, whether a CAAC-OS film is favorable can be determined by the proportion of a region where a diffraction pattern of a CAAC-OS film is observed in a predetermined area (also referred to as proportion of CAAC). In the case of a high quality CAAC-OS film, for example, the proportion of CAAC is higher than or equal to 50%, preferably higher than or equal to 80%, more preferably higher than or equal to 90%, still preferably higher than or equal to 95%. Note that the proportion of a region where a diffraction pattern different from that of a CAAC-OS film is observed is referred to as the proportion of non-CAAC.

For example, transmission electron diffraction patterns were obtained by scanning a top surface of a sample including a CAAC-OS film obtained immediately after deposition (represented as “as-sputtered”) and a top surface of a sample including a CAAC-OS subjected to heat treatment at 450° C. in an atmosphere containing oxygen. Here, the proportion of CAAC was obtained in such a manner that diffraction patterns were observed by scanning for 60 seconds at a rate of 5 nm/s and the obtained diffraction patterns were converted into still images every 0.5 seconds. Note that as an electron beam, a nanobeam with a probe diameter of 1 nm was used. The above measurement was also performed on six samples. The proportion of CAAC was calculated using the average value of the six samples.

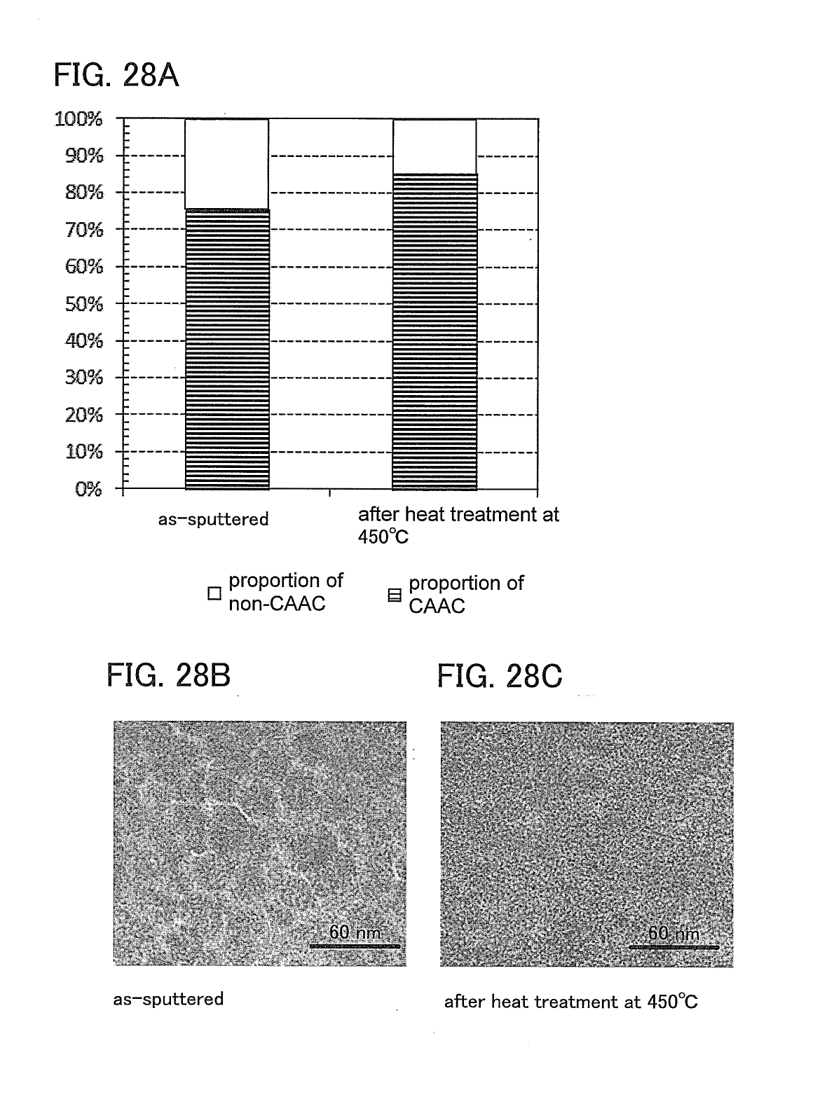

FIG. 28A shows the proportion of CAAC in each sample. The proportion of CAAC of the CAAC-OS film obtained immediately after the deposition was 75.7% (the proportion of non-CAAC was 24.3%). The proportion of CAAC of the CAAC-OS film subjected to the heat treatment at 450° C. was 85.3% (the proportion of non-CAAC was 14.7%). These results show that the proportion of CAAC obtained after the heat treatment at 450° C. is higher than that obtained immediately after the deposition. That is, heat treatment at high temperature (e.g., higher than or equal to 400° C.) reduces the proportion of non-CAAC (increases the proportion of CAAC). The above results also indicate that even when the temperature of the heat treatment is lower than 500° C., the CAAC-OS film can have a high proportion of CAAC.

Here, most of diffraction patterns different from that of a CAAC-OS film were similar to that of an nc-OS film. Furthermore, an amorphous oxide semiconductor film was not able to be observed in a measurement region. Thus, the results suggest that a region having a structure similar to that of an nc-OS film is rearranged by the heat treatment owing to the influence of the structure of an adjacent region, so that the region becomes CAAC.

FIGS. 28B and 28C are planar TEM images of the CAAC-OS film obtained immediately after the deposition and the CAAC-OS film subjected to the heat treatment at 450° C., respectively. Comparison between FIGS. 28B and 28C shows that the CAAC-OS film subjected to the heat treatment at 450° C. has more even film quality. That is, the heat treatment at high temperature improves the film quality of the CAAC-OS film.

With such a measurement method, the structure of an oxide semiconductor film having a plurality of structures can be analyzed in some cases.

Note that the structures, methods, and the like described in this embodiment can be combined with any of the structures, methods, and the like described in the other embodiments as appropriate.

### Embodiment 4

In the transistor including an oxide semiconductor film, current in an off state (off-state current) can be made low, as described in Embodiment 1. Accordingly, an electric signal such as an image signal can be held for a longer period and a writing interval can be set longer.

With the use of a transistor with low off-state current, a display device in this embodiment can display images by at least two driving methods (modes). A first driving mode is a conventional driving method of a display device, in which data is rewritten sequentially every frame. A second driving mode is a driving method in which data rewriting is stopped after data writing is executed, i.e. a driving mode with a reduced refresh rate.

Moving images are displayed in the first driving mode. A still image can be displayed without change in image data every frame; thus, it is not necessary to rewrite data every frame. When the display device is driven in the second driving mode in displaying still images, power consumption can be reduced with fewer screen flickers.

The amount of charge accumulated in a capacitor in a pixel used in the display device in this embodiment is large. Thus, it is possible to hold the potential of a pixel electrode for a longer time and to apply a driving mode with a reduced refresh rate. In addition, a change in voltage held in the pixel can be inhibited for a long time even when the display device is used in the driving mode with a reduced refresh rate. This makes it possible to prevent screen flickers from being perceived by a user more effectively. Thus, power consumption can be reduced and display quality can be improved.

An effect of reducing the refresh rate is described here.

Eye strain is divided into two categories: nerve strain and muscle strain. The nerve strain is caused by prolonged looking at light emitted from a display device or blinking images. This is because brightness stimulates and fatigues the retina and nerve of the eye and the brain. The muscle strain is caused by overuse of a ciliary muscle that works for adjusting the focus.

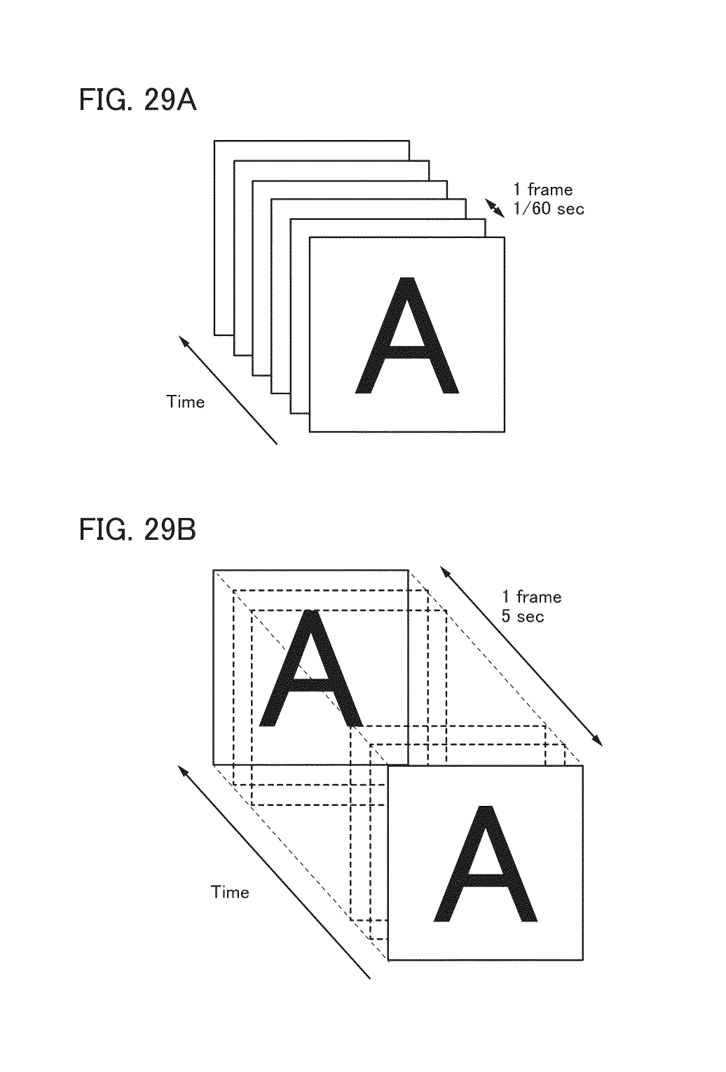

FIG. 29A is a schematic diagram showing display on a conventional display device. As illustrated in FIG. 29A, for the display of the conventional liquid crystal display device, image rewriting is performed 60 times every second. Prolonged looking at such a screen might stimulate the retina and nerve of the eye and the brain of a user and lead to eye strain.

In one embodiment of the present invention, a transistor with extremely low off-state current (e.g., a transistor including an oxide semiconductor) is used in a pixel portion of a display device. In addition, the capacitor included in the pixel of the display device can have large area. With these components, leakage of charge accumulated in the capacitor can be inhibited and a change in the potential can be made gradual; thus, the luminance of the display device can be suppressed even at lower frame frequency.

In other words, as shown in FIG. 29B, an image can be rewritten once every five seconds, for example. This enables the user to see the same image as long as possible, so that flickers on the screen recognized by the user are reduced. Consequently, stimuli to the retina and nerve of the eye and the brain of the user are relieved, resulting in less nerve strain.

According to one embodiment of the present invention, an eye-friendly display device can be provided

Note that the structures, methods, and the like described in this embodiment can be combined with any of the structures, methods, and the like described in the other embodiments as appropriate.

### Embodiment 5

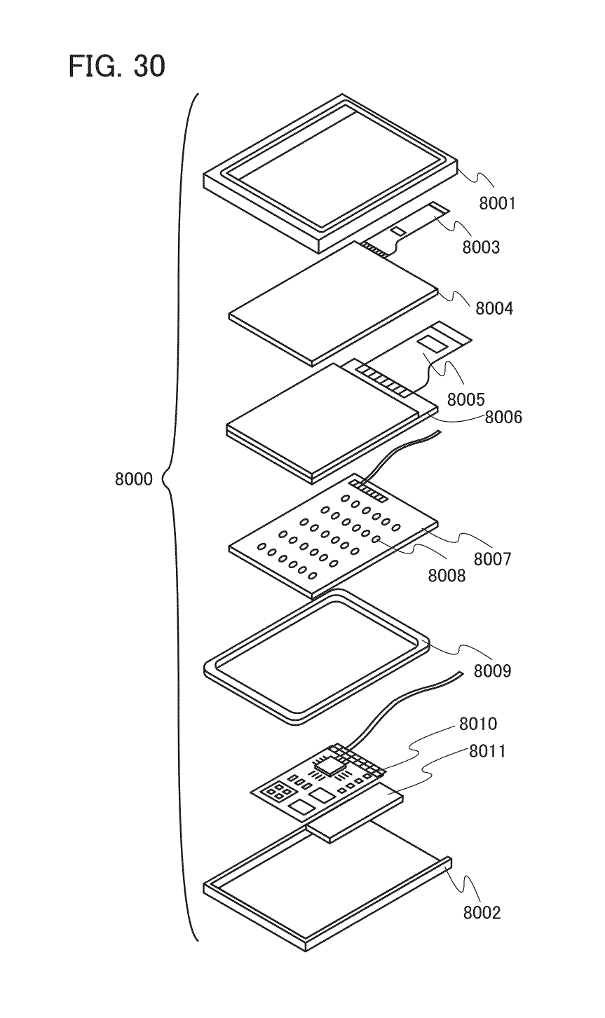

In this embodiment, structural examples of electronic devices each including a display device according to one embodiment of the present invention are described. In addition, in this embodiment, a display module including a display device according to one embodiment of the present invention is described with reference to FIG. 30.

In a display module 8000 in FIG. 30, a touch panel 8004 connected to an FPC 8003, a display panel 8006 connected to an FPC 8005, a backlight unit 8007, a frame 8009, a printed board 8010, and a battery 8011 are provided between an upper cover 8001 and a lower cover 8002. Note that the backlight unit 8007, the battery 8011, the touch panel 8004, and the like are not provided in some cases.

The display device according to one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and may be formed to overlap the display panel 8006. A counter substrate (sealing substrate) of the display panel 8006 can have a touch panel function. An optical sensor may be provided in each pixel of the display panel 8006 to form an optical touch panel. An electrode for a touch sensor may be provided in each pixel of the display panel 8006 to form a capacitive touch panel.

The backlight unit 8007 includes a light source 8008. The light source 8008 may be provided at an end portion of the backlight unit 8007 and a light diffusion plate may be used.

The frame 8009 protects the display panel 8006 and functions as an electromagnetic shield for blocking electromagnetic waves generated by the operation of the printed board 8010. The frame 8009 may function as a radiator plate.

The printed board 8010 includes a power supply circuit and a signal processing circuit for outputting video signals and clock signals. As a power source for supplying power to the power supply circuit, an external commercial power source or a separate power source using the battery 8011 may be used. The battery 8011 can be omitted when a commercial power source is used.

The display module 8000 may be additionally provided with a member such as a polarizing plate, a retardation plate, or a prism sheet.

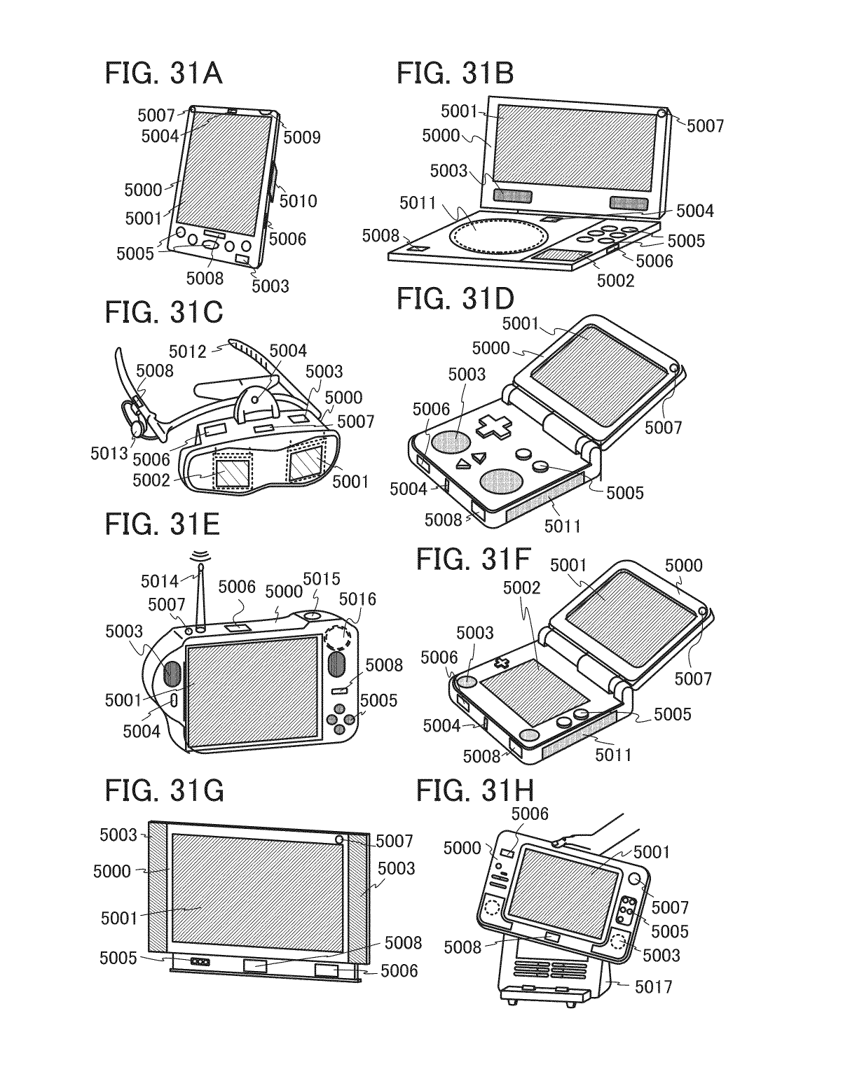

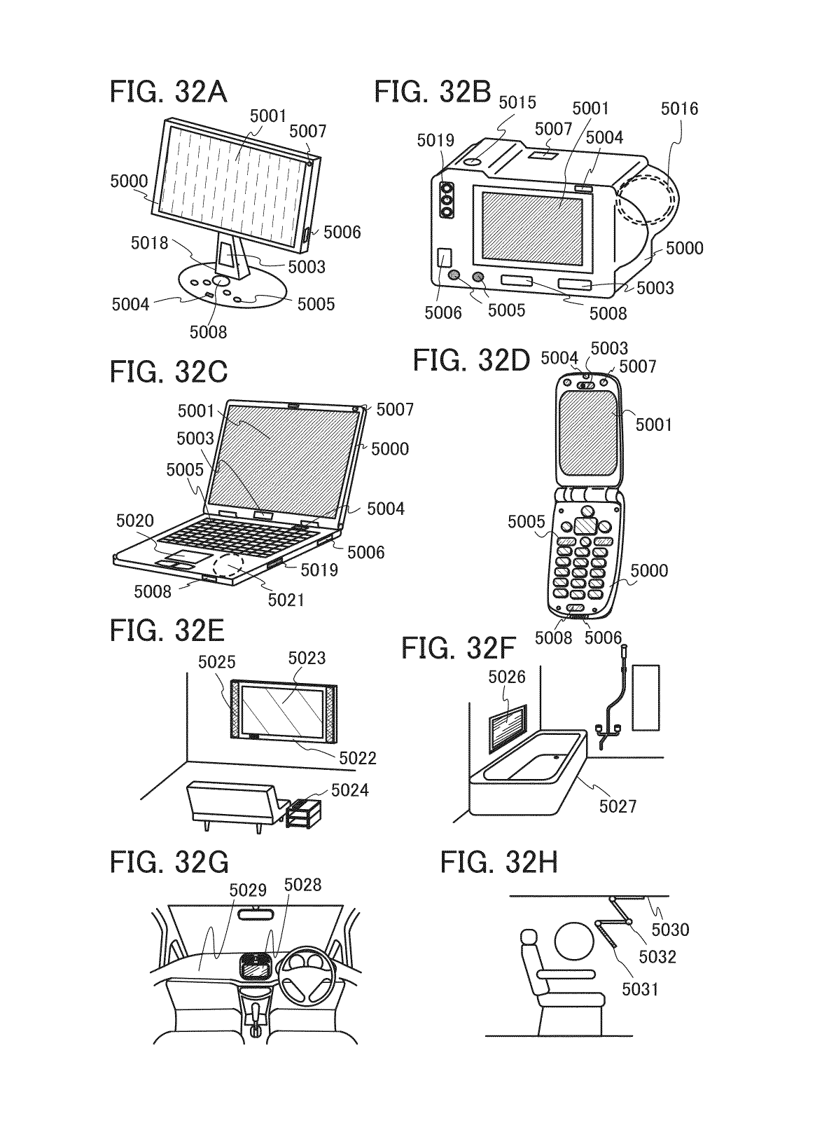

FIGS. 31A to 31H and FIGS. 32A to 32D illustrate electronic devices. These electronic devices can include a housing 5000, a display portion 5001, a speaker 5003, an LED lamp 5004, operation keys 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, smell, or infrared ray), a microphone 5008, and the like.

FIG. 31A illustrates a portable computer, which can include a switch 5009, an infrared port 5010, and the like in addition to the above objects. FIG. 31B illustrates a portable image reproducing device provided with a memory medium (e.g., a DVD reproducing device), which can include a second display portion 5002, a memory medium read portion 5011, and the like in addition to the above objects. FIG. 31C illustrates a goggle-type display, which can include the second display portion 5002, a support 5012, an earphone 5013, and the like in addition to the above objects. FIG. 31D illustrates a portable game machine, which can include the memory medium read portion 5011 and the like in addition to the above objects. FIG. 31E illustrates a digital camera with a television reception function, which can include an antenna 5014, a shutter button 5015, an image reception portion 5016, and the like in addition to the above objects. FIG. 31F illustrates a portable game machine, which can include the second display portion 5002, the memory medium read portion 5011, and the like in addition to the above objects. FIG. 31G illustrates a television receiver, which can include a tuner, an image processing portion, and the like in addition to the above objects. FIG. 31H illustrates a portable television receiver, which can include a charger 5017 capable of transmitting and receiving signals and the like in addition to the above objects. FIG. 32A illustrates a display, which can include a support base 5018 and the like in addition to the above objects. FIG. 32B illustrates a camera, which can include an external connection port 5019, a shutter button 5015, an image reception portion 5016, and the like in addition to the above objects. FIG. 32C illustrates a computer, which can include a pointing device 5020, the external connection port 5019, a reader/writer 5021, and the like in addition to the above objects. FIG. 32D illustrates a mobile phone, which can include a transmitter, a receiver, a tuner of lseg partial reception service for mobile phones and mobile terminals, and the like in addition to the above objects.

The electronic devices in FIGS. 31A to 31H and FIGS. 32A to 32D can have a variety of functions, for example, a function of displaying a lot of information (e.g., a still image, a moving image, and a text image) on a display portion; a touch panel function; a function of displaying a calendar, date, time, and the like; a function of controlling processing with a lot of software (programs); a wireless communication function; a function of being connected to a variety of computer networks with a wireless communication function; a function of transmitting and receiving a lot of data with a wireless communication function; a function of reading a program or data stored in a memory medium and displaying the program or data on a display portion. In addition, the electronic device including a plurality of display portions can have a function of displaying image information mainly on one display portion while displaying text information on another display portion, a function of displaying a three-dimensional image by displaying images where parallax is considered on a plurality of display portions, or the like. Furthermore, the electronic device including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that functions that can be provided for the electronic devices in FIGS. 31A to 31H and FIGS. 32A to 32D are not limited thereto, and the electronic devices can have a variety of functions.

The electronic devices in this embodiment each include a display portion for displaying some kind of information.

Next, application examples of the display device are described.

FIG. 32E illustrates an example in which a display device is incorporated in a building structure. FIG. 32E illustrates a housing 5022, a display portion 5023, a remote control 5024 that is an operation portion, a speaker 5025, and the like. The display device is incorporated in the building structure as a wall-hanging type and can be provided without requiring a large space.

FIG. 32F illustrates another example in which a display device is incorporated in a building structure. A display module 5026 is incorporated in a prefabricated bath unit 5027, so that a bather can view the display module 5026.

Note that although this embodiment describes the wall and the prefabricated bath unit as examples of the building structures, this embodiment is not limited thereto. The display devices can be provided in a variety of building structures.

Next, examples in which display devices are incorporated in moving objects are described.

FIG. 32G illustrates an example in which a display device is incorporated in a car. A display module 5028 is incorporated in a car body 5029 of the car and can display information related to the operation of the car or information input from the inside or outside of the car on demand. Note that the display module 5028 may have a navigation function.

FIG. 32H illustrates an example in which a display device is incorporated in a passenger airplane. FIG. 32H illustrates a usage pattern when a display module 5031 is provided for a ceiling 5030 above a seat of the passenger airplane. The display module 5031 is incorporated in the ceiling 5030 through a hinge portion 5032, and a passenger can view the display module 5031 by stretching of the hinge portion 5032. The display module 5031 has a function of displaying information by the operation of the passenger.

Note that although bodies of a car and an airplane are illustrated as examples of moving objects in this embodiment, this embodiment is not limited thereto. The display devices can be provided for a variety of objects such as two-wheeled vehicles, four-wheeled vehicles (including cars, buses, and the like), trains (including monorails, railroads, and the like), and vessels.

Note that in this specification and the like, in a diagram or a text described in one embodiment, part of the diagram or the text is taken out, and one embodiment of the invention can be constituted. Thus, in the case where a diagram or a text related to a certain portion is described, the context taken out from part of the diagram or the text is also disclosed as one embodiment of the invention, and one embodiment of the invention can be constituted. Therefore, for example, in a diagram or a text in which one or more active elements (e.g., transistors or diodes), wirings, passive elements (e.g., capacitors or resistors), conductive layers, insulating layers, semiconductor layers, organic materials, inorganic materials, components, devices, operating methods, manufacturing methods, or the like are described, part of the diagram or the text is taken out, and one embodiment of the invention can be constituted. For example, M circuit elements (e.g., transistors or capacitors) (M is an integer, where M<N) are taken out from a circuit diagram in which N circuit elements (e.g., transistors or capacitors) (N is an integer) are provided, and one embodiment of the invention can be constituted. As another example, M layers (M is an integer, where M<N) are taken out from a cross-sectional view in which N layers (N is an integer) are provided, and one embodiment of the invention can be constituted. As another example, M elements (M is an integer, where M<N) are taken out from a flow chart in which N elements (N is an integer) are provided, and one embodiment of the invention can be constituted.

Note that in this specification and the like, in a diagram or a text described in one embodiment, in the case where at least one specific example is described, it will be readily appreciated by those skilled in the art that a broader concept of the specific example can be derived. Thus, in the diagram or the text described in one embodiment, in the case where at least one specific example is described, a broader concept of the specific example is disclosed as one embodiment of the invention, and one embodiment of the invention can be constituted.

Note that in this specification and the like, content described in at least a diagram (or may be part of the diagram) is disclosed as one embodiment of the invention, and one embodiment of the invention can be constituted. Thus, when certain content is described in a diagram, the content is disclosed as one embodiment of the invention even when the content is not described with a text, and one embodiment of the invention can be constituted. Similarly, part of a diagram that is taken out from the diagram is disclosed as one embodiment of the invention, and one embodiment of the invention can be constituted.

This application is based on Japanese Patent Application serial No. 2013-245639 filed with Japan Patent Office on Nov. 28, 2013 and Japanese Patent Application serial No. 2014-038196 filed with Japan Patent Office on Feb. 28, 2014, the entire contents of which are hereby incorporated by reference.

What is claimed is:

1. A display device comprising:
a pixel comprising a first subpixel, a second subpixel, a third subpixel, and a fourth subpixel,
wherein the first subpixel is configured to control transmission of a red light and comprises a first opening for transmitting the red light,
wherein the second subpixel is configured to control transmission of a green light and comprises a second opening for transmitting the green light,
wherein the third subpixel is configured to control transmission of a blue light and comprises a third opening for transmitting the blue light,
wherein the fourth subpixel is configured to control transmission of a white light and comprises a fourth opening for transmitting the white light, and
wherein the fourth opening has the smallest area of the first opening, the second opening, the third opening, and the fourth opening.

2. The display device according to claim 1,
wherein the first subpixel, the second subpixel, the third subpixel, and the fourth subpixel are arranged in two rows by two columns in the pixel.

3. A display device comprising:
a pixel comprising a first subpixel, a second subpixel, a third subpixel, and a fourth subpixel,
wherein the first subpixel is configured to control transmission of a red light and comprises a first opening for transmitting the red light,
wherein the second subpixel is configured to control transmission of a green light and comprises a second opening for transmitting the green light,
wherein the third subpixel is configured to control transmission of a blue light and comprises a third opening for transmitting the blue light,
wherein the fourth subpixel is configured to control transmission of a white light and comprises a fourth opening for transmitting the white light,
wherein the fourth opening has the smallest area of the first opening, the second opening, the third opening, and the fourth opening,
wherein each of the first subpixel, the second subpixel, the third subpixel, and the fourth subpixel comprises a transistor and a capacitor,
wherein the transistor comprises an oxide semiconductor film,
wherein the capacitor comprises a first electrode comprising a metal oxide film and a second electrode comprising a light-transmitting conductive film,
wherein an inorganic insulating film is over the transistor and over and in contact with the metal oxide film, and
wherein the light-transmitting conductive film is over the inorganic insulating film and electrically connected to the transistor.

4. The display device according to claim 3,
wherein the first subpixel, the second subpixel, the third subpixel, and the fourth subpixel are arranged in two rows by two columns in the pixel.

5. The display device according to claim 3, further comprising:
a first wiring electrically connected to one of a source and a drain of the transistor of each of the first subpixel and the second subpixel;
a second wiring electrically connected to one of a source and a drain of the transistor of each of the third subpixel and the fourth subpixel;
a third wiring electrically connected to a gate of the transistor of each of the first subpixel and the third subpixel;
a fourth wiring electrically connected to a gate of the transistor of each of the second subpixel and the fourth subpixel; and
a fifth wiring electrically connected to the second electrode of the capacitor.

6. The display device according to claim 3, further comprising:
a first wiring configured to supply a first data signal to the first subpixel and the second subpixel;
a second wiring configured to supply a second data signal to the third subpixel and the fourth subpixel;
a third wiring configured to supply a signal for controlling writing of the first data signal or the second data signal to the first subpixel and the third subpixel;
a fourth wiring configured to supply a signal for controlling writing of the first data signal or the second data signal to the second subpixel and the fourth subpixel; and
a fifth wiring configured to apply a constant potential to the second electrode of the capacitor.

7. The display device according to claim 6, wherein the fifth wiring has a meandering shape.

8. The display device according to claim 3, wherein the inorganic insulating film comprises an oxide insulating film in contact with the oxide semiconductor film and a nitride insulating film over and in contact with the oxide insulating film.

9. The display device according to claim 8, wherein the metal oxide film is in contact with the nitride insulating film and comprises the same metal element as the oxide semiconductor film.

10. The display device according to claim 3,
wherein each of the oxide semiconductor film and the metal oxide film comprises an In—Ga oxide, an In—Zn oxide, or an In-M-Zn oxide, and
wherein M is Al, Ga, Y, Zr, Sn, La, Ce, Nd, Sn, or Hf.

11. The display device according to claim 3,
wherein each of the first subpixel, the second subpixel, and the third subpixel comprises a color filter, and
wherein the fourth subpixel comprises a light-transmitting insulating layer in the same layer as the color filter.

12. A display device comprising:
a pixel comprising a first subpixel, a second subpixel, a third subpixel, and a fourth subpixel;
a first wiring;
a second wiring;
a third wiring;
a fourth wiring; and
a fifth wiring,
wherein the first subpixel is configured to control transmission of a first light and comprises a first opening for transmitting the first light,
wherein the second subpixel is configured to control transmission of a second light and comprises a second opening for transmitting the second light,
wherein the third subpixel is configured to control transmission of a third light and comprises a third opening for transmitting the third light,
wherein the fourth subpixel is configured to control transmission of a fourth light and comprises a fourth opening for transmitting the fourth light,
wherein the first light, the second light, the third light, and the fourth light are different from each other in color,
wherein the fourth opening has the smallest area of the first opening, the second opening, the third opening, and the fourth opening,
wherein each of the first subpixel, the second subpixel, the third subpixel, and the fourth subpixel comprises a transistor and a capacitor,
wherein the transistor comprises an oxide semiconductor film,
wherein the capacitor comprises a first electrode comprising a metal oxide film and a second electrode comprising a light-transmitting conductive film,
wherein an inorganic insulating film is over the transistor and over and in contact with the metal oxide film,
wherein the light-transmitting conductive film is over the inorganic insulating film and electrically connected to the transistor,
wherein the first wiring is electrically connected to one of a source and a drain of the transistor of each of the first subpixel and the second subpixel,
wherein the second wiring is electrically connected to one of a source and a drain of the transistor of each of the third subpixel and the fourth subpixel,
wherein the third wiring is electrically connected to a gate of the transistor of each of the first subpixel and the third subpixel,
wherein the fourth wiring is electrically connected to a gate of the transistor of each of the second subpixel and the fourth subpixel, and
wherein the fifth wiring is electrically connected to the second electrode of the capacitor.

13. The display device according to claim 12, wherein the fifth wiring has a meandering shape.

14. The display device according to claim 12, wherein the inorganic insulating film comprises an oxide insulating film in contact with the oxide semiconductor film and a nitride insulating film over and in contact with the oxide insulating film.

15. The display device according to claim 14, wherein the metal oxide film is in contact with the nitride insulating film and comprises the same metal element as the oxide semiconductor film.

16. The display device according to claim 12,
wherein each of the oxide semiconductor film and the metal oxide film comprises an In—Ga oxide, an In—Zn oxide, or an In-M-Zn oxide, and
wherein M is Al, Ga, Y, Zr, Sn, La, Ce, Nd, Sn, or Hf.

17. The display device according to claim 12,
wherein each of the first subpixel, the second subpixel, and the third subpixel comprises a color filter, and
wherein the fourth subpixel comprises a light-transmitting insulating layer in the same layer as the color filter.
